(19) United States
(12) Patent Application Publication
(10) Pub. No.: US 2024/0088318 A1
(43) Pub. Date: Mar. 14, 2024

(54) HEAT CONDUCTING LAYERS FOR PHOTOVOLTAIC MODULES

(71) Applicant: GAF Energy LLC, Parsippany, NJ (US)

(72) Inventors: Thierry Nguyen, San Francisco, CA (US); Ming-Liang Shiao, Collegeville, PA (US); Ray Lu, Parsippany, NJ (US); Emma Dohner, San Francisco, CA (US)

(21) Appl. No.: 18/467,435

(22) Filed: Sep. 14, 2023

Related U.S. Application Data
(60) Provisional application No. 63/406,511, filed on Sep. 14, 2022.

(51) Int. Cl. H01L 31/052; B32B 27/32; H01L 31/048; H01L 31/049; H02S 20/23

(52) U.S. Cl. CPC H01L 31/052; B32B 27/32; H01L 31/0481; H01L 31/049; H02S 20/23; B32B 2313/04; B32B 2457/12

(57) ABSTRACT

Some embodiments relate to a photovoltaic module. The photovoltaic module may be configured to be installed on a roofing substrate. The photovoltaic module may comprise a frontsheet, a backsheet, and an encapsulated solar cell between the frontsheet and the backsheet. The backsheet may comprise at least one layer. The at least one layer of the backsheet may comprise a polymer and a graphene component. The at least one layer of the backsheet may be a heat conducting layer. The photovoltaic module may comprise a film as a heat conducting layer.

### CROSS-REFERENCE TO RELATED APPLICATIONS

The present application claims priority to and benefit of U.S. Provisional Patent Application No. 63/406,511, filed Sep. 14, 2022 and entitled, “HEAT CONDUCTING LAYERS FOR PHOTOVOLTAIC MODULES”, the entirety of which is herein incorporated by reference.

### FIELD

This disclosure generally relates to photovoltaic modules and, in particular, to photovoltaic modules having at least one heat conducting layer.

### BACKGROUND

Photovoltaic modules generate heat that increases a temperature of the photovoltaic module. Photovoltaic modules also increase in temperature as a result of being exposed to direct and indirect sunlight.

### SUMMARY

Some embodiments relate to a roofing system. In some embodiments, the roofing system comprises a roofing substrate. In some embodiments, the roofing system comprises a plurality of photovoltaic modules installed on the roofing substrate. In some embodiments, each of the plurality of photovoltaic modules comprises a frontsheet. In some embodiments, each of the plurality of photovoltaic modules comprises at least one solar cell. In some embodiments, each of the plurality of photovoltaic modules comprises an encapsulant. In some embodiments, the encapsulant encapsulates the at least one solar cell. In some embodiments, each of the plurality of photovoltaic modules comprises a backsheet. In some embodiments, the backsheet is below the encapsulant. In some embodiments, the backsheet comprises at least one layer. In some embodiments, the at least one layer comprises 50% to 99.5% by weight of a polymer based on a total weight of the at least one layer of the backsheet. In some embodiments, the at least one layer comprises 0.5% to 50% by weight of a graphene component based on the total weight of the at least one layer of the backsheet.

In some embodiments, the roofing substrate comprises at least one of a roof deck, an underlayment, or any combination thereof.

In some embodiments, the graphene component comprises at least one of graphene particles, graphene sheets, graphene flakes, or any combination thereof.

In some embodiments, the graphene component is provided in a form of graphite.

In some embodiments, the graphene component having a median particle size of 1 μm to 300 μm.

In some embodiments, the at least one layer having a thermal conductivity of 0.3 W m⁻¹ K⁻¹ to 3 W m⁻¹ K⁻¹.

In some embodiments, the at least one layer of the backsheet having a thickness of 0.2 mm to 4 mm.

In some embodiments, the at least one layer of the backsheet is in direct contact with the roofing substrate.

In some embodiments, the at least one layer further comprises an encapsulant.

In some embodiments, the encapsulant comprises at least one of polyolefins, ethyl vinyl acetates, ionomers, silicones, poly vinyl butyral, epoxies, polyurethanes, or any combination thereof.

Some embodiments relate to photovoltaic module. In some embodiments, the photovoltaic module comprises a frontsheet. In some embodiments, the photovoltaic module comprises a backsheet. In some embodiments, the photovoltaic module comprises an encapsulated solar cell. In some embodiments, the encapsulated solar cell is located between the frontsheet and the backsheet. In some embodiments, the backsheet comprises at least one layer. In some embodiments, the at least one layer comprises 50% to 99.5% by weight of a polymer based on a total weight of the at least one layer of the backsheet. In some embodiments, the at least one layer comprises 0.5% to 50% by weight of a graphene component based on the total weight of the at least one layer of the backsheet. In some embodiments, the at least one layer is configured to be secured to a roofing substrate.

In some embodiments, the roofing substrate comprises at least one of a roof deck, an underlayment, or any combination thereof.

In some embodiments, the graphene component comprises at least one of graphene particles, graphene sheets, graphene flakes, or any combination thereof.

In some embodiments, the graphene component is provided in a form of graphite.

In some embodiments, the graphene component having a median particle size of 1 μm to 300 μm.

In some embodiments, the at least one layer having a thermal conductivity of 0.3 W m⁻¹ K⁻¹ to 3 W m⁻¹ K⁻¹.

In some embodiments, the at least one layer of the backsheet having a thickness of 0.2 mm to 4 mm.

In some embodiments, the at least one layer of the backsheet, when installed on the roofing substrate, is in direct contact with the roofing substrate.

In some embodiments, the at least one layer further comprises an encapsulant.

In some embodiments, the encapsulant comprises at least one of polyolefins, ethyl vinyl acetates, ionomers, silicones, poly vinyl butyral, epoxies, polyurethanes, or any combination thereof.

### BRIEF DESCRIPTION OF THE DRAWINGS

Reference is made to the drawings that form a part of this disclosure, and which illustrate embodiments in which the materials and methods described herein can be practiced.

FIG. 1 is a schematic diagram of a cross-section of a photovoltaic module, according to some embodiments.

FIG. 2 is a schematic diagram of a cross-section of a photovoltaic module, according to some embodiments.

FIG. 3 is a schematic diagram of a cross-section of a photovoltaic module, according to some embodiments.

FIG. 4 is a schematic diagram of a cross-section of a photovoltaic module, according to some embodiments.

FIG. 5 is a schematic diagram of a cross-section of a photovoltaic module, according to some embodiments.

FIG. 6 is a graphical view of a thermal conductivity test results, according to some embodiments.

### DETAILED DESCRIPTION

Some embodiments relate to heat conducting layers for photovoltaic modules, photovoltaic modules, and related systems. In some embodiments, the heat conducting layers are incorporated into photovoltaic modules. In some embodiments, the heat conducting layers are incorporated into photovoltaic roofing shingles. In some embodiments, the heat conducting layers are configured to provide efficient heat transfer from the photovoltaic module. In some embodiments, this heat transfer enhances energy generated by the photovoltaic module via cooling. In some embodiments, for example, the heat conducting layers lower the temperature of the photovoltaic modules. In some embodiments, the heat conducting layers increase total energy yield of the photovoltaic module relative to a photovoltaic module which is similarly installed and which does not comprise heat conducting layers (e.g., a control photovoltaic module). In some embodiments, the heat conducting layers permit the photovoltaic module to be installed directly on a roofing substrate, such as, for example and without limitation, an underlayment or a roof deck.

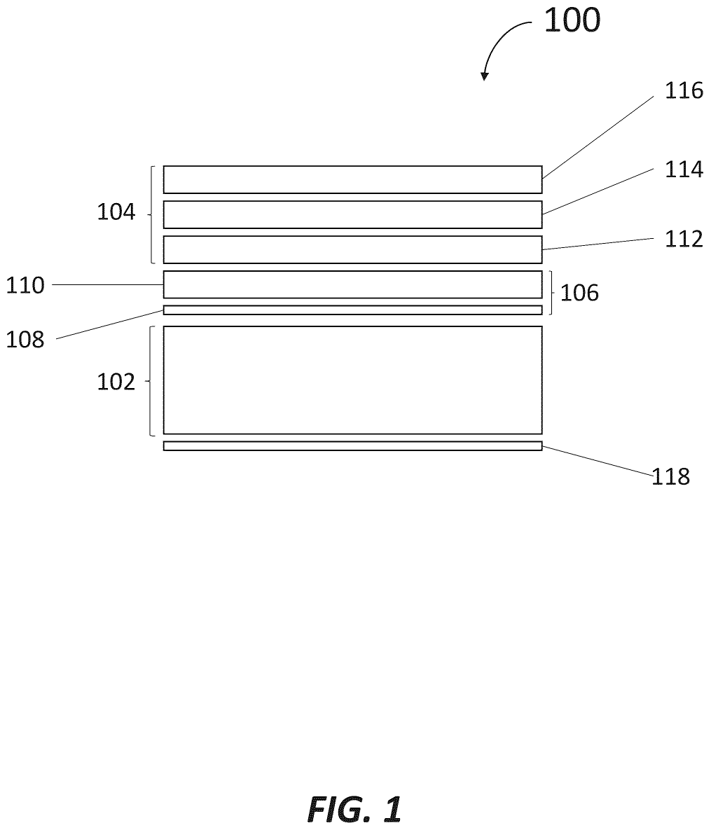

FIG. 1 is a schematic diagram of a cross-section of a photovoltaic module 100, according to some embodiments. As shown in FIG. 1, in some embodiments, the photovoltaic module 100 comprises a backsheet 102, a frontsheet 104, and an encapsulated solar cell 106 between the backsheet 102 and the frontsheet 104. In some embodiments, the backsheet 102 is juxtaposed with a first surface of the encapsulated solar cell 106. In some embodiments, the frontsheet 104 is juxtaposed with a second surface of the encapsulated solar cell 106. In some embodiments, the second surface of the encapsulated solar cell 106 is opposite the first surface of the encapsulated solar cell 106. In some embodiments, the photovoltaic module 100 is configured to be installed on a roofing substrate. In some embodiments, when the photovoltaic module 100 is installed on the roofing substrate, the backsheet 102 is between the roofing substrate and the encapsulated solar cell 106. In some embodiments, the backsheet 102 is in direct contact with the roofing substrate. In some embodiments, the backsheet 102 is in direct contact with the encapsulated solar cell 106.

In some embodiments, the backsheet 102 comprises or consists of a single layer. In some embodiments, the backsheet 102 comprises a plurality of layers. In some embodiments, the backsheet 102 comprises a first layer and a second layer. In some embodiments, the backsheet 102 comprises a first layer, a second layer, and a third layer. In some embodiments, the backsheet 102 comprises a first layer, a second layer, a third layer, and a fourth layer. In some embodiments, the backsheet 102 comprises a first layer, a second layer, a third layer, and a fourth layer. In some embodiments, the backsheet 102 comprises a first layer, a second layer, a third layer, a fourth layer, and a fifth layer. In some embodiments, the backsheet 102 comprises a first layer, a second layer, a third layer, a fourth layer, a fifth layer, and a sixth layer. In some embodiments, the backsheet 102 comprises a first layer, a second layer, a third layer, a fourth layer, a fifth layer, a sixth layer, and a seventh layer. In some embodiments, the backsheet 102 comprises a first layer, a second layer, a third layer, a fourth layer, a fifth layer, a sixth layer, and a seventh layer. In some embodiments, the backsheet 102 comprises a first layer, a second layer, a third layer, a fourth layer, a fifth layer, a sixth layer, a seventh layer, and an eighth layer. In some embodiments, the backsheet 102 comprises a first layer, a second layer, a third layer, a fourth layer, a fifth layer, a sixth layer, a seventh layer, an eighth layer, and a ninth layer. In some embodiments, the backsheet 102 comprises a first layer, a second layer, a third layer, a fourth layer, a fifth layer, a sixth layer, a seventh layer, an eighth layer, a ninth layer, and a tenth layer.

In some embodiments, at least one layer of the backsheet 102 comprises a graphene component. In some embodiments, the graphene component comprises graphene. In some embodiments, the graphene is provided in a form of graphite (e.g., at least one of graphite flakes, graphite sheets, graphite particles, graphite nanoparticles, graphite powder, graphite nanosheets, graphite nanoflakes, graphite platelets, graphite nanoplatelets, graphite fibers, etc., any one or more of which can be expandable graphite). In some embodiments, the graphite comprises stacked layers of graphene. In some embodiments, the graphite has a surface pH of 5 to 8.5. As used herein, the term “graphene” refers to a type of carbon nanomaterial. In some embodiments, the term “graphene” refers to a heat conducting (or thermally conductive) type of carbon nanomaterial. In some embodiments, the term “graphene” refers to a two-dimensional arrangement of carbon atoms. In some embodiments, the term “graphene” refers to a layer of atoms arranged in a two-dimensional honeycomb lattice. In some embodiments, the graphene includes graphene oxides. In some embodiments, the graphene includes reduced graphene oxides. In some embodiments, the term “graphene” does not refer to or does not include graphite. In some embodiments, the at least one layer of the backsheet 102 comprises carbon nanotubes.

In some embodiments, the graphite comprises 2 to 10,000 layers of graphene. In some embodiments, the graphite comprises 2 to 9,000 layers of graphene. In some embodiments, the graphite comprises 2 to 8,000 layers of graphene. In some embodiments, the graphite comprises 2 to 7,000 layers of graphene. In some embodiments, the graphite comprises 2 to 6,000 layers of graphene. In some embodiments, the graphite comprises 2 to 5,000 layers of graphene. In some embodiments, the graphite comprises 2 to 4,000 layers of graphene. In some embodiments, the graphite comprises 2 to 3,000 layers of graphene. In some embodiments, the graphite comprises 2 to 2,000 layers of graphene. In some embodiments, the graphite comprises 2 to 1,000 layers of graphene. In some embodiments, the graphite comprises 2 to 900 layers of graphene. In some embodiments, the graphite comprises 2 to 800 layers of graphene. In some embodiments, the graphite comprises 2 to 700 layers of graphene. In some embodiments, the graphite comprises 2 to 600 layers of graphene. In some embodiments, the graphite comprises 2 to 500 layers of graphene. In some embodiments, the graphite comprises 2 to 400 layers of graphene. In some embodiments, the graphite comprises 2 to 300 layers of graphene. In some embodiments, the graphite comprises 2 to 200 layers of graphene. In some embodiments, the graphite comprises 2 to 100 layers of graphene. In some embodiments, the graphite comprises 2 to 90 layers of graphene. In some embodiments, the graphite comprises 2 to 80 layers of graphene. In some embodiments, the graphite comprises 2 to 70 layers of graphene. In some embodiments, the graphite comprises 2 to 60 layers of graphene. In some embodiments, the graphite comprises 2 to 50 layers of graphene. In some embodiments, the graphite comprises 2 to 40 layers of graphene. In some embodiments, the graphite comprises 2 to 30 layers of graphene. In some embodiments, the graphite comprises 2 to 20 layers of graphene. In some embodiments, the graphite comprises 2 to 10 layers of graphene. In some embodiments, the graphite comprises 2 to 5 layers of graphene.

In some embodiments, the graphite comprises 100 to 10,000 layers of graphene. In some embodiments, the graphite comprises 200 to 10,000 layers of graphene. In some embodiments, the graphite comprises 300 to 10,000 layers of graphene. In some embodiments, the graphite comprises 400 to 10,000 layers of graphene. In some embodiments, the graphite comprises 500 to 10,000 layers of graphene. In some embodiments, the graphite comprises 600 to 10,000 layers of graphene. In some embodiments, the graphite comprises 700 to 10,000 layers of graphene. In some embodiments, the graphite comprises 800 to 10,000 layers of graphene. In some embodiments, the graphite comprises 900 to 10,000 layers of graphene. In some embodiments, the graphite comprises 1000 to 10,000 layers of graphene. In some embodiments, the graphite comprises 2000 to 10,000 layers of graphene. In some embodiments, the graphite comprises 3000 to 10,000 layers of graphene. In some embodiments, the graphite comprises 4000 to 10,000 layers of graphene. In some embodiments, the graphite comprises 5000 to 10,000 layers of graphene. In some embodiments, the graphite comprises 6000 to 10,000 layers of graphene. In some embodiments, the graphite comprises 7000 to 10,000 layers of graphene. In some embodiments, the graphite comprises 8000 to 10,000 layers of graphene. In some embodiments, the graphite comprises 9000 to 10,000 layers of graphene.

In some embodiments, the graphite comprises 2 to 100 layers of graphene. In some embodiments, the graphite comprises 2 to 90 layers of graphene. In some embodiments, the graphite comprises 2 to 80 layers of graphene. In some embodiments, the graphite comprises 2 to 70 layers of graphene. In some embodiments, the graphite comprises 2 to 60 layers of graphene. In some embodiments, the graphite comprises 2 to 50 layers of graphene. In some embodiments, the graphite comprises 2 to 40 layers of graphene. In some embodiments, the graphite comprises 2 to 30 layers of graphene. In some embodiments, the graphite comprises 2 to 20 layers of graphene. In some embodiments, the graphite comprises 2 to 10 layers of graphene. In some embodiments, the graphite comprises 10 to 100 layers of graphene. In some embodiments, the graphite comprises 20 to 100 layers of graphene. In some embodiments, the graphite comprises 30 to 100 layers of graphene. In some embodiments, the graphite comprises 40 to 100 layers of graphene. In some embodiments, the graphite comprises 50 to 100 layers of graphene. In some embodiments, the graphite comprises 60 to 100 layers of graphene. In some embodiments, the graphite comprises 70 to 100 layers of graphene. In some embodiments, the graphite comprises 80 to 100 layers of graphene. In some embodiments, the graphite comprises 90 to 100 layers of graphene.

In some embodiments, the graphene comprises graphene powder. In some embodiments, the graphene comprises a graphene particle. In some embodiments, the graphene comprises a plurality of graphene particles. In some embodiments, the plurality of graphene particles comprises a plurality of graphene nanoparticles. In some embodiments, the graphene comprises a graphene sheet. In some embodiments, the graphene comprises a plurality of graphene sheets. In some embodiments, the plurality of graphene sheets comprises a plurality of graphene nanosheets. In some embodiments, the graphene comprises graphene flakes. In some embodiments, the graphene flakes comprise graphene nanoflakes. In some embodiments, the graphene comprises graphene platelets. In some embodiments, the graphene platelets comprise graphene nanoplatelets. In some embodiments, the at least one layer of the backsheet does not comprise graphene nanoplatelets. In some embodiments, the graphene comprises graphene rods. In some embodiments, the graphene comprises graphene fibers.

In some embodiments, the at least one layer comprises 0.5% to 50% by weight of the graphene component based on a total weight of the at least one layer. In some embodiments, the at least one layer comprises 0.5% to 45% by weight of the graphene component based on the total weight of the at least one layer. In some embodiments, the at least one layer comprises 0.5% to 40% by weight of the graphene component based on the total weight of the at least one layer. In some embodiments, the at least one layer comprises 0.5% to 35% by weight of the graphene component based on the total weight of the at least one layer. In some embodiments, the at least one layer comprises 0.5% to 30% by weight of the graphene component based on the total weight of the at least one layer. In some embodiments, the at least one layer comprises 0.5% to 25% by weight of the graphene component based on the total weight of the at least one layer. In some embodiments, the at least one layer comprises 0.5% to 20% by weight of the graphene component based on the total weight of the at least one layer. In some embodiments, the at least one layer comprises 0.5% to 15% by weight of the graphene component based on the total weight of the at least one layer. In some embodiments, the at least one layer comprises 0.5% to 10% by weight of the graphene component based on the total weight of the at least one layer. In some embodiments, the at least one layer comprises 0.5% to 5% by weight of the graphene component based on the total weight of the at least one layer. In some embodiments, the at least one layer comprises 0.5% to 4% by weight of the graphene component based on the total weight of the at least one layer. In some embodiments, the at least one layer comprises 0.5% to 2% by weight of the graphene component based on the total weight of the at least one layer. In some embodiments, the at least one layer comprises 0.5% to 1% by weight of the graphene component based on the total weight of the at least one layer.

In some embodiments, the at least one layer comprises 1% to 50% by weight of the graphene component based on the total weight of the at least one layer. In some embodiments, the at least one layer comprises 5% to 50% by weight of the graphene component based on the total weight of the at least one layer. In some embodiments, the at least one layer comprises 10% to 50% by weight of the graphene component based on the total weight of the at least one layer. In some embodiments, the at least one layer comprises 15% to 50% by weight of the graphene component based on the total weight of the at least one layer. In some embodiments, the at least one layer comprises 20% to 50% by weight of the graphene component based on the total weight of the at least one layer. In some embodiments, the at least one layer comprises 25% to 50% by weight of the graphene component based on the total weight of the at least one layer. In some embodiments, the at least one layer comprises 30% to 50% by weight of the graphene component based on the total weight of the at least one layer. In some embodiments, the at least one layer comprises 35% to 50% by weight of the graphene component based on the total weight of the at least one layer. In some embodiments, the at least one layer comprises 40% to 50% by weight of the graphene component based on the total weight of the at least one layer. In some embodiments, the at least one layer comprises 45% to 50% by weight of the graphene component based on the total weight of the at least one layer.

In some embodiments, the at least one layer comprises at least 35% by volume of the graphene based on the total volume of the at least one layer. In some embodiments, the at least one layer comprises at least 40% by volume of the graphene based on the total volume of the at least one layer. In some embodiments, the at least one layer comprises at least 45% by volume of the graphene based on the total volume of the at least one layer. In some embodiments, the at least one layer comprises at least 50% by volume of the graphene based on the total volume of the at least one layer. In some embodiments, the at least one layer comprises at least 55% by volume of the graphene based on the total volume of the at least one layer. In some embodiments, the at least one layer comprises at least 60% by volume of the graphene based on the total volume of the at least one layer. In some embodiments, the at least one layer comprises at least 65% by volume of the graphene based on the total volume of the at least one layer. In some embodiments, the at least one layer comprises at least 70% by volume of the graphene based on the total volume of the at least one layer.

In some embodiments, the at least one layer comprises 35% to 70% by volume of the graphene based on the total volume of the at least one layer. In some embodiments, the at least one layer comprises 35% to 65% by volume of the graphene based on the total volume of the at least one layer. In some embodiments, the at least one layer comprises 35% to 60% by volume of the graphene based on the total volume of the at least one layer. In some embodiments, the at least one layer comprises 35% to 55% by volume of the graphene based on the total volume of the at least one layer. In some embodiments, the at least one layer comprises 35% to 50% by volume of the graphene based on the total volume of the at least one layer. In some embodiments, the at least one layer comprises 35% to 45% by volume of the graphene based on the total volume of the at least one layer. In some embodiments, the at least one layer comprises 35% to 40% by volume of the graphene based on the total volume of the at least one layer.

In some embodiments, the at least one layer comprises 40% to 70% by volume of the graphene based on the total volume of the at least one layer. In some embodiments, the at least one layer comprises 45% to 70% by volume of the graphene based on the total volume of the at least one layer. In some embodiments, the at least one layer comprises 50% to 70% by volume of the graphene based on the total volume of the at least one layer. In some embodiments, the at least one layer comprises 55% to 70% by volume of the graphene based on the total volume of the at least one layer. In some embodiments, the at least one layer comprises 60% to 70% by volume of the graphene based on the total volume of the at least one layer. In some embodiments, the at least one layer comprises 65% to 70% by volume of the graphene based on the total volume of the at least one layer.

In some embodiments, the graphene is characterized by a lateral size. As used herein, the term “lateral size” of the graphene refers to a length or an average length of at least one dimension of the graphene component. In some embodiments, the term “lateral size” of the graphene refers to a length of the greatest dimension of the graphene component. In some embodiments, the term “lateral size” of the graphene refers to an average length of the greatest dimension of the graphene component. In some embodiments, for example, the lateral size of graphene may refer to a radius. In some embodiments, the lateral size of graphene may refer to a diameter. In some embodiments, the lateral size of graphene may refer to a width. In some embodiments, the lateral size of graphene may refer to a height. In some embodiments, the lateral size of graphene may refer to a length. In some embodiments, the lateral size of the graphene may refer to a thickness. In some embodiments, the lateral size of the graphene may refer to a median particle size. In some embodiments, the graphene component comprises graphene having a plurality of different lateral sizes.

In some embodiments, a lateral size of the graphene is 800 μm or less. In some embodiments, the lateral size of the graphene is 600 μm or less. In some embodiments, the lateral size of the graphene is 500 μm or less. In some embodiments, the lateral size of the graphene is 400 μm or less. In some embodiments, the lateral size of the graphene is 300 μm or less. In some embodiments, the lateral size of the graphene is 200 μm or less. In some embodiments, the lateral size of the graphene is 0.01 nm to 800 nm. In some embodiments, the lateral size of the graphene is 5 nm to 800 nm. In some embodiments, the lateral size of the graphene is 10 nm to 500 nm. In some embodiments, the lateral size of the graphene is 10 nm to 400 nm. In some embodiments, the lateral size of the graphene is 10 nm to 200 nm. In some embodiments, the lateral size of the graphene is 5 nm to 150 nm. In some embodiments, the lateral size of the graphene is 10 nm to 500 μm. In some embodiments, the lateral size of the graphene is 50 nm to 500 μm. In some embodiments, the lateral size of the graphene is 100 nm to 500 μm. In some embodiments, the lateral size of the graphene is 200 nm to 500 μm. In some embodiments, the lateral size of the graphene is 200 nm to 20 μm. In some embodiments, the lateral size of the graphene is 500 nm to 5 μm. In some embodiments, the lateral size of the graphene is 5 μm to 20 μm. In some embodiments, the lateral size of the graphene is 200 nm to 500 nm. In some embodiments, the lateral size of the graphene is 0.5 μm to 5 μm.

In some embodiments, the lateral size of the graphene is 1 nm to 100 μm. In some embodiments, the lateral size of the graphene is 1 nm to 90 μm. In some embodiments, the lateral size of the graphene is 1 nm to 80 μm. In some embodiments, the lateral size of the graphene is 1 nm to 70 μm. In some embodiments, the lateral size of the graphene is 1 nm to 60 μm. In some embodiments, the lateral size of the graphene is 1 nm to 50 μm. In some embodiments, the lateral size of the graphene is 1 nm to 40 μm. In some embodiments, the lateral size of the graphene is 1 nm to 30 μm. In some embodiments, the lateral size of the graphene is 1 nm to 20 μm. In some embodiments, the lateral size of the graphene is 1 nm to 10 μm. In some embodiments, the lateral size of the graphene is 10 nm to 100 μm. In some embodiments, the lateral size of the graphene is 20 nm to 100 μm. In some embodiments, the lateral size of the graphene is 30 nm to 100 μm. In some embodiments, the lateral size of the graphene is 40 nm to 100 μm. In some embodiments, the lateral size of the graphene is 50 nm to 100 μm. In some embodiments, the lateral size of the graphene is 60 nm to 100 μm. In some embodiments, the lateral size of the graphene is 70 nm to 100 μm. In some embodiments, the lateral size of the graphene is nm to 100 μm. In some embodiments, the lateral size of the graphene is 80 nm to 100 μm. In some embodiments, the lateral size of the graphene is 90 nm to 100 μm. In some embodiments, the lateral size of the graphene is 10 nm to 70 μm. In some embodiments, the lateral size of the graphene is 1 μm to 2 μm.

In some embodiments, the lateral size of the graphene component is 50 μm to 1000 μm. In some embodiments, the lateral size of the graphene component is 50 μm to 900 μm. In some embodiments, the lateral size of the graphene component is 50 μm to 800 μm. In some embodiments, the lateral size of the graphene component is 50 μm to 700 μm. In some embodiments, the lateral size of the graphene component is 50 μm to 600 μm. In some embodiments, the lateral size of the graphene component is 50 μm to 500 μm. In some embodiments, the lateral size of the graphene component is 50 μm to 400 μm. In some embodiments, the lateral size of the graphene component is 50 μm to 300 μm. In some embodiments, the lateral size of the graphene component is 50 μm to 200 μm. In some embodiments, the lateral size of the graphene component is 50 μm to 100 μm.

In some embodiments, the lateral size of the graphene component is 100 μm to 1000 μm. In some embodiments, the lateral size of the graphene component is 200 μm to 1000 μm. In some embodiments, the lateral size of the graphene component is 300 μm to 1000 μm. In some embodiments, the lateral size of the graphene component is 400 μm to 1000 μm. In some embodiments, the lateral size of the graphene component is 500 μm to 1000 μm. In some embodiments, the lateral size of the graphene component is 600 μm to 1000 μm. In some embodiments, the lateral size of the graphene component is 700 μm to 1000 μm. In some embodiments, the lateral size of the graphene component is 800 μm to 1000 μm. In some embodiments, the lateral size of the graphene component is 900 μm to 1000 μm.

In some embodiments, the graphene component has an orientation in the at least one layer of the backsheet 102. In some embodiments, the graphene component comprises graphene in a random orientation in the at least one layer of the backsheet 102. In some embodiments, the graphene component comprises graphene in an ordered orientation in the at least one layer of the backsheet 102. In some embodiments, the graphene component comprises graphene oriented in the at least one layer of the backsheet 102 in a two-dimensional structure. In some embodiments, the graphene component comprises graphene oriented in the at least one layer of the backsheet 102 in a three-dimensional structure. In some embodiments, the graphene component comprises graphene oriented in the at least one layer of the backsheet 102 in end-to-end strips. In some embodiments, the graphene component comprises graphene oriented in the at least one layer of the backsheet 102 in a sheet structure.

In some embodiments, the graphene component comprises impurities. In some embodiments, the graphene component comprises no more than 4% by weight of impurities based on a total weight of the graphene component. In some embodiments, the graphene component comprises no more than 3% by weight of impurities based on the total weight of the graphene component. In some embodiments, the graphene component comprises no more than 2% by weight of impurities based on the total weight of the graphene component. In some embodiments, the graphene component comprises no more than 1% by weight of impurities based on the total weight of the graphene component. In some embodiments, the graphene component comprises 0.01% to 4% by weight of impurities based on the total weight of the graphene component. In some embodiments, the graphene component comprises 0.01% to 3.5% by weight of impurities based on the total weight of the graphene component. In some embodiments, the graphene component comprises 0.01% to 3% by weight of impurities based on the total weight of the graphene component. In some embodiments, the graphene component comprises 0.01% to 2.5% by weight of impurities based on the total weight of the graphene component. In some embodiments, the graphene component comprises 0.01% to 2% by weight of impurities based on the total weight of the graphene component. In some embodiments, the graphene component comprises 0.01% to 1.5% by weight of impurities based on the total weight of the graphene component. In some embodiments, the graphene component comprises 0.01% to 1% by weight of impurities based on the total weight of the graphene component. In some embodiments, the graphene component comprises 0.01% to 0.5% by weight of impurities based on the total weight of the graphene component. In some embodiments, the graphene component comprises 0.5% to 4% by weight of impurities based on the total weight of the graphene component. In some embodiments, the graphene component comprises 1% to 4% by weight of impurities based on the total weight of the graphene component. In some embodiments, the graphene component comprises 1.5% to 4% by weight of impurities based on the total weight of the graphene component. In some embodiments, the graphene component comprises 2% to 4% by weight of impurities based on the total weight of the graphene component. In some embodiments, the graphene component comprises 2.5% to 4% by weight of impurities based on the total weight of the graphene component. In some embodiments, the graphene component comprises 3% to 4% by weight of impurities based on the total weight of the graphene component. In some embodiments, the graphene component comprises 3.5% to 4% by weight of impurities based on the total weight of the graphene component. In some embodiments, the impurities comprise any substance other than graphene.

In some embodiments, the at least one layer of the backsheet 102 comprises a polymeric material. In some embodiments, the at least one layer of the backsheet 102 comprises one or more thermoplastic polymers. In some embodiments, the thermoplastic polymer comprises a polyolefin. In some embodiments, the thermoplastic polymer comprises a thermoplastic polyolefin (TPO). In some embodiments, the thermoplastic polyolefin comprises at least one of polyethylene, polypropylene, any copolymer thereof, any homopolymer thereof, any polymer blend thereof, or any combination thereof. In some embodiments, the thermoplastic polyolefin comprises at least one of a copolymer of propylene and ethylene, a blend of propylene and ethylene, a copolymer of ethylene alpha-olefin, a propylene homopolymer, an ethylene homopolymer, a propylene block copolymer, an ethylene block copolymer, a propylene elastomer, an ethylene elastomer, or any combination thereof. In some embodiments, the thermoplastic polymer comprises at least one of a copolymer comprising ethylene and octene, a copolymer comprising ethylene and hexane, a copolymer comprising ethylene and butene, polyethylene (including raw and/or recycled low density polyethylene (LDPE)), linear low density polyethylene (LLDPE), high density polyethylene (HDPE)), polypropylenes (e.g., isotactic polypropylene (IPP) and/or atactic polypropylene (APP/IPP)), amorphous polyalpha olefins (APAO), amorphous polyolefins (APO), or any combination thereof. In some embodiments, the thermoplastic polymer does not comprise polyurethane.

Such thermoplastic polymers can include, for example and without limitation, at least one of Vistamaxx® 6102, Vistamaxx® 8880, both of which are polypropylenes (e.g., isotactic polypropylene (IPP)) that are available from ExxonMobil, Irving, Tex.; Elvaloy®, which is a terpolymer that is available from Dow/DuPont, Wilmington, Del.; Fusabond®, which is a chemically modified ethylene acrylate copolymer and/or a modified polyethylene, that is available from Dow/DuPont, Wilmington, Del.; RT2304, which is an amorphous polyalpha olefin (APAO) that is available from Rextac APAO Polymers LLC, Odessa, Tex.; Eastoflex® P1023, which is an amorphous polyolefin (APO) that comprises a propylene homopolymer, and is available from Eastman Chemical Company, Kingsport, Tenn.; Eastoflex® E1060, which is an amorphous polyolefin (APO) that comprises a copolymer of propylene and ethylene, and is available from Eastman Chemical Company, Kingsport, Tenn.; Eastoflex® M1025, which is an amorphous polyolefin (APO) that comprises a blend of propylene homopolymer and copolymers of propylene and ethylene, and is available from Eastman Chemical Company, Kingsport, Tenn.; Engage® 7487, which is a polyolefin elastomer (POE) that is available from Dow Inc., Midland, Mich., or any combination thereof.

In some embodiments, the at least one layer of the backsheet 102 comprises polyethylene terephthalate (PET). In some embodiments, the at least one layer of the backsheet 102 comprises ethylene tetrafluoroethylene (ETFE). In some embodiments, the at least one layer of the backsheet 102 comprises an acrylic such as polymethyl methacrylate (PMMA). In some embodiments, the at least one layer of the backsheet 102 comprises thermoplastic polyolefin (TPO). In some embodiments, the at least one layer of the backsheet 102 comprises a single ply TPO roofing membrane. In other embodiments, non-limiting examples of TPO membranes are disclosed in U.S. Pat. No. 9,359,014 to Yang et al., which is incorporated by reference herein in its entirety. In some embodiments, the at least one layer of the backsheet 102 comprises polyvinyl chloride. In some embodiments, the at least one layer of the backsheet 102 comprises ethylene propylene diene monomer (EPDM) rubber. In some embodiments, the at least one layer of the backsheet 102 comprises a flame retardant. In some embodiments, the flame retardant comprises at least one of clays, nanoclays, silicas, carbon black, metal hydroxides such as aluminum hydroxide, metal foils, graphite, expandable graphite, or any combination thereof. In some embodiments, the at least one layer of the backsheet 102 is white in color. In some embodiments, the at least one layer of the backsheet 102 is white TPO.

In some embodiments, the at least one layer comprises 50% to 99.5% by weight of the polymeric material based on the total weight of the at least one layer. In some embodiments, the at least one layer comprises 50% to 95% by weight of the polymeric material based on the total weight of the at least one layer. In some embodiments, the at least one layer comprises 50% to 90% by weight of the polymeric material based on the total weight of the at least one layer. In some embodiments, the at least one layer comprises 50% to 85% by weight of the polymeric material based on the total weight of the at least one layer. In some embodiments, the at least one layer comprises 50% to 80% by weight of the polymeric material based on the total weight of the at least one layer. In some embodiments, the at least one layer comprises 50% to 75% by weight of the polymeric material based on the total weight of the at least one layer. In some embodiments, the at least one layer comprises 50% to 70% by weight of the polymeric material based on the total weight of the at least one layer. In some embodiments, the at least one layer comprises 50% to 65% by weight of the polymeric material based on the total weight of the at least one layer. In some embodiments, the at least one layer comprises 50% to 60% by weight of the polymeric material based on the total weight of the at least one layer. In some embodiments, the at least one layer comprises 50% to 55% by weight of the polymeric material based on the total weight of the at least one layer.

In some embodiments, the at least one layer comprises 55% to 99.5% by weight of the polymeric material based on the total weight of the at least one layer. In some embodiments, the at least one layer comprises 60% to 99.5% by weight of the polymeric material based on the total weight of the at least one layer. In some embodiments, the at least one layer comprises 65% to 99.5% by weight of the polymeric material based on the total weight of the at least one layer. In some embodiments, the at least one layer comprises 70% to 99.5% by weight of the polymeric material based on the total weight of the at least one layer. In some embodiments, the at least one layer comprises 75% to 99.5% by weight of the polymeric material based on the total weight of the at least one layer. In some embodiments, the at least one layer comprises 80% to 99.5% by weight of the polymeric material based on the total weight of the at least one layer. In some embodiments, the at least one layer comprises 85% to 99.5% by weight of the polymeric material based on the total weight of the at least one layer. In some embodiments, the at least one layer comprises 90% to 99.5% by weight of the polymeric material based on the total weight of the at least one layer. In some embodiments, the at least one layer comprises 95% to 99.5% by weight of the polymeric material based on the total weight of the at least one layer.

In some embodiments, the at least one layer comprises an encapsulant. In some embodiments in which the at least one layer comprises the encapsulant, the backsheet 102 encapsulates at least a portion of at least one solar cell 108. In some of these embodiments, the at least one layer of the backsheet 102 is an encapsulant-backsheet layer. In some embodiments, the encapsulant-backsheet layer of the backsheet 102 is juxtaposed with a first surface of the at least one solar cell 108. In some embodiments, an encapsulant layer 110 is juxtaposed with a second surface of the at least one solar cell 108. As used herein, the terms “encapsulating” and “encapsulates” mean to partially or fully envelope or enclose, and with respect to certain embodiments of the photovoltaic module 100, the at least one solar cell 108 is fully enveloped by or enclosed within the encapsulant layer 110 and the encapsulant-backsheet layer of the backsheet 102, or partially enveloped by or enclosed within the encapsulant layer 110 and the encapsulant-backsheet layer of the backsheet 102. In some embodiments, the encapsulant layer 110 comprises an encapsulant, which may be the same or different from the encapsulant of the at least one layer of the backsheet 102. In some embodiments, the encapsulant comprises at least one of at least one of polyolefins, ethyl vinyl acetates, ionomers, silicones, poly vinyl butyral, epoxies, polyurethanes, any hybrids thereof, or any combinations thereof. In some embodiments, the encapsulant is made from thermosetting polyolefin.

In some embodiments, the encapsulant layer 110 encapsulates 50% to 99.9% of an exterior surface area of the at least one solar cell 108, and the encapsulant-backsheet layer of the backsheet 102 covers 0.1% to 50% of the exterior surface area of the at least one solar cell 108. In another embodiment, the encapsulant layer 110 encapsulates 55% to 99.9% of an exterior surface area of the at least one solar cell 108, and the encapsulant-backsheet layer of the backsheet 102 covers 0.1% to 45% of the exterior surface area of the at least one solar cell 108. In another embodiment, the encapsulant layer 110 encapsulates 60% to 99.9% of an exterior surface area of the at least one solar cell 108, and the encapsulant-backsheet layer of the backsheet 102 covers 0.1% to 40% of the exterior surface area of the at least one solar cell 108. In another embodiment, the encapsulant layer 110 encapsulates 65% to 99.9% of an exterior surface area of the at least one solar cell 108, and the encapsulant-backsheet layer of the backsheet 102 covers 0.1% to 35% of the exterior surface area of the at least one solar cell 108. In another embodiment, the encapsulant layer 110 encapsulates 70% to 99.9% of an exterior surface area of the at least one solar cell 108, and the encapsulant-backsheet layer of the backsheet 102 covers 0.1% to 30% of the exterior surface area of the at least one solar cell 108. In another embodiment, the encapsulant layer 110 encapsulates 75% to 99.9% of an exterior surface area of the at least one solar cell 108, and the encapsulant-backsheet layer of the backsheet 102 covers 0.1% to 25% of the exterior surface area of the at least one solar cell 108. In another embodiment, the encapsulant layer 110 encapsulates 80% to 99.9% of an exterior surface area of the at least one solar cell 108, and the encapsulant-backsheet layer of the backsheet 102 covers 0.1% to 20% of the exterior surface area of the at least one solar cell 108. In another embodiment, the encapsulant layer 110 encapsulates 85% to 99.9% of an exterior surface area of the at least one solar cell 108, and the encapsulant-backsheet layer of the backsheet 102 covers 0.1% to 15% of the exterior surface area of the at least one solar cell 108. In another embodiment, the encapsulant layer 110 encapsulates 90% to 99.9% of an exterior surface area of the at least one solar cell 108, and the encapsulant-backsheet layer of the backsheet 102 covers 0.1% to 10% of the exterior surface area of the at least one solar cell 108. In another embodiment, the encapsulant layer 110 encapsulates 95% to 99.9% of an exterior surface area of the at least one solar cell 108, and the encapsulant-backsheet layer of the backsheet 102 covers 0.1% to 5% of the exterior surface area of the at least one solar cell 108.

In some embodiments, the encapsulant layer 110 encapsulates 50% to 95% of an exterior surface area of the at least one solar cell 108, and the encapsulant-backsheet layer of the backsheet 102 covers 5% to 50% of the exterior surface area of the at least one solar cell 108. In another embodiment, the encapsulant layer 110 encapsulates 55% to 95% of an exterior surface area of the at least one solar cell 108, and the encapsulant-backsheet layer of the backsheet 102 covers 5% to 45% of the exterior surface area of the at least one solar cell 108. In another embodiment, the encapsulant layer 110 encapsulates 60% to 95% of an exterior surface area of the at least one solar cell 108, and the encapsulant-backsheet layer of the backsheet 102 covers 5% to 40% of the exterior surface area of the at least one solar cell 108. In another embodiment, the encapsulant layer 110 encapsulates 65% to 95% of an exterior surface area of the at least one solar cell 108, and the encapsulant-backsheet layer of the backsheet 102 covers 5% to 35% of the exterior surface area of the at least one solar cell 108. In another embodiment, the encapsulant layer 110 encapsulates 70% to 95% of an exterior surface area of the at least one solar cell 108, and the encapsulant-backsheet layer of the backsheet 102 covers 5% to 30% of the exterior surface area of the at least one solar cell 108. In another embodiment, the encapsulant layer 110 encapsulates 75% to 95% of an exterior surface area of the at least one solar cell 108, and the encapsulant-backsheet layer of the backsheet 102 covers 5% to 25% of the exterior surface area of the at least one solar cell 108. In another embodiment, the encapsulant layer 110 encapsulates 80% to 95% of an exterior surface area of the at least one solar cell 108, and the encapsulant-backsheet layer of the backsheet 102 covers 5% to 20% of the exterior surface area of the at least one solar cell 108. In another embodiment, the encapsulant layer 110 encapsulates 85% to 95% of an exterior surface area of the at least one solar cell 108, and the encapsulant-backsheet layer of the backsheet 102 covers 5% to 15% of the exterior surface area of the at least one solar cell 108. In another embodiment, the encapsulant layer 110 encapsulates 90% to 95% of an exterior surface area of the at least one solar cell 108, and the encapsulant-backsheet layer of the backsheet 102 covers 5% to 10% of the exterior surface area of the at least one solar cell 108.

In another embodiment, the encapsulant layer 110 encapsulates 50% to 90% of an exterior surface area of the at least one solar cell 108, and the encapsulant-backsheet layer of the backsheet 102 covers 10% to 50% of the exterior surface area of the at least one solar cell 108. In another embodiment, the encapsulant layer 110 encapsulates 55% to 90% of an exterior surface area of the at least one solar cell 108, and the encapsulant-backsheet layer of the backsheet 102 covers 10% to 45% of the exterior surface area of the at least one solar cell 108. In another embodiment, the encapsulant layer 110 encapsulates 60% to 90% of an exterior surface area of the at least one solar cell 108, and the encapsulant-backsheet layer of the backsheet 102 covers 10% to 40% of the exterior surface area of the at least one solar cell 108. In another embodiment, the encapsulant layer 110 encapsulates 65% to 90% of an exterior surface area of the at least one solar cell 108, and the encapsulant-backsheet layer of the backsheet 102 covers 10% to 35% of the exterior surface area of the at least one solar cell 108. In another embodiment, the encapsulant layer 110 encapsulates 70% to 90% of an exterior surface area of the at least one solar cell 108, and the encapsulant-backsheet layer of the backsheet 102 covers 10% to 30% of the exterior surface area of the at least one solar cell 108. In another embodiment, the encapsulant layer 110 encapsulates 75% to 90% of an exterior surface area of the at least one solar cell 108, and the encapsulant-backsheet layer of the backsheet 102 covers 10% to 25% of the exterior surface area of the at least one solar cell 108. In another embodiment, the encapsulant layer 110 encapsulates 80% to 90% of an exterior surface area of the at least one solar cell 108, and the encapsulant-backsheet layer of the backsheet 102 covers 10% to 20% of the exterior surface area of the at least one solar cell 108. In another embodiment, the encapsulant layer 110 encapsulates 85% to 90% of an exterior surface area of the at least one solar cell 108, and the encapsulant-backsheet layer of the backsheet 102 covers 10% to 15% of the exterior surface area of the at least one solar cell 108.

In another embodiment, the encapsulant layer 110 encapsulates 50% to 85% of an exterior surface area of the at least one solar cell 108, and the encapsulant-backsheet layer of the backsheet 102 covers 15% to 50% of the exterior surface area of the at least one solar cell 108. In another embodiment, the encapsulant layer 110 encapsulates 55% to 85% of an exterior surface area of the at least one solar cell 108, and the encapsulant-backsheet layer of the backsheet 102 covers 15% to 45% of the exterior surface area of the at least one solar cell 108. In another embodiment, the encapsulant layer 110 encapsulates 60% to 85% of an exterior surface area of the at least one solar cell 108, and the encapsulant-backsheet layer of the backsheet 102 covers 15% to 40% of the exterior surface area of the at least one solar cell 108. In another embodiment, the encapsulant layer 110 encapsulates 65% to 85% of an exterior surface area of the at least one solar cell 108, and the encapsulant-backsheet layer of the backsheet 102 covers 15% to 35% of the exterior surface area of the at least one solar cell 108. In another embodiment, the encapsulant layer 110 encapsulates 70% to 85% of an exterior surface area of the at least one solar cell 108, and the encapsulant-backsheet layer of the backsheet 102 covers 15% to 30% of the exterior surface area of the at least one solar cell 108. In another embodiment, the encapsulant layer 110 encapsulates 75% to 85% of an exterior surface area of the at least one solar cell 108, and the encapsulant-backsheet layer of the backsheet 102 covers 15% to 25% of the exterior surface area of the at least one solar cell 108. In another embodiment, the encapsulant layer 110 encapsulates 80% to 85% of an exterior surface area of the at least one solar cell 108, and the encapsulant-backsheet layer of the backsheet 102 covers 15% to 20% of the exterior surface area of the at least one solar cell 108.

In another embodiment, the encapsulant layer 110 encapsulates 50% to 80% of an exterior surface area of the at least one solar cell 108, and the encapsulant-backsheet layer of the backsheet 102 covers 20% to 50% of the exterior surface area of the at least one solar cell 108. In another embodiment, the encapsulant layer 110 encapsulates 55% to 80% of an exterior surface area of the at least one solar cell 108, and the encapsulant-backsheet layer of the backsheet 102 covers 20% to 45% of the exterior surface area of the at least one solar cell 108. In another embodiment, the encapsulant layer 110 encapsulates 60% to 80% of an exterior surface area of the at least one solar cell 108, and the encapsulant-backsheet layer of the backsheet 102 covers 20% to 40% of the exterior surface area of the at least one solar cell 108. In another embodiment, the encapsulant layer 110 encapsulates 65% to 80% of an exterior surface area of the at least one solar cell 108, and the encapsulant-backsheet layer of the backsheet 102 covers 20% to 35% of the exterior surface area of the at least one solar cell 108. In another embodiment, the encapsulant layer 110 encapsulates 70% to 80% of an exterior surface area of the at least one solar cell 108, and the encapsulant-backsheet layer of the backsheet 102 covers 20% to 30% of the exterior surface area of the at least one solar cell 108. In another embodiment, the encapsulant layer 110 encapsulates 75% to 80% of an exterior surface area of the at least one solar cell 108, and the encapsulant-backsheet layer of the backsheet 102 covers 20% to 25% of the exterior surface area of the at least one solar cell 108.

In another embodiment, the encapsulant layer 110 encapsulates 50% to 75% of an exterior surface area of the at least one solar cell 108, and the encapsulant-backsheet layer of the backsheet 102 covers 25% to 50% of the exterior surface area of the at least one solar cell 108. In another embodiment, the encapsulant layer 110 encapsulates 55% to 75% of an exterior surface area of the at least one solar cell 108, and the encapsulant-backsheet layer of the backsheet 102 covers 25% to 45% of the exterior surface area of the at least one solar cell 108. In another embodiment, the encapsulant layer 110 encapsulates 60% to 75% of an exterior surface area of the at least one solar cell 108, and the encapsulant-backsheet layer of the backsheet 102 covers 25% to 40% of the exterior surface area of the at least one solar cell 108. In another embodiment, the encapsulant layer 110 encapsulates 65% to 75% of an exterior surface area of the at least one solar cell 108, and the encapsulant-backsheet layer of the backsheet 102 covers 25% to 35% of the exterior surface area of the at least one solar cell 108. In another embodiment, the encapsulant layer 110 encapsulates 70% to 75% of an exterior surface area of the at least one solar cell 108, and the encapsulant-backsheet layer of the backsheet 102 covers 25% to 30% of the exterior surface area of the at least one solar cell 108.

In another embodiment, the encapsulant layer 110 encapsulates 50% to 70% of an exterior surface area of the at least one solar cell 108, and the encapsulant-backsheet layer of the backsheet 102 covers 30% to 50% of the exterior surface area of the at least one solar cell 108. In another embodiment, the encapsulant layer 110 encapsulates 55% to 70% of an exterior surface area of the at least one solar cell 108, and the encapsulant-backsheet layer of the backsheet 102 covers 30% to 45% of the exterior surface area of the at least one solar cell 108. In another embodiment, the encapsulant layer 110 encapsulates 60% to 70% of an exterior surface area of the at least one solar cell 108, and the encapsulant-backsheet layer of the backsheet 102 covers 30% to 40% of the exterior surface area of the at least one solar cell 108. In another embodiment, the encapsulant layer 110 encapsulates 65% to 70% of an exterior surface area of the at least one solar cell 108, and the encapsulant-backsheet layer of the backsheet 102 covers 30% to 35% of the exterior surface area of the at least one solar cell 108.

In another embodiment, the encapsulant layer 110 encapsulates 50% to 65% of an exterior surface area of the at least one solar cell 108, and the encapsulant-backsheet layer of the backsheet 102 covers 35% to 50% of the exterior surface area of the at least one solar cell 108. In another embodiment, the encapsulant layer 110 encapsulates 55% to 65% of an exterior surface area of the at least one solar cell 108, and the encapsulant-backsheet layer of the backsheet 102 covers 35% to 45% of the exterior surface area of the at least one solar cell 108. In another embodiment, the encapsulant layer 110 encapsulates 60% to 65% of an exterior surface area of the at least one solar cell 108, and the encapsulant-backsheet layer of the backsheet 102 covers 35% to 40% of the exterior surface area of the at least one solar cell 108. In another embodiment, the encapsulant layer 110 encapsulates 50% to 60% of an exterior surface area of the at least one solar cell 108, and the encapsulant-backsheet layer of the backsheet 102 covers 40% to 50% of the exterior surface area of the at least one solar cell 108. In another embodiment, the encapsulant layer 110 encapsulates 55% to 60% of an exterior surface area of the at least one solar cell 108, and the encapsulant-backsheet layer of the backsheet 102 covers 40% to 45% of the exterior surface area of the at least one solar cell 108. In another embodiment, the encapsulant layer 110 encapsulates 50% to 55% of an exterior surface area of the at least one solar cell 108, and the encapsulant-backsheet layer of the backsheet 102 covers 45% to 50% of the exterior surface area of the at least one solar cell 108.

In some embodiments, the encapsulant layer 110 encapsulates 50% of an exterior surface area of the at least one solar cell 108 and the encapsulant-backsheet layer of the backsheet 102 covers 50% of the exterior surface area of the at least one solar cell 108. In another embodiment, the encapsulant layer 110 encapsulates 55% of the exterior surface area of the at least one solar cell 108 and the encapsulant-backsheet layer of the backsheet 102 covers 45% of the exterior surface area of the at least one solar cell 108. In another embodiment, the encapsulant layer 110 encapsulates 60% of the exterior surface area of the at least one solar cell 108 and the encapsulant-backsheet layer of the backsheet 102 covers 40% of the exterior surface area of the at least one solar cell 108. In another embodiment, the encapsulant layer 110 encapsulates 65% of the exterior surface area of the at least one solar cell 108 and the encapsulant-backsheet layer of the backsheet 102 covers 35% of the exterior surface area of the at least one solar cell 108. In another embodiment, the encapsulant layer 110 encapsulates 70% of the exterior surface area of the at least one solar cell 108 and the encapsulant-backsheet layer of the backsheet 102 covers 30% of the exterior surface area of the at least one solar cell 108. In another embodiment, the encapsulant layer 110 encapsulates 75% of the exterior surface area of the at least one solar cell 108 and the encapsulant-backsheet layer of the backsheet 102 covers 25% of the exterior surface area of the at least one solar cell 108. In another embodiment, the encapsulant layer 110 encapsulates 80% of the exterior surface area of the at least one solar cell 108 and the encapsulant-backsheet layer of the backsheet 102 covers 20% of the exterior surface area of the at least one solar cell 108. In another embodiment, the encapsulant layer 110 encapsulates 85% of the exterior surface area of the at least one solar cell 108 and the encapsulant-backsheet layer of the backsheet 102 covers 15% of the exterior surface area of the at least one solar cell 108. In another embodiment, the encapsulant layer 110 encapsulates 90% of the exterior surface area of the at least one solar cell 108 and the encapsulant-backsheet layer of the backsheet 102 covers 10% of the exterior surface area of the at least one solar cell 108. In another embodiment, the encapsulant layer 110 encapsulates 95% of the exterior surface area of the at least one solar cell 108 and the encapsulant-backsheet layer of the backsheet 102 covers 5% of the exterior surface area of the at least one solar cell 108. In another embodiment, the encapsulant layer 110 encapsulates 100% of the exterior surface area of the at least one solar cell 108.

In some embodiments, the at least one layer has a thermal conductivity of 0.3 W m⁻¹ K⁻¹ to 3 W m⁻¹ K⁻¹. In some embodiments, the at least one layer has a thermal conductivity of 0.3 W m⁻¹ K⁻¹ to 2.9 W m⁻¹ K⁻¹. In some embodiments, the at least one layer has a thermal conductivity of 0.3 W m⁻¹ K⁻¹ to 2.8 W m⁻¹ K⁻¹. In some embodiments, the at least one layer has a thermal conductivity of 0.3 W m⁻¹ K⁻¹ to 2.7 W m⁻¹ K⁻¹. In some embodiments, the at least one layer has a thermal conductivity of 0.3 W m⁻¹ K⁻¹ to 2.6 W m⁻¹ K⁻¹. In some embodiments, the at least one layer has a thermal conductivity of 0.3 W m⁻¹ K⁻¹ to 2.5 W m⁻¹ K⁻¹. In some embodiments, the at least one layer has a thermal conductivity of 0.3 W m⁻¹ K⁻¹ to 2.4 W m⁻¹ K⁻¹. In some embodiments, the at least one layer has a thermal conductivity of 0.3 W m⁻¹ K⁻¹ to 2.3 W m⁻¹ K⁻¹. In some embodiments, the at least one layer has a thermal conductivity of 0.3 W m⁻¹ K⁻¹ to 2.2 W m⁻¹ K⁻¹. In some embodiments, the at least one layer has a thermal conductivity of 0.3 W m⁻¹ K⁻¹ to 2.1 W m⁻¹ K⁻¹. In some embodiments, the at least one layer has a thermal conductivity of 0.3 W m⁻¹ K⁻¹ to 2 W m⁻¹ K⁻¹. In some embodiments, the at least one layer has a thermal conductivity of 0.3 W m⁻¹ K⁻¹ to 1.9 W m⁻¹ K⁻¹. In some embodiments, the at least one layer has a thermal conductivity of 0.3 W m⁻¹ K⁻¹ to 1.8 W m⁻¹ K⁻¹. In some embodiments, the at least one layer has a thermal conductivity of 0.3 W m⁻¹ K⁻¹ to 1.7 W m⁻¹ K⁻¹. In some embodiments, the at least one layer has a thermal conductivity of 0.3 W m⁻¹ K⁻¹ to 1.6 W m⁻¹ K⁻¹. In some embodiments, the at least one layer has a thermal conductivity of 0.3 W m⁻¹ K⁻¹ to 1.5 W m⁻¹ K⁻¹. In some embodiments, the at least one layer has a thermal conductivity of 0.3 W m⁻¹ K⁻¹ to 1.4 W m⁻¹ K⁻¹. In some embodiments, the at least one layer has a thermal conductivity of 0.3 W m⁻¹ K⁻¹ to 1.3 W m⁻¹ K⁻¹. In some embodiments, the at least one layer has a thermal conductivity of 0.3 W m⁻¹ K⁻¹ to 1.2 W m⁻¹ K⁻¹. In some embodiments, the at least one layer has a thermal conductivity of 0.3 W m⁻¹ K⁻¹ to 1.1 W m⁻¹ K⁻¹. In some embodiments, the at least one layer has a thermal conductivity of 0.3 W m⁻¹ K⁻¹ to 1 W m⁻¹ K⁻¹. In some embodiments, the at least one layer has a thermal conductivity of 0.3 W m⁻¹ K⁻¹ to 0.9 W m⁻¹ K⁻¹. In some embodiments, the at least one layer has a thermal conductivity of 0.3 W m⁻¹ K⁻¹ to 0.8 W m⁻¹ K⁻¹. In some embodiments, the at least one layer has a thermal conductivity of 0.3 W m⁻¹ K⁻¹ to 0.7 W m⁻¹ K⁻¹. In some embodiments, the at least one layer has a thermal conductivity of 0.3 W m⁻¹ K⁻¹ to 0.6 W m⁻¹ K⁻¹. In some embodiments, the at least one layer has a thermal conductivity of 0.3 W m⁻¹ K⁻¹ to 0.5 W m⁻¹ K⁻¹. In some embodiments, the at least one layer has a thermal conductivity of 0.3 W m⁻¹ K⁻¹ to 0.4 W m⁻¹ K⁻¹.

In some embodiments, the at least one layer has a thermal conductivity of 0.3 W m⁻¹ K⁻¹ to 3 W m⁻¹ K⁻¹. In some embodiments, the at least one layer has a thermal conductivity of 0.4 W m⁻¹ K⁻¹ to 3 W m⁻¹ K⁻¹. In some embodiments, the at least one layer has a thermal conductivity of 0.5 W m⁻¹ K⁻¹ to 3 W m⁻¹ K⁻¹. In some embodiments, the at least one layer has a thermal conductivity of 0.6 W m⁻¹ K⁻¹ to 3 W m⁻¹ K⁻¹. In some embodiments, the at least one layer has a thermal conductivity of 0.7 W m⁻¹ K⁻¹ to 3 W m⁻¹ K⁻¹. In some embodiments, the at least one layer has a thermal conductivity of 0.8 W m⁻¹ K⁻¹ to 3 W m⁻¹ K⁻¹. In some embodiments, the at least one layer has a thermal conductivity of 0.9 W m⁻¹ K⁻¹ to 3 W m⁻¹ K⁻¹. In some embodiments, the at least one layer has a thermal conductivity of 1 W m⁻¹ K⁻¹ to 3 W m⁻¹ K⁻¹. In some embodiments, the at least one layer has a thermal conductivity of 1.1 W m⁻¹ K⁻¹ to 3 W m⁻¹ K⁻¹. In some embodiments, the at least one layer has a thermal conductivity of 1.2 W m⁻¹ K⁻¹ to 3 W m⁻¹ K⁻¹. In some embodiments, the at least one layer has a thermal conductivity of 1.3 W m⁻¹ K⁻¹ to 3 W m⁻¹ K⁻¹. In some embodiments, the at least one layer has a thermal conductivity of 1.4 W m⁻¹ K⁻¹ to 3 W m⁻¹ K⁻¹. In some embodiments, the at least one layer has a thermal conductivity of 1.5 W m⁻¹ K⁻¹ to 3 W m⁻¹ K⁻¹. In some embodiments, the at least one layer has a thermal conductivity of 1.6 W m⁻¹ K⁻¹ to 3 W m⁻¹ K⁻¹. In some embodiments, the at least one layer has a thermal conductivity of 1.7 W m⁻¹ K⁻¹ to 3 W m⁻¹ K⁻¹. In some embodiments, the at least one layer has a thermal conductivity of 1.8 W m⁻¹ K⁻¹ to 3 W m⁻¹ K⁻¹. In some embodiments, the at least one layer has a thermal conductivity of 1.9 W m⁻¹ K⁻¹ to 3 W m⁻¹ K⁻¹. In some embodiments, the at least one layer has a thermal conductivity of 2 W m⁻¹ K⁻¹ to 3 W m⁻¹ K⁻¹. In some embodiments, the at least one layer has a thermal conductivity of 2.1 W m⁻¹ K⁻¹ to 3 W m⁻¹ K⁻¹. In some embodiments, the at least one layer has a thermal conductivity of 2.2 W m⁻¹ K⁻¹ to 3 W m⁻¹ K⁻¹. In some embodiments, the at least one layer has a thermal conductivity of 2.3 W m⁻¹ K⁻¹ to 3 W m⁻¹ K⁻¹. In some embodiments, the at least one layer has a thermal conductivity of 2.4 W m⁻¹ K⁻¹ to 3 W m⁻¹ K⁻¹. In some embodiments, the at least one layer has a thermal conductivity of 2.5 W m⁻¹ K⁻¹ to 3 W m⁻¹ K⁻¹. In some embodiments, the at least one layer has a thermal conductivity of 2.6 W m⁻¹ K⁻¹ to 3 W m⁻¹ K⁻¹. In some embodiments, the at least one layer has a thermal conductivity of 2.7 W m⁻¹ K⁻¹ to 3 W m⁻¹ K⁻¹. In some embodiments, the at least one layer has a thermal conductivity of 2.8 W m⁻¹ K⁻¹ to 3 W m⁻¹ K⁻¹. In some embodiments, the at least one layer has a thermal conductivity of 2.9 W m⁻¹ K⁻¹ to 3 W m⁻¹ K⁻¹.

In some embodiments, the at least one layer has a thickness of 0.2 mm to 4 mm. In some embodiments, the at least one layer has a thickness of 0.2 mm to 3.5 mm. In some embodiments, the at least one layer has a thickness of 0.2 mm to 3 mm. In some embodiments, the at least one layer has a thickness of 0.2 mm to 2.5 mm. In some embodiments, the at least one layer has a thickness of 0.2 mm to 2 mm. In some embodiments, the at least one layer has a thickness of 0.2 mm to 1.5 mm. In some embodiments, the at least one layer has a thickness of 0.2 mm to 1 mm. In some embodiments, the at least one layer has a thickness of 0.2 mm to 0.5 mm. In some embodiments, the at least one layer has a thickness of 0.5 mm to 4 mm. In some embodiments, the at least one layer has a thickness of 1 mm to 4 mm. In some embodiments, the at least one layer has a thickness of 1.5 mm to 4 mm. In some embodiments, the at least one layer has a thickness of 2 mm to 4 mm. In some embodiments, the at least one layer has a thickness of 2.5 mm to 4 mm. In some embodiments, the at least one layer has a thickness of 3 mm to 4 mm. In some embodiments, the at least one layer has a thickness of 3.5 mm to 4 mm.

In some embodiments, the at least one layer has a thickness of 0.2 mm to 0.5 mm. In another embodiment, the at least one layer has a thickness of 0.2 mm to 0.4 mm. In another embodiment, the at least one layer has a thickness of 0.2 mm to 0.3 mm. In some embodiments, the at least one layer has a thickness of 0.3 mm to 0.5 mm. In another embodiment, the at least one layer has a thickness of 0.3 mm to 0.4 mm. In some embodiments, the at least one layer has a thickness of 0.4 mm to 0.5 mm. In some embodiments, the at least one layer has a thickness of 0.2 mm. In some embodiments, the at least one layer has a thickness of 0.3 mm. In some embodiments, the at least one layer has a thickness of 0.4 mm. In some embodiments, the at least one layer has a thickness of 0.5 mm.

In some embodiments, the at least one layer has a thickness of 1 mm to 5 mm. In some embodiments, the at least one layer has a thickness of 1 mm to 4 mm. In some embodiments, the at least one layer has a thickness of 1 mm to 3.5 mm. In some embodiments, the at least one layer has a thickness of 1 mm to 3 mm. In some embodiments, the at least one layer has a thickness of 1 mm to 2.5 mm. In some embodiments, the at least one layer has a thickness of 1 mm to 2 mm. In some embodiments, the at least one layer has a thickness of 1 mm to 1.5 mm. In some embodiments, the at least one layer has a thickness of 2 mm to 5 mm. In some embodiments, the at least one layer has a thickness of 2 mm to 4 mm. In some embodiments, the at least one layer has a thickness of 2 mm to 3.5 mm. In some embodiments, the at least one layer has a thickness of 2 mm to 3 mm. In some embodiments, the at least one layer has a thickness of 3 mm to 5 mm. In some embodiments, the at least one layer has a thickness of 3 mm to 4 mm. In some embodiments, the at least one layer has a thickness of 4 mm to 5 mm. In some embodiments, the at least one layer has a thickness of 1 mm. In some embodiments, the at least one layer has a thickness of 2 mm. In some embodiments, the at least one layer has a thickness of 3 mm. In some embodiments, the at least one layer has a thickness of 4 mm. In some embodiments, the at least one layer has a thickness of 5 mm.

In some embodiments, the at least one layer has a thickness of 1 mm to 10 mm. In some embodiments, the at least one layer has a thickness of 1 mm to 9 mm. In some embodiments, the at least one layer has a thickness of 1 mm to 8 mm. In some embodiments, the at least one layer has a thickness of 1 mm to 7 mm. In some embodiments, the at least one layer has a thickness of 1 mm to 6 mm. In some embodiments, the at least one layer has a thickness of 4 mm to 10 mm. In some embodiments, the at least one layer has a thickness of 5 mm to 10 mm. In some embodiments, the at least one layer has a thickness of 6 mm to 10 mm. In some embodiments, the at least one layer has a thickness of 7 mm to 10 mm. In some embodiments, the at least one layer has a thickness of 8 mm to 10 mm. In some embodiments, the at least one layer has a thickness of 9 mm to 10 mm.

In some embodiments, the backsheet 102 has a thickness of 1 mm to 10 mm. In some embodiments, the backsheet 102 has a thickness of 1 mm to 9 mm. In some embodiments, the backsheet 102 has a thickness of 1 mm to 8 mm. In some embodiments, the backsheet 102 has a thickness of 1 mm to 7 mm. In some embodiments, the backsheet 102 has a thickness of 1 mm to 6 mm. In some embodiments, the backsheet 102 has a thickness of 4 mm to 10 mm. In some embodiments, the backsheet 102 has a thickness of 5 mm to 10 mm. In some embodiments, the backsheet 102 has a thickness of 6 mm to 10 mm. In some embodiments, the backsheet 102 has a thickness of 7 mm to 10 mm. In some embodiments, the backsheet 102 has a thickness of 8 mm to 10 mm. In some embodiments, the backsheet 102 has a thickness of 9 mm to 10 mm. In some embodiments, the thickness of the backsheet 102 is different from a thickness of the encapsulant layer 110.

In some embodiments, the backsheet 102 has a thermal conductivity of 0.3 W m⁻¹ K⁻¹ to 3 W m⁻¹ K⁻¹. In some embodiments, the backsheet 102 has a thermal conductivity of 0.3 W m⁻¹ K⁻¹ to 2.9 W m⁻¹ K⁻¹. In some embodiments, the backsheet 102 has a thermal conductivity of 0.3 W m⁻¹ K⁻¹ to 2.8 W m⁻¹ K⁻¹. In some embodiments, the backsheet 102 has a thermal conductivity of 0.3 W m⁻¹ K⁻¹ to 2.7 W m⁻¹ K⁻¹. In some embodiments, the backsheet 102 has a thermal conductivity of 0.3 W m⁻¹ K⁻¹ to 2.6 W m⁻¹ K⁻¹. In some embodiments, the backsheet 102 has a thermal conductivity of 0.3 W m⁻¹ K⁻¹ to 2.5 W m⁻¹ K⁻¹. In some embodiments, the backsheet 102 has a thermal conductivity of 0.3 W m⁻¹ K⁻¹ to 2.4 W m⁻¹ K⁻¹. In some embodiments, the backsheet 102 has a thermal conductivity of 0.3 W m⁻¹ K⁻¹ to 2.3 W m⁻¹ K⁻¹. In some embodiments, the backsheet 102 has a thermal conductivity of 0.3 W m⁻¹ K⁻¹ to 2.2 W m⁻¹ K⁻¹. In some embodiments, the backsheet 102 has a thermal conductivity of 0.3 W m⁻¹ K⁻¹ to 2.1 W m⁻¹ K⁻¹. In some embodiments, the backsheet 102 has a thermal conductivity of 0.3 W m⁻¹ K⁻¹ to 2 W m⁻¹ K⁻¹. In some embodiments, the backsheet 102 has a thermal conductivity of 0.3 W m⁻¹ K⁻¹ to 1.9 W m⁻¹ K⁻¹. In some embodiments, the backsheet 102 has a thermal conductivity of 0.3 W m⁻¹ K⁻¹ to 1.8 W m⁻¹ K⁻¹. In some embodiments, the backsheet 102 has a thermal conductivity of 0.3 W m⁻¹ K⁻¹ to 1.7 W m⁻¹ K⁻¹. In some embodiments, the backsheet 102 has a thermal conductivity of 0.3 W m⁻¹ K⁻¹ to 1.6 W m⁻¹ K⁻¹. In some embodiments, the backsheet 102 has a thermal conductivity of 0.3 W m⁻¹ K⁻¹ to 1.5 W m⁻¹ K⁻¹. In some embodiments, the backsheet 102 has a thermal conductivity of 0.3 W m⁻¹ K⁻¹ to 1.4 W m⁻¹ K⁻¹. In some embodiments, the backsheet 102 has a thermal conductivity of 0.3 W m⁻¹ K⁻¹ to 1.3 W m⁻¹ K⁻¹. In some embodiments, the backsheet 102 has a thermal conductivity of 0.3 W m⁻¹ K⁻¹ to 1.2 W m⁻¹ K⁻¹. In some embodiments, the backsheet 102 has a thermal conductivity of 0.3 W m⁻¹ K⁻¹ to 1.1 W m⁻¹ K⁻¹. In some embodiments, the backsheet 102 has a thermal conductivity of 0.3 W m⁻¹ K⁻¹ to 1 W m⁻¹ K⁻¹. In some embodiments, the backsheet 102 has a thermal conductivity of 0.3 W m⁻¹ K⁻¹ to 0.9 W m⁻¹ K⁻¹. In some embodiments, the backsheet 102 has a thermal conductivity of 0.3 W m⁻¹ K⁻¹ to 0.8 W m⁻¹ K⁻¹. In some embodiments, the backsheet 102 has a thermal conductivity of 0.3 W m⁻¹ K⁻¹ to 0.7 W m⁻¹ K⁻¹. In some embodiments, the backsheet 102 has a thermal conductivity of 0.3 W m⁻¹ K⁻¹ to 0.6 W m⁻¹ K⁻¹. In some embodiments, the backsheet 102 has a thermal conductivity of 0.3 W m⁻¹ K⁻¹ to 0.5 W m⁻¹ K⁻¹. In some embodiments, the backsheet 102 has a thermal conductivity of 0.3 W m⁻¹ K⁻¹ to 0.4 W m⁻¹ K⁻¹.

In some embodiments, the backsheet 102 has a thermal conductivity of 0.3 W m⁻¹ K⁻¹ to 3 W m⁻¹ K⁻¹. In some embodiments, the backsheet 102 has a thermal conductivity of 0.4 W m⁻¹ K⁻¹ to 3 W m⁻¹ K⁻¹. In some embodiments, the backsheet 102 has a thermal conductivity of 0.5 W m⁻¹ K⁻¹ to 3 W m⁻¹ K⁻¹. In some embodiments, the backsheet 102 has a thermal conductivity of 0.6 W m⁻¹ K⁻¹ to 3 W m⁻¹ K⁻¹. In some embodiments, the backsheet 102 has a thermal conductivity of 0.7 W m⁻¹ K⁻¹ to 3 W m⁻¹ K⁻¹. In some embodiments, the backsheet 102 has a thermal conductivity of 0.8 W m⁻¹ K⁻¹ to 3 W m⁻¹ K⁻¹. In some embodiments, the backsheet 102 has a thermal conductivity of 0.9 W m⁻¹ K⁻¹ to 3 W m⁻¹ K⁻¹. In some embodiments, the backsheet 102 has a thermal conductivity of 1 W m⁻¹ K⁻¹ to 3 W m⁻¹ K⁻¹. In some embodiments, the backsheet 102 has a thermal conductivity of 1.1 W m⁻¹ K⁻¹ to 3 W m⁻¹ K⁻¹. In some embodiments, the backsheet 102 has a thermal conductivity of 1.2 W m⁻¹ K⁻¹ to 3 W m⁻¹ K⁻¹. In some embodiments, the backsheet 102 has a thermal conductivity of 1.3 W m⁻¹ K⁻¹ to 3 W m⁻¹ K⁻¹. In some embodiments, the backsheet 102 has a thermal conductivity of 1.4 W m⁻¹ K⁻¹ to 3 W m⁻¹ K⁻¹. In some embodiments, the backsheet 102 has a thermal conductivity of 1.5 W m⁻¹ K⁻¹ to 3 W m⁻¹ K⁻¹. In some embodiments, the backsheet 102 has a thermal conductivity of 1.6 W m⁻¹ K⁻¹ to 3 W m⁻¹ K⁻¹. In some embodiments, the backsheet 102 has a thermal conductivity of 1.7 W m⁻¹ K⁻¹ to 3 W m⁻¹ K⁻¹. In some embodiments, the backsheet 102 has a thermal conductivity of 1.8 W m⁻¹ K⁻¹ to 3 W m⁻¹ K⁻¹. In some embodiments, the backsheet 102 has a thermal conductivity of 1.9 W m⁻¹ K⁻¹ to 3 W m⁻¹ K⁻¹. In some embodiments, the backsheet 102 has a thermal conductivity of 2 W m⁻¹ K⁻¹ to 3 W m⁻¹ K⁻¹. In some embodiments, the backsheet 102 has a thermal conductivity of 2.1 W m⁻¹ K⁻¹ to 3 W m⁻¹ K⁻¹. In some embodiments, the backsheet 102 has a thermal conductivity of 2.2 W m⁻¹ K⁻¹ to 3 W m⁻¹ K⁻¹. In some embodiments, the backsheet 102 has a thermal conductivity of 2.3 W m⁻¹ K⁻¹ to 3 W m⁻¹ K⁻¹. In some embodiments, the backsheet 102 has a thermal conductivity of 2.4 W m⁻¹ K⁻¹ to 3 W m⁻¹ K⁻¹. In some embodiments, the backsheet 102 has a thermal conductivity of 2.5 W m⁻¹ K⁻¹ to 3 W m⁻¹ K⁻¹. In some embodiments, the backsheet 102 has a thermal conductivity of 2.6 W m⁻¹ K⁻¹ to 3 W m⁻¹ K⁻¹. In some embodiments, the backsheet 102 has a thermal conductivity of 2.7 W m⁻¹ K⁻¹ to 3 W m⁻¹ K⁻¹. In some embodiments, the backsheet 102 has a thermal conductivity of 2.8 W m⁻¹ K⁻¹ to 3 W m⁻¹ K⁻¹. In some embodiments, the backsheet 102 has a thermal conductivity of 2.9 W m⁻¹ K⁻¹ to 3 W m⁻¹ K⁻¹.

In some embodiments, the encapsulant layer 110 encapsulates 50% to 99.9% of an exterior surface area of the at least one solar cell 108. In another embodiment, the encapsulant layer 110 encapsulates 55% to 99.9% of an exterior surface area of the at least one solar cell 108. In another embodiment, the encapsulant layer 110 encapsulates 60% to 99.9% of an exterior surface area of the at least one solar cell 108. In another embodiment, the encapsulant layer 110 encapsulates 65% to 99.9% of an exterior surface area of the at least one solar cell 108. In another embodiment, the encapsulant layer 110 encapsulates 70% to 99.9% of an exterior surface area of the at least one solar cell 108. In another embodiment, the encapsulant layer 110 encapsulates 75% to 99.9% of an exterior surface area of the at least one solar cell 108. In another embodiment, the encapsulant layer 110 encapsulates 80% to 99.9% of an exterior surface area of the at least one solar cell 108. In another embodiment, the encapsulant layer 110 encapsulates 85% to 99.9% of an exterior surface area of the at least one solar cell 108. In another embodiment, the encapsulant layer 110 encapsulates 90% to 99.9% of an exterior surface area of the at least one solar cell 108. In another embodiment, the encapsulant layer 110 encapsulates 95% to 99.9% of an exterior surface area of the at least one solar cell 108.

In another embodiment, the encapsulant layer 110 encapsulates 50% to 95% of an exterior surface area of the at least one solar cell 108. In another embodiment, the encapsulant layer 110 encapsulates 55% to 95% of an exterior surface area of the at least one solar cell 108. In another embodiment, the encapsulant layer 110 encapsulates 60% to 95% of an exterior surface area of the at least one solar cell 108. In another embodiment, the encapsulant layer 110 encapsulates 65% to 95% of an exterior surface area of the at least one solar cell 108. In another embodiment, the encapsulant layer 110 encapsulates 70% to 95% of an exterior surface area of the at least one solar cell 108. In another embodiment, the encapsulant layer 110 encapsulates 75% to 95% of an exterior surface area of the at least one solar cell 108. In another embodiment, the encapsulant layer 110 encapsulates 80% to 95% of an exterior surface area of the at least one solar cell 108. In another embodiment, the encapsulant layer 110 encapsulates 85% to 95% of an exterior surface area of the at least one solar cell 108. In another embodiment, the encapsulant layer 110 encapsulates 90% to 95% of an exterior surface area of the at least one solar cell 108.

In another embodiment, the encapsulant layer 110 encapsulates 50% to 90% of an exterior surface area of the at least one solar cell 108. In another embodiment, the encapsulant layer 110 encapsulates 55% to 90% of an exterior surface area of the at least one solar cell 108. In another embodiment, the encapsulant layer 110 encapsulates 60% to 90% of an exterior surface area of the at least one solar cell 108. In another embodiment, the encapsulant layer 110 encapsulates 65% to 90% of an exterior surface area of the at least one solar cell 108. In another embodiment, the encapsulant layer 110 encapsulates 70% to 90% of an exterior surface area of the at least one solar cell 108. In another embodiment, the encapsulant layer 110 encapsulates 75% to 90% of an exterior surface area of the at least one solar cell 108. In another embodiment, the encapsulant layer 110 encapsulates 80% to 90% of an exterior surface area of the at least one solar cell 108. In another embodiment, the encapsulant layer 110 encapsulates 85% to 90% of an exterior surface area of the at least one solar cell 108.

In another embodiment, the encapsulant layer 110 encapsulates 50% to 85% of an exterior surface area of the at least one solar cell 108. In another embodiment, the encapsulant layer 110 encapsulates 55% to 85% of an exterior surface area of the at least one solar cell 108. In another embodiment, the encapsulant layer 110 encapsulates 60% to 85% of an exterior surface area of the at least one solar cell 108. In another embodiment, the encapsulant layer 110 encapsulates 65% to 85% of an exterior surface area of the at least one solar cell 108. In another embodiment, the encapsulant layer 110 encapsulates 70% to 85% of an exterior surface area of the at least one solar cell 108. In another embodiment, the encapsulant layer 110 encapsulates 75% to 85% of an exterior surface area of the at least one solar cell 108. In another embodiment, the encapsulant layer 110 encapsulates 80% to 85% of an exterior surface area of the at least one solar cell 108.

In another embodiment, the encapsulant layer 110 encapsulates 50% to 80% of an exterior surface area of the at least one solar cell 108. In another embodiment, the encapsulant layer 110 encapsulates 55% to 80% of an exterior surface area of the at least one solar cell 108. In another embodiment, the encapsulant layer 110 encapsulates 60% to 80% of an exterior surface area of the at least one solar cell 108. In another embodiment, the encapsulant layer 110 encapsulates 65% to 80% of an exterior surface area of the at least one solar cell 108. In another embodiment, the encapsulant layer 110 encapsulates 70% to 80% of an exterior surface area of the at least one solar cell 108. In another embodiment, the encapsulant layer 110 encapsulates 75% to 80% of an exterior surface area of the at least one solar cell 108.

In another embodiment, the encapsulant layer 110 encapsulates 50% to 75% of an exterior surface area of the at least one solar cell 108. In another embodiment, the encapsulant layer 110 encapsulates 55% to 75% of an exterior surface area of the at least one solar cell 108. In another embodiment, the encapsulant layer 110 encapsulates 60% to 75% of an exterior surface area of the at least one solar cell 108. In another embodiment, the encapsulant layer 110 encapsulates 65% to 75% of an exterior surface area of the at least one solar cell 108. In another embodiment, the encapsulant layer 110 encapsulates 70% to 75% of an exterior surface area of the at least one solar cell 108.

In another embodiment, the encapsulant layer 110 encapsulates 50% to 70% of an exterior surface area of the at least one solar cell 108. In another embodiment, the encapsulant layer 110 encapsulates 55% to 70% of an exterior surface area of the at least one solar cell 108. In another embodiment, the encapsulant layer 110 encapsulates 60% to 70% of an exterior surface area of the at least one solar cell 108. In another embodiment, the encapsulant layer 110 encapsulates 65% to 70% of an exterior surface area of the at least one solar cell 108.

In another embodiment, the encapsulant layer 110 encapsulates 50% to 65% of an exterior surface area of the at least one solar cell 108. In another embodiment, the encapsulant layer 110 encapsulates 55% to 65% of an exterior surface area of the at least one solar cell 108. In another embodiment, the encapsulant layer 110 encapsulates 60% to 65% of an exterior surface area of the at least one solar cell 108. In another embodiment, the encapsulant layer 110 encapsulates 50% to 60% of an exterior surface area of the at least one solar cell 108. In another embodiment, the encapsulant layer 110 encapsulates 55% to 60% of an exterior surface area of the at least one solar cell 108. In another embodiment, the encapsulant layer 110 encapsulates 55% to 60% of an exterior surface area of the at least one solar cell 108.

In some embodiments, the encapsulant layer 110 encapsulates 50% of an exterior surface area of the at least one solar cell 108. In another embodiment, the encapsulant layer 110 encapsulates 55% of the exterior surface area of the at least one solar cell 108. In another embodiment, the encapsulant layer 110 encapsulates 60% of the exterior surface area of the at least one solar cell 108. In another embodiment, the encapsulant layer 110 encapsulates 65% of the exterior surface area of the at least one solar cell 108. In another embodiment, the encapsulant layer 110 encapsulates 70% of the exterior surface area of the at least one solar cell 108. In another embodiment, the encapsulant layer 110 encapsulates 75% of the exterior surface area of the at least one solar cell 108. In another embodiment, the encapsulant layer 110 encapsulates 80% of the exterior surface area of the at least one solar cell 108. In another embodiment, the encapsulant layer 110 encapsulates 85% of the exterior surface area of the at least one solar cell 108. In another embodiment, the encapsulant layer 110 encapsulates 90% of the exterior surface area of the at least one solar cell 108. In another embodiment, the encapsulant layer 110 encapsulates 95% of the exterior surface area of the at least one solar cell 108. In another embodiment, the encapsulant layer 110 encapsulates 100% of the exterior surface area of the at least one solar cell 108.

In some embodiments, the encapsulant layer 110 has a thickness of 0.5 mm to 4 mm. In another embodiment, the encapsulant layer 110 has a thickness of 0.5 mm to 3.5 mm. In another embodiment, the encapsulant layer 110 has a thickness of 0.5 mm to 3 mm. In another embodiment, the encapsulant layer 110 has a thickness of 0.5 mm to 2.5 mm. In another embodiment, the encapsulant layer 110 has a thickness of 0.5 mm to 2 mm. In another embodiment, the encapsulant layer 110 has a thickness of 0.5 mm to 1.5 mm. In another embodiment, the encapsulant layer 110 has a thickness of 0.5 mm to 1 mm.

In some embodiments, the encapsulant layer 110 has a thickness of 1 mm to 4 mm. In another embodiment, the encapsulant layer 110 has a thickness of 1 mm to 3.5 mm. In another embodiment, the encapsulant layer 110 has a thickness of 1 mm to 3 mm. In another embodiment, the encapsulant layer 110 has a thickness of 1 mm to 2.5 mm. In another embodiment, the encapsulant layer 110 has a thickness of 1 mm to 2 mm. In another embodiment, the encapsulant layer 110 has a thickness of 1 mm to 1.5 mm. In some embodiments, the encapsulant layer 110 has a thickness of 1.5 mm to 4 mm. In another embodiment, the encapsulant layer 110 has a thickness of 1.5 mm to 3.5 mm. In another embodiment, the encapsulant layer 110 has a thickness of 1.5 mm to 3 mm. In another embodiment, the encapsulant layer 110 has a thickness of 1.5 mm to 2.5 mm. In another embodiment, the encapsulant layer 110 has a thickness of 1.5 mm to 2 mm.

In some embodiments, the encapsulant layer 110 has a thickness of 2 mm to 4 mm. In another embodiment, the encapsulant layer 110 has a thickness of 2 mm to 3.5 mm. In another embodiment, the encapsulant layer 110 has a thickness of 2 mm to 3 mm. In another embodiment, the encapsulant layer 110 has a thickness of 2 mm to 2.5 mm. In some embodiments, the encapsulant layer 110 has a thickness of 2.5 mm to 4 mm. In another embodiment, the encapsulant layer 110 has a thickness of 2.5 mm to 3.5 mm. In another embodiment, the encapsulant layer 110 has a thickness of 2.5 mm to 3 mm. In some embodiments, the encapsulant layer 110 has a thickness of 3 mm to 4 mm. In another embodiment, the encapsulant layer 110 has a thickness of 3 mm to 3.5 mm. In some embodiments, the encapsulant layer 110 has a thickness of 3.5 mm to 4 mm.

In some embodiments, the encapsulant layer 110 has a thickness of 0.5 mm. In some embodiments, the encapsulant layer 110 has a thickness of 0.6 mm. In some embodiments, the encapsulant layer 110 has a thickness of 0.7 mm. In some embodiments, the encapsulant layer 110 has a thickness of 0.8 mm. In some embodiments, the encapsulant layer 110 has a thickness of 0.9 mm. In some embodiments, the encapsulant layer 110 has a thickness of 1 mm. In some embodiments, the encapsulant layer 110 has a thickness of 1.5 mm. In some embodiments, the encapsulant layer 110 has a thickness of 2 mm. In some embodiments, the encapsulant layer 110 has a thickness of 2.5 mm. In some embodiments, the encapsulant layer 110 has a thickness of 3 mm. In some embodiments, the encapsulant layer 110 has a thickness of 3.5 mm. In some embodiments, the encapsulant layer 110 has a thickness of 4 mm.

In some embodiments, the encapsulant layer 110 has a thickness of 0.2 mm to 2 mm. In some embodiments, the encapsulant layer 110 has a thickness of 0.2 mm to 1.5 mm. In some embodiments, the encapsulant layer 110 has a thickness of 0.2 mm to 1 mm. In some embodiments, the encapsulant layer 110 has a thickness of 0.2 mm to 0.6 mm. In some embodiments, the encapsulant layer 110 has a thickness of 0.2 mm to 0.5 mm. In some embodiments, the encapsulant layer 110 has a thickness of 0.5 mm to 2 mm. In some embodiments, the encapsulant layer 110 has a thickness of 0.5 mm to 1.5 mm. In some embodiments, the encapsulant layer 110 has a thickness of 0.5 mm to 1 mm. In some embodiments, the encapsulant layer 110 has a thickness of 1 mm to 2 mm. In some embodiments, the encapsulant layer 110 has a thickness of 1 mm to 1.5 mm. In some embodiments, the encapsulant layer 110 has a thickness of 1.5 mm to 2 mm.

In some embodiments, the encapsulant layer 110 has a thickness of 0.2 mm. In some embodiments, the encapsulant layer 110 has a thickness of 0.3 mm. In some embodiments, the encapsulant layer 110 has a thickness of 0.4 mm. In some embodiments, the encapsulant layer 110 has a thickness of 0.45 mm. In some embodiments, the encapsulant layer 110 has a thickness of 0.5 mm. In some embodiments, the encapsulant layer 110 has a thickness of 0.6 mm. In some embodiments, the encapsulant layer 110 has a thickness of 1 mm. In some embodiments, the encapsulant layer 110 has a thickness of 1.5 mm. In some embodiments, the encapsulant layer 110 has a thickness of 2 mm. In some embodiments, the encapsulant layer 110 has a thickness of 2.5 mm. In some embodiments, the encapsulant layer 110 has a thickness of 3 mm. In some embodiments, the encapsulant layer 110 has a thickness of 3.5 mm. In some embodiments, the encapsulant layer 110 has a thickness of 4 mm.

In some embodiments, the at least one solar cell 108 includes a plurality of the solar cells. In some embodiments, the plurality of solar cells includes two solar cells. In some embodiments, the plurality of solar cells includes three solar cells. In some embodiments, the plurality of solar cells includes four solar cells. In some embodiments, the plurality of solar cells includes five solar cells. In some embodiments, the plurality of solar cells includes six solar cells. In some embodiments, the plurality of solar cells includes seven solar cells. In some embodiments, the plurality of solar cells includes eight solar cells. In some embodiments, the plurality of solar cells includes nine solar cells. In some embodiments, the plurality of solar cells includes ten solar cells. In some embodiments, the plurality of solar cells includes eleven solar cells. In some embodiments, the plurality of solar cells includes twelve solar cells. In some embodiments, the plurality of solar cells includes thirteen solar cells. In some embodiments, the plurality of solar cells includes fourteen solar cells. In some embodiments, the plurality of solar cells includes fifteen solar cells. In some embodiments, the plurality of solar cells includes sixteen solar cells. In some embodiments, the plurality of solar cells includes more than sixteen solar cells.

In some embodiments, the plurality of solar cells is arranged in one row (i.e., one reveal). In another embodiment, the plurality of solar cells is arranged in two rows (i.e., two reveals). In another embodiment, the plurality of solar cells is arranged in three rows (i.e., three reveals). In another embodiment, the plurality of solar cells is arranged in four rows (i.e., four reveals). In another embodiment, the plurality of solar cells is arranged in five rows (i.e., five reveals). In another embodiment, the plurality of solar cells is arranged in six rows (i.e., six reveals). In other embodiments, the plurality of solar cells is arranged in more than six rows.

In some embodiments, the frontsheet 104 comprises a glass layer 112, a polymer layer 116, and an adhesive layer 114 between the glass layer 112 and the polymer layer 116. In some embodiments, the glass layer 112 is juxtaposed with the encapsulant layer 110. In some embodiments, a first surface of the glass layer 112 is juxtaposed with a second surface of the encapsulant layer 110. In some embodiments, the adhesive layer 114 is juxtaposed with the glass layer 112. In some embodiments, a first surface of the adhesive layer 114 is juxtaposed with a second surface of the glass layer 112. In some embodiments, the polymer layer is juxtaposed with the adhesive layer. In some embodiments, a first surface of the polymer layer 116 is juxtaposed with a second surface of the adhesive layer 114. In some embodiments, a second surface of the polymer layer 116 is an upper, sun facing-side surface of the photovoltaic module 100.

In some embodiments, each of the encapsulant layer 110, the glass layer 112, and the polymer layer 116 is transparent. In some embodiments, the polymer layer 116 is attached to the glass layer 112 by an adhesive layer 114. In some embodiments, the adhesive layer 114 may include polyvinyl butyrate, acrylic, silicone, or polycarbonate. In another embodiment, the adhesive layer 114 may include pressure sensitive adhesives. In another embodiment, the polymer layer 116 is attached to the glass layer 112 by thermal bonding. In another embodiment, the frontsheet 104 includes at least one of the glass layer 112 or the polymer layer 116. In some embodiments, the adhesive layer 114 is transparent. As used herein, the term “transparent” means having a solar weighted transmittance of 80% or greater, and with respect to certain embodiments of the photovoltaic module 100, a transparent layer of the photovoltaic module has a solar weighted transmittance of 80% or greater. In another embodiment, the frontsheet 104 does not include the glass layer 112.

In some embodiments, the glass layer 112 has a thickness of 1 mm to 4 mm. In some embodiments, the glass layer 112 has a thickness of 1 mm to 3.5 mm. In some embodiments, the glass layer 112 has a thickness of 1 mm to 3 mm. In some embodiments, the glass layer 112 has a thickness of 1 mm to 2.5 mm. In some embodiments, the glass layer 112 has a thickness of 1 mm to 2 mm. In some embodiments, the glass layer 112 has a thickness of 1 mm to 1.5 mm. In some embodiments, the glass layer 112 has a thickness of 1.5 mm to 4 mm. In some embodiments, the glass layer 112 has a thickness of 1.5 mm to 3.5 mm. In some embodiments, the glass layer 112 has a thickness of 1.5 mm to 3 mm. In some embodiments, the glass layer 112 has a thickness of 1 mm to 2.5 mm. In some embodiments, the glass layer 112 has a thickness of 1.5 mm to 2 mm.

In some embodiments, the glass layer 112 has a thickness of 2 mm to 4 mm. In some embodiments, the glass layer 112 has a thickness of 2 mm to 3.5 mm. In some embodiments, the glass layer 112 has a thickness of 2 mm to 3 mm. In some embodiments, the glass layer 112 has a thickness of 2 mm to 2.5 mm. In some embodiments, the glass layer 112 has a thickness of 2.5 mm to 4 mm. In some embodiments, the glass layer 112 has a thickness of 2.5 mm to 3.5 mm. In some embodiments, the glass layer 112 has a thickness of 2.5 mm to 3 mm. In some embodiments, the glass layer 112 has a thickness of 3 mm to 4 mm. In some embodiments, the glass layer 112 has a thickness of 3 mm to 3.5 mm. In some embodiments, the glass layer 112 has a thickness of 3.5 mm to 4 mm.

In some embodiments, the glass layer 112 has a thickness of 1 mm. In some embodiments, the glass layer 112 has a thickness of 1.5 mm. In some embodiments, the glass layer 112 has a thickness of 2 mm. In some embodiments, the glass layer 112 has a thickness of 2.5 mm. In some embodiments, the glass layer 112 has a thickness of 3 mm. In some embodiments, the glass layer 112 has a thickness of 3.5 mm. In some embodiments, the glass layer 112 has a thickness of 4 mm.

In some embodiments, the adhesive layer 114 is composed of thermosetting polyolefin, thermosetting polyolefin encapsulant material, thermosetting ethylene-vinyl acetate (EVA), EVA encapsulants, thermoplastic olefin, thermoplastic polyolefin (TPO) or hybrids/combinations thereof.

In some embodiments, the adhesive layer 114 has a thickness of 0.2 mm to 2 mm. In some embodiments, the adhesive layer 114 has a thickness of 0.2 mm to 1.5 mm. In some embodiments, the adhesive layer 114 has a thickness of 0.2 mm to 1 mm. In some embodiments, the adhesive layer 114 has a thickness of 0.2 mm to 0.5 mm. In some embodiments, the adhesive layer 114 has a thickness of 0.5 mm to 2 mm. In some embodiments, the adhesive layer 114 has a thickness of 0.5 mm to 1.5 mm. In some embodiments, the adhesive layer 114 has a thickness of 0.5 mm to 1 mm. In some embodiments, the adhesive layer 114 has a thickness of 1 mm to 2 mm. In some embodiments, the adhesive layer 114 has a thickness of 1 mm to 1.5 mm. In some embodiments, the adhesive layer 114 has a thickness of 1.5 mm to 2 mm.

In some embodiments, the adhesive layer 114 has a thickness of 0.2 mm. In some embodiments, the adhesive layer 114 has a thickness of 0.3 mm. In some embodiments, the adhesive layer 114 has a thickness of 0.4 mm. In some embodiments, the adhesive layer 114 has a thickness of 0.45 mm. In some embodiments, the adhesive layer 114 has a thickness of 0.5 mm. In some embodiments, the adhesive layer 114 has a thickness of 1 mm. In some embodiments, the adhesive layer 114 has a thickness of 1.5 mm. In some embodiments, the adhesive layer 114 has a thickness of 2 mm. In some embodiments, the adhesive layer 114 has a thickness of 2.5 mm. In some embodiments, the adhesive layer 114 has a thickness of 3 mm. In some embodiments, the adhesive layer 114 has a thickness of 3.5 mm. In some embodiments, the adhesive layer 114 has a thickness of 4 mm.

In another embodiment, the adhesive layer 114 has a thickness of 1 μm to 900 μm. In some embodiments, the adhesive layer 114 has a thickness of 1 μm to 900 μm. In some embodiments, the adhesive layer 114 has a thickness of 1 μm to 850 μm. In some embodiments, the adhesive layer 114 has a thickness of 1 μm to 800 μm. In some embodiments, the adhesive layer 114 has a thickness of 1 μm to 750 μm. In some embodiments, the adhesive layer 114 has a thickness of 1 μm to 700 μm. In some embodiments, the adhesive layer 114 has a thickness of 1 μm to 650 μm. In some embodiments, the adhesive layer 114 has a thickness of 1 μm to 600 μm. In some embodiments, the adhesive layer 114 has a thickness of 1 μm to 550 μm. In some embodiments, the adhesive layer 114 has a thickness of 1 μm to 500 μm. In some embodiments, the adhesive layer 114 has a thickness of 1 μm to 450 μm. In some embodiments, the adhesive layer 114 has a thickness of 1 μm to 400 μm. In some embodiments, the adhesive layer 114 has a thickness of 1 μm to 350 μm. In some embodiments, the adhesive layer 114 has a thickness of 1 μm to 300 μm. In some embodiments, the adhesive layer 114 has a thickness of 1 μm to 250 μm. In some embodiments, the adhesive layer 114 has a thickness of 1 μm to 200 μm. In some embodiments, the adhesive layer 114 has a thickness of 1 μm to 150 μm. In some embodiments, the adhesive layer 114 has a thickness of 1 μm to 100 μm. In some embodiments, the adhesive layer 114 has a thickness of 1 μm to 50 μm.

In some embodiments, the adhesive layer 114 has a thickness of 50 μm to 900 μm. In some embodiments, the adhesive layer 114 has a thickness of 50 μm to 850 μm. In some embodiments, the adhesive layer 114 has a thickness of 50 μm to 800 μm. In some embodiments, the adhesive layer 114 has a thickness of 50 μm to 750 μm. In some embodiments, the adhesive layer 114 has a thickness of 50 μm to 700 μm. In some embodiments, the adhesive layer 114 has a thickness of 50 μm to 650 μm. In some embodiments, the adhesive layer 114 has a thickness of 50 μm to 600 μm. In some embodiments, the adhesive layer 114 has a thickness of 50 μm to 550 μm. In some embodiments, the adhesive layer 114 has a thickness of 50 μm to 500 μm. In some embodiments, the adhesive layer 114 has a thickness of 50 μm to 450 μm. In some embodiments, the adhesive layer 114 has a thickness of 50 μm to 400 μm. In some embodiments, the adhesive layer 114 has a thickness of 50 μm to 350 μm. In some embodiments, the adhesive layer 114 has a thickness of 50 μm to 300 μm. In some embodiments, the adhesive layer 114 has a thickness of 50 μm to 250 μm. In some embodiments, the adhesive layer 114 has a thickness of 50 μm to 200 μm. In some embodiments, the adhesive layer 114 has a thickness of 50 μm to 150 μm. In some embodiments, the adhesive layer 114 has a thickness of 50 μm to 100 μm.

In some embodiments, the adhesive layer 114 has a thickness of 100 μm to 900 μm. In some embodiments, the adhesive layer 114 has a thickness of 100 μm to 850 μm. In some embodiments, the adhesive layer 114 has a thickness of 100 μm to 800 μm. In some embodiments, the adhesive layer 114 has a thickness of 100 μm to 750 μm. In some embodiments, the adhesive layer 114 has a thickness of 100 μm to 700 μm. In some embodiments, the adhesive layer 114 has a thickness of 100 μm to 650 μm. In some embodiments, the adhesive layer 114 has a thickness of 100 μm to 600 μm. In some embodiments, the adhesive layer 114 has a thickness of 100 μm to 550 μm. In some embodiments, the adhesive layer 114 has a thickness of 100 μm to 500 μm. In some embodiments, the adhesive layer 114 has a thickness of 100 μm to 450 μm. In some embodiments, the adhesive layer 114 has a thickness of 100 μm to 400 μm. In some embodiments, the adhesive layer 114 has a thickness of 100 μm to 350 μm. In some embodiments, the adhesive layer 114 has a thickness of 100 μm to 300 μm. In some embodiments, the adhesive layer 114 has a thickness of 100 μm to 250 μm. In some embodiments, the adhesive layer 114 has a thickness of 100 μm to 200 μm. In some embodiments, the adhesive layer 114 has a thickness of 100 μm to 150 μm.

In some embodiments, the adhesive layer 114 has a thickness of 150 μm to 900 μm. In some embodiments, the adhesive layer 114 has a thickness of 150 μm to 850 μm. In some embodiments, the adhesive layer 114 has a thickness of 150 μm to 800 μm. In some embodiments, the adhesive layer 114 has a thickness of 150 μm to 750 μm. In some embodiments, the adhesive layer 114 has a thickness of 150 μm to 700 μm. In some embodiments, the adhesive layer 114 has a thickness of 150 μm to 650 μm. In some embodiments, the adhesive layer 114 has a thickness of 150 μm to 600 μm. In some embodiments, the adhesive layer 114 has a thickness of 150 μm to 550 μm. In some embodiments, the adhesive layer 114 has a thickness of 150 μm to 500 μm. In some embodiments, the adhesive layer 114 has a thickness of 150 μm to 450 μm. In some embodiments, the adhesive layer 114 has a thickness of 150 μm to 400 μm. In some embodiments, the adhesive layer 114 has a thickness of 150 μm to 350 μm. In some embodiments, the adhesive layer 114 has a thickness of 150 μm to 300 μm. In some embodiments, the adhesive layer 114 has a thickness of 150 μm to 250 μm. In some embodiments, the adhesive layer 114 has a thickness of 150 μm to 200 μm.

In some embodiments, the adhesive layer 114 has a thickness of 200 μm to 900 μm. In some embodiments, the adhesive layer 114 has a thickness of 200 μm to 850 μm. In some embodiments, the adhesive layer 114 has a thickness of 200 μm to 800 μm. In some embodiments, the adhesive layer 114 has a thickness of 200 μm to 750 μm. In some embodiments, the adhesive layer 114 has a thickness of 200 μm to 700 μm. In some embodiments, the adhesive layer 114 has a thickness of 200 μm to 650 μm. In some embodiments, the adhesive layer 114 has a thickness of 200 μm to 600 μm. In some embodiments, the adhesive layer 114 has a thickness of 200 μm to 550 μm. In some embodiments, the adhesive layer 114 has a thickness of 200 μm to 500 μm. In some embodiments, the adhesive layer 114 has a thickness of 200 μm to 450 μm. In some embodiments, the adhesive layer 114 has a thickness of 200 μm to 400 μm. In some embodiments, the adhesive layer 114 has a thickness of 200 μm to 350 μm. In some embodiments, the adhesive layer 114 has a thickness of 200 μm to 300 μm. In some embodiments, the adhesive layer 114 has a thickness of 200 μm to 250 μm.

In some embodiments, the adhesive layer 114 has a thickness of 250 μm to 900 μm. In some embodiments, the adhesive layer 114 has a thickness of 250 μm to 850 μm. In some embodiments, the adhesive layer 114 has a thickness of 250 μm to 800 μm. In some embodiments, the adhesive layer 114 has a thickness of 250 μm to 750 μm. In some embodiments, the adhesive layer 114 has a thickness of 250 μm to 700 μm. In some embodiments, the adhesive layer 114 has a thickness of 250 μm to 650 μm. In some embodiments, the adhesive layer 114 has a thickness of 250 μm to 600 μm. In some embodiments, the adhesive layer 114 has a thickness of 250 μm to 550 μm. In some embodiments, the adhesive layer 114 has a thickness of 250 μm to 500 μm. In some embodiments, the adhesive layer 114 has a thickness of 250 μm to 450 μm. In some embodiments, the adhesive layer 114 has a thickness of 250 μm to 400 μm. In some embodiments, the adhesive layer 114 has a thickness of 250 μm to 350 μm. In some embodiments, the adhesive layer 114 has a thickness of 250 μm to 300 μm.

In some embodiments, the adhesive layer 114 has a thickness of 300 μm to 900 μm. In some embodiments, the adhesive layer 114 has a thickness of 300 μm to 850 μm. In some embodiments, the adhesive layer 114 has a thickness of 300 μm to 800 μm. In some embodiments, the adhesive layer 114 has a thickness of 300 μm to 750 μm. In some embodiments, the adhesive layer 114 has a thickness of 300 μm to 700 μm. In some embodiments, the adhesive layer 114 has a thickness of 300 μm to 650 μm. In some embodiments, the adhesive layer 114 has a thickness of 300 μm to 600 μm. In some embodiments, the adhesive layer 114 has a thickness of 300 μm to 550 μm. In some embodiments, the adhesive layer 114 has a thickness of 300 μm to 500 μm. In some embodiments, the adhesive layer 114 has a thickness of 300 μm to 450 μm. In some embodiments, the adhesive layer 114 has a thickness of 300 μm to 400 μm. In some embodiments, the adhesive layer 114 has a thickness of 300 μm to 350 μm.

In some embodiments, the adhesive layer 114 has a thickness of 350 μm to 900 μm. In some embodiments, the adhesive layer 114 has a thickness of 350 μm to 850 μm. In some embodiments, the adhesive layer 114 has a thickness of 350 μm to 800 μm. In some embodiments, the adhesive layer 114 has a thickness of 350 μm to 750 μm. In some embodiments, the adhesive layer 114 has a thickness of 350 μm to 700 μm. In some embodiments, the adhesive layer 114 has a thickness of 350 μm to 650 μm. In some embodiments, the adhesive layer 114 has a thickness of 350 μm to 600 μm. In some embodiments, the adhesive layer 114 has a thickness of 350 μm to 550 μm. In some embodiments, the adhesive layer 114 has a thickness of 350 μm to 500 μm. In some embodiments, the adhesive layer 114 has a thickness of 350 μm to 450 μm. In some embodiments, the adhesive layer 114 has a thickness of 350 μm to 400 μm.

In some embodiments, the adhesive layer 114 has a thickness of 400 μm to 900 μm. In some embodiments, the adhesive layer 114 has a thickness of 400 μm to 850 μm. In some embodiments, the adhesive layer 114 has a thickness of 400 μm to 800 μm. In some embodiments, the adhesive layer 114 has a thickness of 400 μm to 750 μm. In some embodiments, the adhesive layer 114 has a thickness of 400 μm to 700 μm. In some embodiments, the adhesive layer 114 has a thickness of 400 μm to 650 μm. In some embodiments, the adhesive layer 114 has a thickness of 400 μm to 600 μm. In some embodiments, the adhesive layer 114 has a thickness of 400 μm to 550 μm. In some embodiments, the adhesive layer 114 has a thickness of 400 μm to 500 μm. In some embodiments, the adhesive layer 114 has a thickness of 400 μm to 450 μm.

In some embodiments, the adhesive layer 114 has a thickness of 450 μm to 900 μm. In some embodiments, the adhesive layer 114 has a thickness of 450 μm to 850 μm. In some embodiments, the adhesive layer 114 has a thickness of 450 μm to 800 μm. In some embodiments, the adhesive layer 114 has a thickness of 450 μm to 750 μm. In some embodiments, the adhesive layer 114 has a thickness of 450 μm to 700 μm. In some embodiments, the adhesive layer 114 has a thickness of 450 μm to 650 μm. In some embodiments, the adhesive layer 114 has a thickness of 450 μm to 600 μm. In some embodiments, the adhesive layer 114 has a thickness of 450 μm to 550 μm. In some embodiments, the adhesive layer 114 has a thickness of 450 μm to 500 μm.

In some embodiments, the adhesive layer 114 has a thickness of 500 μm to 900 μm. In some embodiments, the adhesive layer 114 has a thickness of 500 μm to 850 μm. In some embodiments, the adhesive layer 114 has a thickness of 500 μm to 800 μm. In some embodiments, the adhesive layer 114 has a thickness of 500 μm to 750 μm. In some embodiments, the adhesive layer 114 has a thickness of 500 μm to 700 μm. In some embodiments, the adhesive layer 114 has a thickness of 500 μm to 650 μm. In some embodiments, the adhesive layer 114 has a thickness of 500 μm to 600 μm. In some embodiments, the adhesive layer 114 has a thickness of 500 μm to 550 μm.

In some embodiments, the adhesive layer 114 has a thickness of 550 μm to 900 μm. In some embodiments, the adhesive layer 114 has a thickness of 550 μm to 850 μm. In some embodiments, the adhesive layer 114 has a thickness of 550 μm to 800 μm. In some embodiments, the adhesive layer 114 has a thickness of 550 μm to 750 μm. In some embodiments, the adhesive layer 114 has a thickness of 550 μm to 700 μm. In some embodiments, the adhesive layer 114 has a thickness of 550 μm to 650 μm. In some embodiments, the adhesive layer 114 has a thickness of 550 μm to 600 μm.

In some embodiments, the adhesive layer 114 has a thickness of 600 μm to 900 μm. In some embodiments, the adhesive layer 114 has a thickness of 600 μm to 850 μm. In some embodiments, the adhesive layer 114 has a thickness of 600 μm to 800 μm. In some embodiments, the adhesive layer 114 has a thickness of 600 μm to 750 μm. In some embodiments, the adhesive layer 114 has a thickness of 600 μm to 700 μm. In some embodiments, the adhesive layer 114 has a thickness of 600 μm to 650 μm.

In some embodiments, the adhesive layer 114 has a thickness of 650 μm to 900 μm. In some embodiments, the adhesive layer 114 has a thickness of 650 μm to 850 μm. In some embodiments, the adhesive layer 114 has a thickness of 650 μm to 800 μm. In some embodiments, the adhesive layer 114 has a thickness of 650 μm to 750 μm. In some embodiments, the adhesive layer 114 has a thickness of 650 μm to 700 μm. In some embodiments, the adhesive layer 114 has a thickness of 700 μm to 900 μm. In some embodiments, the adhesive layer 114 has a thickness of 700 μm to 850 μm. In some embodiments, the adhesive layer 114 has a thickness of 700 μm to 800 μm. In some embodiments, the adhesive layer 114 has a thickness of 700 μm to 750 μm. In some embodiments, the adhesive layer 114 has a thickness of 750 μm to 900 μm. In some embodiments, the adhesive layer 114 has a thickness of 750 μm to 850 μm. In some embodiments, the adhesive layer 114 has a thickness of 750 μm to 800 μm. In some embodiments, the adhesive layer 114 has a thickness of 800 μm to 900 μm. In some embodiments, the adhesive layer 114 has a thickness of 800 μm to 850 μm. In some embodiments, the adhesive layer 114 has a thickness of 850 μm to 900 μm.

In some embodiments, the adhesive layer 114 has a thickness of 1 μm. In some embodiments, the adhesive layer 114 has a thickness of 50 μm. In some embodiments, the adhesive layer 114 has a thickness of 100 μm. In some embodiments, the adhesive layer 114 has a thickness of 1 μm. In some embodiments, the adhesive layer 114 has a thickness of 150 μm. In some embodiments, the adhesive layer 114 has a thickness of 200 μm. In some embodiments, the adhesive layer 114 has a thickness of 250 μm. In some embodiments, the adhesive layer 114 has a thickness of 300 μm. In some embodiments, the adhesive layer 114 has a thickness of 350 μm. In some embodiments, the adhesive layer 114 has a thickness of 400 μm. In some embodiments, the adhesive layer 114 has a thickness of 450 μm. In some embodiments, the adhesive layer 114 has a thickness of 500 μm. In some embodiments, the adhesive layer 114 has a thickness of 550 μm. In some embodiments, the adhesive layer 114 has a thickness of 600 μm. In some embodiments, the adhesive layer 114 has a thickness of 650 μm. In some embodiments, the adhesive layer 114 has a thickness of 700 μm. In some embodiments, the adhesive layer 114 has a thickness of 750 μm. In some embodiments, the adhesive layer 114 has a thickness of 800 μm. In some embodiments, the adhesive layer 114 has a thickness of 850 μm. In some embodiments, the adhesive layer 114 has a thickness of 900 μm.

In some embodiments, the polymer layer 116 is composed of a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In some embodiments, the frontsheet is composed of fluoropolymers, acrylics, polyesters, silicones, polycarbonates, or combinations thereof. In other embodiments, the polymer layer 116 is composed of polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In some embodiments, the polymer layer 116 is composed of a crosslinked polymeric material. In some embodiments, 50% to 99% of the polymer chains of the polymeric material are crosslinked.

In some embodiments, the polymer layer 116 has a thickness of 0.01 mm to 0.5 mm. In some embodiments, the polymer layer 116 has a thickness of 0.01 mm to 0.45 mm. In some embodiments, the polymer layer 116 has a thickness of 0.01 mm to 0.4 mm. In some embodiments, the polymer layer 116 has a thickness of 0.01 mm to 0.35 mm. In some embodiments, the polymer layer 116 has a thickness of 0.01 mm to 0.3 mm. In some embodiments, the polymer layer 116 has a thickness of 0.01 mm to 0.25 mm. In some embodiments, the polymer layer 116 has a thickness of 0.01 mm to 0.2 mm. In some embodiments, the polymer layer 116 has a thickness of 0.01 mm to 0.15 mm. In some embodiments, the polymer layer 116 has a thickness of 0.01 mm to 0.1 mm. In some embodiments, the polymer layer 116 has a thickness of 0.01 mm to 0.05 mm.

In some embodiments, the polymer layer 116 has a thickness of 0.05 mm to 0.5 mm. In some embodiments, the polymer layer 116 has a thickness of 0.05 mm to 0.45 mm. In some embodiments, the polymer layer 116 has a thickness of 0.05 mm to 0.4 mm. In some embodiments, the polymer layer 116 has a thickness of 0.05 mm to 0.35 mm. In some embodiments, the polymer layer 116 has a thickness of 0.05 mm to 0.3 mm. In some embodiments, the polymer layer 116 has a thickness of 0.05 mm to 0.25 mm. In some embodiments, the polymer layer 116 has a thickness of 0.05 mm to 0.2 mm. In some embodiments, the polymer layer 116 has a thickness of 0.05 mm to 0.15 mm. In some embodiments, the polymer layer 116 has a thickness of 0.05 mm to 0.1 mm.

In some embodiments, the polymer layer 116 has a thickness of 0.1 mm to 0.5 mm. In some embodiments, the polymer layer 116 has a thickness of 0.1 mm to 0.45 mm. In some embodiments, the polymer layer 116 has a thickness of 0.1 mm to 0.4 mm. In some embodiments, the polymer layer 116 has a thickness of 0.1 mm to 0.35 mm. In some embodiments, the polymer layer 116 has a thickness of 0.1 mm to 0.3 mm. In some embodiments, the polymer layer 116 has a thickness of 0.1 mm to 0.25 mm. In some embodiments, the polymer layer 116 has a thickness of 0.1 mm to 0.2 mm. In some embodiments, the polymer layer 116 has a thickness of 0.1 mm to 0.15 mm. In some embodiments, the polymer layer 116 has a thickness of 0.15 mm to 0.5 mm. In some embodiments, the polymer layer 116 has a thickness of 0.15 mm to 0.45 mm. In some embodiments, the polymer layer 116 has a thickness of 0.15 mm to 0.4 mm. In some embodiments, the polymer layer 116 has a thickness of 0.15 mm to 0.35 mm. In some embodiments, the polymer layer 116 has a thickness of 0.15 mm to 0.3 mm. In some embodiments, the polymer layer 116 has a thickness of 0.15 mm to 0.25 mm. In some embodiments, the polymer layer 116 has a thickness of 0.15 mm to 0.2 mm.

In some embodiments, the polymer layer 116 has a thickness of 0.2 mm to 0.5 mm. In some embodiments, the polymer layer 116 has a thickness of 0.2 mm to 0.45 mm. In some embodiments, the polymer layer 116 has a thickness of 0.2 mm to 0.4 mm. In some embodiments, the polymer layer 116 has a thickness of 0.2 mm to 0.35 mm. In some embodiments, the polymer layer 116 has a thickness of 0.2 mm to 0.3 mm. In some embodiments, the polymer layer 116 has a thickness of 0.2 mm to 0.25 mm. In some embodiments, the polymer layer 116 has a thickness of 0.25 mm to 0.5 mm. In some embodiments, the polymer layer 116 has a thickness of 0.25 mm to 0.45 mm. In some embodiments, the polymer layer 116 has a thickness of 0.25 mm to 0.4 mm. In some embodiments, the polymer layer 116 has a thickness of 0.25 mm to 0.35 mm. In some embodiments, the polymer layer 116 has a thickness of 0.25 mm to 0.3 mm.

In some embodiments, the polymer layer 116 has a thickness of 0.3 mm to 0.5 mm. In some embodiments, the polymer layer 116 has a thickness of 0.3 mm to 0.45 mm. In some embodiments, the polymer layer 116 has a thickness of 0.3 mm to 0.4 mm. In some embodiments, the polymer layer 116 has a thickness of 0.3 mm to 0.35 mm. In some embodiments, the polymer layer 116 has a thickness of 0.35 mm to 0.5 mm. In some embodiments, the polymer layer 116 has a thickness of 0.35 mm to 0.45 mm. In some embodiments, the polymer layer 116 has a thickness of 0.35 mm to 0.4 mm. In some embodiments, the polymer layer 116 has a thickness of 0.4 mm to 0.5 mm. In some embodiments, the polymer layer 116 has a thickness of 0.4 mm to 0.45 mm. In some embodiments, the polymer layer 116 has a thickness of 0.45 mm to 0.5 mm.

In some embodiments, the polymer layer 116 has a thickness of 0.01 mm. In some embodiments, the polymer layer 116 has a thickness of 0.05 mm. In some embodiments, the polymer layer 116 has a thickness of 0.1 mm. In some embodiments, the polymer layer 116 has a thickness of 0.15 mm. In some embodiments, the polymer layer 116 has a thickness of 0.2 mm. In some embodiments, the polymer layer 116 has a thickness of 0.25 mm. In some embodiments, the polymer layer 116 has a thickness of 0.3 mm. In some embodiments, the polymer layer 116 has a thickness of 0.35 mm. In some embodiments, the polymer layer 116 has a thickness of 0.4 mm. In some embodiments, the polymer layer 116 has a thickness of 0.45 mm. In some embodiments, the polymer layer 116 has a thickness of 0.5 mm.

In some embodiments, the photovoltaic module 100 comprises a film 118. In some embodiments, the film 118 is located between the backsheet 102 and, when the photovoltaic module 100 is installed, a roofing substrate. In some embodiments, the film 118 directly contacts the backsheet 102. In some embodiments, the film 118 directly contacts the roofing substrate. In some embodiments, an intervening layer is located between the backsheet 102 and the film 118. In some embodiments, for example, an adhesive layer is located between the backsheet 102 and the film 118.

In some embodiments, the film comprises a thermally conductive film. In some embodiments, the film comprises at least one of graphite, calcium carbonate, calcium silicate, talc, barite, barium sulfate, titanium oxide (e.g., rutile, anatase, etc.), magnetite, alumina, silicon dioxide, aluminum nitride, wollastonite, aluminum nitride, silicon carbide, graphene, carbon nanostructures (e.g., carbon nanotubes), fullerenes, or any combination thereof. In some embodiments, the graphite comprises a highly oriented pyrolytic graphite. In some embodiments, the highly oriented pyrolytic graphite refers to a pure and ordered form of synthetic graphite. In some embodiments, the highly oriented pyrolytic graphite comprises aligned graphite crystallites. In some embodiments, the adhesive layer between the backsheet 102 and the film 118 comprises any of the adhesives disclosed herein, such as, for example and without limitation, a hot melt adhesive, a pressure sensitive adhesive, or any combination thereof. For example, in some embodiments, the adhesive layer comprises at least one of a polyolefin elastomer, a polyurethane, an acrylic, a silicone, or any combination thereof.

In some embodiments, the film has a thickness of 10 microns to 500 microns. In some embodiments, the film has a thickness of 10 microns to 450 microns. In some embodiments, the film has a thickness of 10 microns to 400 microns. In some embodiments, the film has a thickness of 10 microns to 350 microns. In some embodiments, the film has a thickness of 10 microns to 300 microns. In some embodiments, the film has a thickness of 10 microns to 250 microns. In some embodiments, the film has a thickness of 10 microns to 200 microns. In some embodiments, the film has a thickness of 10 microns to 150 microns. In some embodiments, the film has a thickness of 10 microns to 100 microns. In some embodiments, the film has a thickness of 10 microns to 90 microns. In some embodiments, the film has a thickness of 10 microns to 80 microns. In some embodiments, the film has a thickness of 10 microns to 70 microns. In some embodiments, the film has a thickness of 10 microns to 60 microns. In some embodiments, the film has a thickness of 10 microns to 50 microns. In some embodiments, the film has a thickness of 10 microns to 40 microns. In some embodiments, the film has a thickness of 10 microns to 30 microns. In some embodiments, the film has a thickness of 10 microns to 20 microns.

In some embodiments, the film has a thickness of 50 microns to 500 microns. In some embodiments, the film has a thickness of 100 microns to 500 microns. In some embodiments, the film has a thickness of 150 microns to 500 microns. In some embodiments, the film has a thickness of 200 microns to 500 microns. In some embodiments, the film has a thickness of 250 microns to 500 microns. In some embodiments, the film has a thickness of 300 microns to 500 microns. In some embodiments, the film has a thickness of 350 microns to 500 microns. In some embodiments, the film has a thickness of 400 microns to 500 microns. In some embodiments, the film has a thickness of 450 microns to 500 microns.

In some embodiments, the film 118 has a thermal conductivity of 1 W m⁻¹ K⁻¹ to 2000 W m⁻¹ K⁻¹. In some embodiments, the film 118 has a thermal conductivity of 1 W m⁻¹ K⁻¹ to 1900 W m⁻¹ K⁻¹. In some embodiments, the film 118 has a thermal conductivity of 1 W m⁻¹ K⁻¹ to 1800 W m⁻¹ K⁻¹. In some embodiments, the film 118 has a thermal conductivity of 1 W m⁻¹ K⁻¹ to 1700 W m⁻¹ K⁻¹. In some embodiments, the film 118 has a thermal conductivity of 1 W m⁻¹ K⁻¹ to 1600 W m⁻¹ K⁻¹. In some embodiments, the film 118 has a thermal conductivity of 1 W m⁻¹ K⁻¹ to 1500 W m⁻¹ K⁻¹. In some embodiments, the film 118 has a thermal conductivity of 1 W m⁻¹ K⁻¹ to 1400 W m⁻¹ K⁻¹. In some embodiments, the film 118 has a thermal conductivity of 1 W m⁻¹ K⁻¹ to 1300 W m⁻¹ K⁻¹. In some embodiments, the film 118 has a thermal conductivity of 1 W m⁻¹ K⁻¹ to 1200 W m⁻¹ K⁻¹. In some embodiments, the film 118 has a thermal conductivity of 1 W m⁻¹ K⁻¹ to 1100 W m⁻¹ K⁻¹. In some embodiments, the film 118 has a thermal conductivity of 1 W m⁻¹ K⁻¹ to 1000 W m⁻¹ K⁻¹. In some embodiments, the film 118 has a thermal conductivity of 1 W m⁻¹ K⁻¹ to 900 W m⁻¹ K⁻¹. In some embodiments, the film 118 has a thermal conductivity of 1 W m⁻¹ K⁻¹ to 800 W m⁻¹ K⁻¹. In some embodiments, the film 118 has a thermal conductivity of 1 W m⁻¹ K⁻¹ to 700 W m⁻¹ K⁻¹. In some embodiments, the film 118 has a thermal conductivity of 1 W m⁻¹ K⁻¹ to 600 W m⁻¹ K⁻¹. In some embodiments, the film 118 has a thermal conductivity of 1 W m⁻¹ K⁻¹ to 500 W m⁻¹ K⁻¹. In some embodiments, the film 118 has a thermal conductivity of 1 W m⁻¹ K⁻¹ to 400 W m⁻¹ K⁻¹. In some embodiments, the film 118 has a thermal conductivity of 1 W m⁻¹ K⁻¹ to 300 W m⁻¹ K⁻¹. In some embodiments, the film 118 has a thermal conductivity of 1 W m⁻¹ K⁻¹ to 200 W m⁻¹ K⁻¹. In some embodiments, the film 118 has a thermal conductivity of 1 W m⁻¹ K⁻¹ to 100 W m⁻¹ K⁻¹. In some embodiments, the film 118 has a thermal conductivity of 1 W m⁻¹ K⁻¹ to 90 W m⁻¹ K⁻¹. In some embodiments, the film 118 has a thermal conductivity of 1 W m⁻¹ K⁻¹ to 80 W m⁻¹ K⁻¹. In some embodiments, the film 118 has a thermal conductivity of 1 W m⁻¹ K⁻¹ to 70 W m⁻¹ K⁻¹. In some embodiments, the film 118 has a thermal conductivity of 1 W m⁻¹ K⁻¹ to 60 W m⁻¹ K⁻¹. In some embodiments, the film 118 has a thermal conductivity of 1 W m⁻¹ K⁻¹ to 50 W m⁻¹ K⁻¹. In some embodiments, the film 118 has a thermal conductivity of 1 W m⁻¹ K⁻¹ to 40 W m⁻¹ K⁻¹. In some embodiments, the film 118 has a thermal conductivity of 1 W m⁻¹ K⁻¹ to 30 W m⁻¹ K⁻¹. In some embodiments, the film 118 has a thermal conductivity of 1 W m⁻¹ K⁻¹ to 20 W m⁻¹ K⁻¹. In some embodiments, the film 118 has a thermal conductivity of 1 W m⁻¹ K⁻¹ to 10 W m⁻¹ K⁻¹. In some embodiments, the film 118 has a thermal conductivity of 1 W m⁻¹ K⁻¹ to 5 W m⁻¹ K⁻¹.

In some embodiments, the film 118 has a thermal conductivity of 100 W m⁻¹ K⁻¹ to 2000 W m⁻¹ K⁻¹. In some embodiments, the film 118 has a thermal conductivity of 200 W m⁻¹ K⁻¹ to 2000 W m⁻¹ K⁻¹. In some embodiments, the film 118 has a thermal conductivity of 300 W m⁻¹ K⁻¹ to 2000 W m⁻¹ K⁻¹. In some embodiments, the film 118 has a thermal conductivity of 400 W m⁻¹ K⁻¹ to 2000 W m⁻¹ K⁻¹. In some embodiments, the film 118 has a thermal conductivity of 500 W m⁻¹ K⁻¹ to 2000 W m⁻¹ K⁻¹. In some embodiments, the film 118 has a thermal conductivity of 600 W m⁻¹ K⁻¹ to 2000 W m⁻¹ K⁻¹. In some embodiments, the film 118 has a thermal conductivity of 700 W m⁻¹ K⁻¹ to 2000 W m⁻¹ K⁻¹. In some embodiments, the film 118 has a thermal conductivity of 800 W m⁻¹ K⁻¹ to 2000 W m⁻¹ K⁻¹. In some embodiments, the film 118 has a thermal conductivity of 900 W m⁻¹ K⁻¹ to 2000 W m⁻¹ K⁻¹. In some embodiments, the film 118 has a thermal conductivity of 1000 W m⁻¹ K⁻¹ to 2000 W m⁻¹ K⁻¹. In some embodiments, the film 118 has a thermal conductivity of 1100 W m⁻¹ K⁻¹ to 2000 W m⁻¹ K⁻¹. In some embodiments, the film 118 has a thermal conductivity of 1200 W m⁻¹ K⁻¹ to 2000 W m⁻¹ K⁻¹. In some embodiments, the film 118 has a thermal conductivity of 1300 W m⁻¹ K⁻¹ to 2000 W m⁻¹ K⁻¹. In some embodiments, the film 118 has a thermal conductivity of 1400 W m⁻¹ K⁻¹ to 2000 W m⁻¹ K⁻¹. In some embodiments, the film 118 has a thermal conductivity of 1500 W m⁻¹ K⁻¹ to 2000 W m⁻¹ K⁻¹. In some embodiments, the film 118 has a thermal conductivity of 1600 W m⁻¹ K⁻¹ to 2000 W m⁻¹ K⁻¹. In some embodiments, the film 118 has a thermal conductivity of 1700 W m⁻¹ K⁻¹ to 2000 W m⁻¹ K⁻¹. In some embodiments, the film 118 has a thermal conductivity of 1800 W m⁻¹ K⁻¹ to 2000 W m⁻¹ K⁻¹. In some embodiments, the film 118 has a thermal conductivity of 1900 W m⁻¹ K⁻¹ to 2000 W m⁻¹ K⁻¹.

In some embodiments, when the photovoltaic module 100 is installed on a roofing substrate such that the film 118 is located between the backsheet 102 and the roofing substrate, the photovoltaic module exhibits a 1% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 45% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 40% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 35% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 30% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 25% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 20% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 15% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 10% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 1% to 5% reduction in max temperature in comparison to a photovoltaic module without a film.

In some embodiments, when the photovoltaic module 100 is installed on a roofing substrate such that the film 118 is located between the backsheet 102 and the roofing substrate, the photovoltaic module exhibits a 5% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 10% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 15% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 20% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 25% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 30% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 35% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 40% to 50% reduction in max temperature in comparison to a photovoltaic module without a film. In some embodiments, when the photovoltaic module 100 is installed on a roofing substrate such that the film 118 is located between the backsheet 102 and the roofing substrate, the photovoltaic module exhibits a 45% to 50% reduction in max temperature in comparison to a photovoltaic module without a film. In some embodiments, the max temperature is an internal temperature of the photovoltaic module. In some embodiments, the max temperature is a temperature of the roofing substrate (e.g., a surface temperature).

In some embodiments, the roofing substrate may comprise, consist of, or consist essentially of at least one of a plywood substrate, a glass substrate, a cellulosic substrate, a roof shingle, a glass mat, a fiberglass mat, an underlayment, a roofing membrane, a roof deck, a photovoltaic (PV) panel, a modified bitumen (MODBIT) substrate, a roll good, a board (such as but not limited to at least one of a foam board (e.g., a polyisocyanurate (ISO) foam board), a cover board, or any combination thereof), a pipe, a base sheet, a chimney, a wax paper, or any combination thereof.

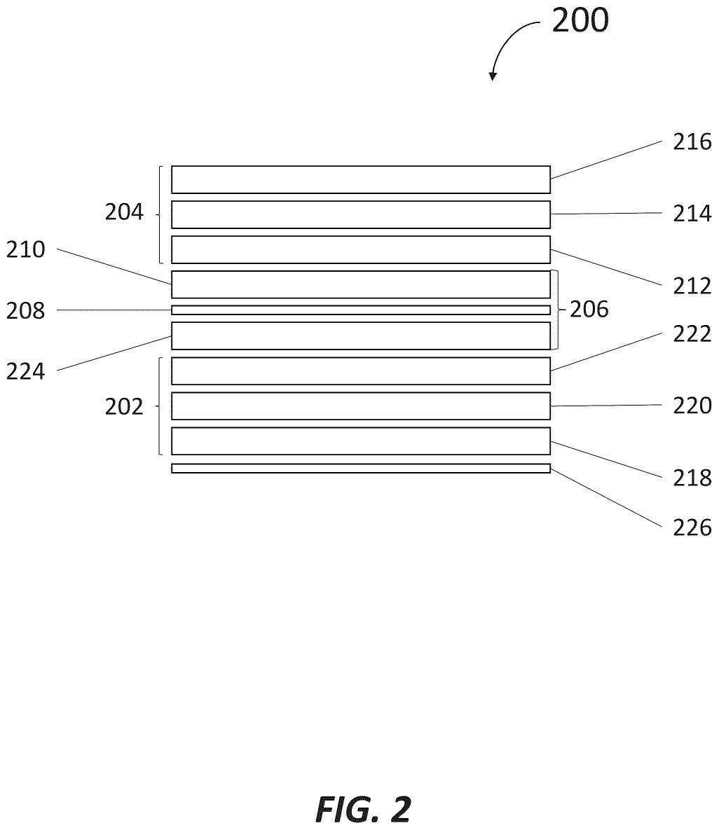

FIG. 2 is a schematic diagram of a cross-section of a photovoltaic module 200, according to some embodiments. In some embodiments, the photovoltaic module 200 is same or similar to the photovoltaic module 100. In some embodiments, features not discussed with respect to the photovoltaic module 200 are same or similar to the features discussed with respect to the photovoltaic module 100. Accordingly, similar reference numbers are used. Some of the differences between the photovoltaic modules are discussed. It will be appreciated that other differences may exist without departing from the scope of this disclosure.

As shown in FIG. 2, the photovoltaic module 200 comprises a backsheet 202, a frontsheet 204, and an encapsulated solar cell 206 between the backsheet 202 and the frontsheet 204. In some embodiments, the backsheet 202 is juxtaposed with a first surface of the encapsulated solar cell 206. In some embodiments, the frontsheet 204 is juxtaposed with a second surface of the encapsulated solar cell 206. In some embodiments, the second surface of the encapsulated solar cell 206 is opposite the first surface of the encapsulated solar cell 206. In some embodiments, the photovoltaic module 200 is configured to be installed on a roofing substrate. In some embodiments, when the photovoltaic module 200 is installed on the roofing substrate, the backsheet 202 is between the roofing substrate and the encapsulated solar cell 206. In some embodiments, the backsheet 202 is in direct contact with the roofing substrate. In some embodiments, the backsheet 202 is in direct contact with the encapsulated solar cell 206.

In some embodiments, the backsheet 202 comprises a plurality of layers. In some embodiments, the backsheet 202 comprises a first layer 218. In some embodiments, the backsheet 202 comprises a second layer 222. In some embodiments, the first layer 218 of the backsheet 202 is juxtaposed with the second layer 222 of the backsheet 202. In some embodiments, the second layer 222 of the backsheet 202 is juxtaposed with the encapsulated solar cell 206. In some embodiments, the backsheet 202 comprises a third layer 220. In some embodiments, the third layer 220 is between the first layer 218 of the backsheet 202 and the second layer 222 of the backsheet 202. In some embodiments, the third layer 220 is in direct contact with the first layer 218. In some embodiments, the third layer 220 is in direct contact with the second layer 222. In some embodiments, the third layer 220 is an adhesive layer. In some embodiments, the first layer 218 comprises the graphene component. In some embodiments, the second layer 222 comprises the graphene component. In some embodiments, the third layer 220 comprises the graphene component. In some embodiments, the first layer 218 does not comprise the graphene component. In some embodiments, the second layer 222 does not comprise the graphene component. In some embodiments, the third layer 220 does not comprise the graphene component. It will be appreciated that the backsheet 202 may comprise more or less layers without departing from the scope of this disclosure.

In some embodiments, the first layer 218 of the backsheet 202 is a core layer. In some embodiments, the second layer 222 of the backsheet 202 is a cap layer. In some embodiments, the third layer 220 of the backsheet 202 is a scrim or a mat.

In some embodiments, the first layer 218 of the backsheet 202 comprises a graphene component. In some embodiments, the graphene component comprises graphene. In some embodiments, the graphene is provided in a form of graphite (e.g., at least one of graphite flakes, graphite sheets, graphite particles, graphite nanoparticles, graphite powder, graphite nanosheets, graphite nanoflakes, graphite platelets, graphite nanoplatelets, graphite fibers, etc., any one or more of which can be expandable graphite). In some embodiments, the graphite comprises stacked layers of graphene. In some embodiments, the graphite has a surface pH of 5 to 8.5. As used herein, the term “graphene” refers to a type of carbon nanomaterial. In some embodiments, the term “graphene” refers to a heat conducting (or thermally conductive) type of carbon nanomaterial. In some embodiments, the term “graphene” refers to a two-dimensional arrangement of carbon atoms. In some embodiments, the term “graphene” refers to a layer of atoms arranged in a two-dimensional honeycomb lattice. In some embodiments, the graphene includes graphene oxides. In some embodiments, the graphene includes reduced graphene oxides. In some embodiments, the term “graphene” does not refer to or does not include graphite. In some embodiments, the at least one layer of the backsheet 202 comprises carbon nanotubes.

In some embodiments, the graphene comprises graphene powder. In some embodiments, the graphene comprises a graphene particle. In some embodiments, the graphene comprises a plurality of graphene particles. In some embodiments, the plurality of graphene particles comprises a plurality of graphene nanoparticles. In some embodiments, the graphene comprises a graphene sheet. In some embodiments, the graphene comprises a plurality of graphene sheets. In some embodiments, the plurality of graphene sheets comprises a plurality of graphene nanosheets. In some embodiments, the graphene comprises graphene flakes. In some embodiments, the graphene flakes comprise graphene nanoflakes. In some embodiments, the graphene comprises graphene platelets. In some embodiments, the graphene platelets comprise graphene nanoplatelets. In some embodiments, the graphene comprises graphene rods. In some embodiments, the graphene comprises graphene fibers.

In some embodiments, the first layer 218 comprises 0.5% to 50% by weight of the graphene component based on a total weight of the first layer 218. In some embodiments, the first layer 218 comprises 0.5% to 45% by weight of the graphene component based on the total weight of the first layer 218. In some embodiments, the first layer 218 comprises 0.5% to 40% by weight of the graphene component based on the total weight of the first layer 218. In some embodiments, the first layer 218 comprises 0.5% to 35% by weight of the graphene component based on the total weight of the first layer 218. In some embodiments, the first layer 218 comprises 0.5% to 30% by weight of the graphene component based on the total weight of the first layer 218. In some embodiments, the first layer 218 comprises 0.5% to 25% by weight of the graphene component based on the total weight of the first layer 218. In some embodiments, the first layer 218 comprises 0.5% to 20% by weight of the graphene component based on the total weight of the first layer 218. In some embodiments, the first layer 218 comprises 0.5% to 15% by weight of the graphene component based on the total weight of the first layer 218. In some embodiments, the first layer 218 comprises 0.5% to 10% by weight of the graphene component based on the total weight of the first layer 218. In some embodiments, the first layer 218 comprises 0.5% to 5% by weight of the graphene component based on the total weight of the first layer 218. In some embodiments, the first layer 218 comprises 0.5% to 4% by weight of the graphene component based on the total weight of the first layer 218. In some embodiments, the first layer 218 comprises 0.5% to 2% by weight of the graphene component based on the total weight of the first layer 218. In some embodiments, the first layer 218 comprises 0.5% to 1% by weight of the graphene component based on the total weight of the first layer 218.

In some embodiments, the first layer 218 comprises 1% to 50% by weight of the graphene component based on the total weight of the first layer 218. In some embodiments, the first layer 218 comprises 5% to 50% by weight of the graphene component based on the total weight of the first layer 218. In some embodiments, the first layer 218 comprises 10% to 50% by weight of the graphene component based on the total weight of the first layer 218. In some embodiments, the first layer 218 comprises 15% to 50% by weight of the graphene component based on the total weight of the first layer 218. In some embodiments, the first layer 218 comprises 20% to 50% by weight of the graphene component based on the total weight of the first layer 218. In some embodiments, the first layer 218 comprises 25% to 50% by weight of the graphene component based on the total weight of the first layer 218. In some embodiments, the first layer 218 comprises 30% to 50% by weight of the graphene component based on the total weight of the first layer 218. In some embodiments, the first layer 218 comprises 35% to 50% by weight of the graphene component based on the total weight of the first layer 218. In some embodiments, the first layer 218 comprises 40% to 50% by weight of the graphene component based on the total weight of the first layer 218. In some embodiments, the first layer 218 comprises 45% to 50% by weight of the graphene component based on the total weight of the first layer 218.

In some embodiments, the first layer 218 comprises at least 35% by volume of the graphene based on the total volume of the first layer 218. In some embodiments, the first layer 218 comprises at least 40% by volume of the graphene based on the total volume of the first layer 218. In some embodiments, the first layer 218 comprises at least 45% by volume of the graphene based on the total volume of the first layer 218. In some embodiments, the first layer 218 comprises at least 50% by volume of the graphene based on the total volume of the first layer 218. In some embodiments, the first layer 218 comprises at least 55% by volume of the graphene based on the total volume of the first layer 218. In some embodiments, the first layer 218 comprises at least 60% by volume of the graphene based on the total volume of the first layer 218. In some embodiments, the first layer 218 comprises at least 65% by volume of the graphene based on the total volume of the first layer 218. In some embodiments, the first layer 218 comprises at least 70% by volume of the graphene based on the total volume of the first layer 218.

In some embodiments, the first layer 218 comprises 35% to 70% by volume of the graphene based on the total volume of the first layer 218. In some embodiments, the first layer 218 comprises 35% to 65% by volume of the graphene based on the total volume of the first layer 218. In some embodiments, the first layer 218 comprises 35% to 60% by volume of the graphene based on the total volume of the first layer 218. In some embodiments, the first layer 218 comprises 35% to 55% by volume of the graphene based on the total volume of the first layer 218. In some embodiments, the first layer 218 comprises 35% to 50% by volume of the graphene based on the total volume of the first layer 218. In some embodiments, the first layer 218 comprises 35% to 45% by volume of the graphene based on the total volume of the first layer 218. In some embodiments, the first layer 218 comprises 35% to 40% by volume of the graphene based on the total volume of the first layer 218.

In some embodiments, the first layer 218 comprises 40% to 70% by volume of the graphene based on the total volume of the first layer 218. In some embodiments, the first layer 218 comprises 45% to 70% by volume of the graphene based on the total volume of the first layer 218. In some embodiments, the first layer 218 comprises 50% to 70% by volume of the graphene based on the total volume of the first layer 218. In some embodiments, the first layer 218 comprises 55% to 70% by volume of the graphene based on the total volume of the first layer 218. In some embodiments, the first layer 218 comprises 60% to 70% by volume of the graphene based on the total volume of the first layer 218. In some embodiments, the first layer 218 comprises 65% to 70% by volume of the graphene based on the total volume of the first layer 218.

In some embodiments, the graphene is characterized by a lateral size. As used herein, the term “lateral size” of the graphene refers to a length or an average length of at least one dimension of the graphene component. In some embodiments, the term “lateral size” of the graphene refers to a length of the greatest dimension of the graphene component. In some embodiments, the term “lateral size” of the graphene refers to an average length of the greatest dimension of the graphene component. In some embodiments, for example, the lateral size of graphene may refer to a radius. In some embodiments, the lateral size of graphene may refer to a diameter. In some embodiments, the lateral size of graphene may refer to a width. In some embodiments, the lateral size of graphene may refer to a height. In some embodiments, the lateral size of graphene may refer to a length. In some embodiments, the lateral size of the graphene may refer to a thickness. In some embodiments, the lateral size of the graphene may refer to a median particle size. In some embodiments, the graphene component comprises graphene having a plurality of different lateral sizes.

In some embodiments, the lateral size of the graphene is 0.01 nm to 1000 μm, or any range or subrange between 0.01 nm and 1000 μm. In some embodiments, the lateral size of the graphene is 1 nm to 1000 μm. In some embodiments, the lateral size of the graphene is 1 μm to 1000 μm. In some embodiments, the lateral size of the graphene is 800 μm or less. In some embodiments, the lateral size of the graphene is 600 μm or less. In some embodiments, the lateral size of the graphene is 500 μm or less. In some embodiments, the lateral size of the graphene is 400 μm or less. In some embodiments, the lateral size of the graphene is 300 μm or less. In some embodiments, the lateral size of the graphene is 200 μm or less. In some embodiments, the lateral size of the graphene is 0.01 nm to 800 nm. In some embodiments, the lateral size of the graphene is 5 nm to 800 nm. In some embodiments, the lateral size of the graphene is 10 nm to 500 nm. In some embodiments, the lateral size of the graphene is 10 nm to 400 nm. In some embodiments, the lateral size of the graphene is 10 nm to 200 nm. In some embodiments, the lateral size of the graphene is 5 nm to 150 nm. In some embodiments, the lateral size of the graphene is 10 nm to 500 μm. In some embodiments, the lateral size of the graphene is 50 nm to 500 μm. In some embodiments, the lateral size of the graphene is 100 nm to 500 μm. In some embodiments, the lateral size of the graphene is 200 nm to 500 μm. In some embodiments, the lateral size of the graphene is 200 nm to 20 μm. In some embodiments, the lateral size of the graphene is 500 nm to 5 μm. In some embodiments, the lateral size of the graphene is 5 μm to 20 μm. In some embodiments, the lateral size of the graphene is 200 nm to 500 nm. In some embodiments, the lateral size of the graphene is 0.5 μm to 5 μm.

In some embodiments, the lateral size of the graphene is 1 nm to 100 μm. In some embodiments, the lateral size of the graphene is 1 nm to 90 μm. In some embodiments, the lateral size of the graphene is 1 nm to 80 μm. In some embodiments, the lateral size of the graphene is 1 nm to 70 μm. In some embodiments, the lateral size of the graphene is 1 nm to 60 μm. In some embodiments, the lateral size of the graphene is 1 nm to 50 μm. In some embodiments, the lateral size of the graphene is 1 nm to 40 μm. In some embodiments, the lateral size of the graphene is 1 nm to 30 μm. In some embodiments, the lateral size of the graphene is 1 nm to 20 μm. In some embodiments, the lateral size of the graphene is 1 nm to 10 μm. In some embodiments, the lateral size of the graphene is 10 nm to 100 μm. In some embodiments, the lateral size of the graphene is 20 nm to 100 μm. In some embodiments, the lateral size of the graphene is 30 nm to 100 μm. In some embodiments, the lateral size of the graphene is 40 nm to 100 μm. In some embodiments, the lateral size of the graphene is 50 nm to 100 μm. In some embodiments, the lateral size of the graphene is 60 nm to 100 μm. In some embodiments, the lateral size of the graphene is 70 nm to 100 μm. In some embodiments, the lateral size of the graphene is nm to 100 μm. In some embodiments, the lateral size of the graphene is 80 nm to 100 μm. In some embodiments, the lateral size of the graphene is 90 nm to 100 μm. In some embodiments, the lateral size of the graphene is 10 nm to 70 μm. In some embodiments, the lateral size of the graphene is 1 μm to 2 μm.

In some embodiments, the lateral size of the graphene component is 1 μm to 1000 μm. In some embodiments, the lateral size of the graphene component is 1 μm to 900 μm. In some embodiments, the lateral size of the graphene component is 1 μm to 800 μm. In some embodiments, the lateral size of the graphene component is 1 μm to 700 μm. In some embodiments, the lateral size of the graphene component is 1 μm to 600 μm. In some embodiments, the lateral size of the graphene component is 1 μm to 500 μm. In some embodiments, the lateral size of the graphene component is 1 μm to 400 μm. In some embodiments, the lateral size of the graphene component is 1 μm to 300 μm. In some embodiments, the lateral size of the graphene component is 1 μm to 200 μm. In some embodiments, the lateral size of the graphene component is 1 μm to 100 μm.

In some embodiments, the lateral size of the graphene component is 100 μm to 1000 μm. In some embodiments, the lateral size of the graphene component is 200 μm to 1000 μm. In some embodiments, the lateral size of the graphene component is 300 μm to 1000 μm. In some embodiments, the lateral size of the graphene component is 400 μm to 1000 μm. In some embodiments, the lateral size of the graphene component is 500 μm to 1000 μm. In some embodiments, the lateral size of the graphene component is 600 μm to 1000 μm. In some embodiments, the lateral size of the graphene component is 700 μm to 1000 μm. In some embodiments, the lateral size of the graphene component is 800 μm to 1000 μm. In some embodiments, the lateral size of the graphene component is 900 μm to 1000 μm.

In some embodiments, the graphene component has an orientation in the at least one layer of the backsheet 202. In some embodiments, the graphene component comprises graphene in a random orientation in the at least one layer of the backsheet 202. In some embodiments, the graphene component comprises graphene in an ordered orientation in the at least one layer of the backsheet 202. In some embodiments, the graphene component comprises graphene oriented in the at least one layer of the backsheet 202 in a two-dimensional structure. In some embodiments, the graphene component comprises graphene oriented in the at least one layer of the backsheet 202 in a three-dimensional structure. In some embodiments, the graphene component comprises graphene oriented in the at least one layer of the backsheet 202 in end-to-end strips. In some embodiments, the graphene component comprises graphene oriented in the at least one layer of the backsheet 202 in a sheet structure.

In some embodiments, the graphene component comprises impurities. In some embodiments, the graphene component comprises no more than 4% by weight of impurities based on a total weight of the graphene component. In some embodiments, the graphene component comprises no more than 3% by weight of impurities based on the total weight of the graphene component. In some embodiments, the graphene component comprises no more than 2% by weight of impurities based on the total weight of the graphene component. In some embodiments, the graphene component comprises no more than 1% by weight of impurities based on the total weight of the graphene component. In some embodiments, the graphene component comprises 0.01% to 4% by weight of impurities based on the total weight of the graphene component. In some embodiments, the graphene component comprises 0.01% to 3.5% by weight of impurities based on the total weight of the graphene component. In some embodiments, the graphene component comprises 0.01% to 3% by weight of impurities based on the total weight of the graphene component. In some embodiments, the graphene component comprises 0.01% to 2.5% by weight of impurities based on the total weight of the graphene component. In some embodiments, the graphene component comprises 0.01% to 2% by weight of impurities based on the total weight of the graphene component. In some embodiments, the graphene component comprises 0.01% to 1.5% by weight of impurities based on the total weight of the graphene component. In some embodiments, the graphene component comprises 0.01% to 1% by weight of impurities based on the total weight of the graphene component. In some embodiments, the graphene component comprises 0.01% to 0.5% by weight of impurities based on the total weight of the graphene component. In some embodiments, the graphene component comprises 0.5% to 4% by weight of impurities based on the total weight of the graphene component. In some embodiments, the graphene component comprises 1% to 4% by weight of impurities based on the total weight of the graphene component. In some embodiments, the graphene component comprises 1.5% to 4% by weight of impurities based on the total weight of the graphene component. In some embodiments, the graphene component comprises 2% to 4% by weight of impurities based on the total weight of the graphene component. In some embodiments, the graphene component comprises 2.5% to 4% by weight of impurities based on the total weight of the graphene component. In some embodiments, the graphene component comprises 3% to 4% by weight of impurities based on the total weight of the graphene component. In some embodiments, the graphene component comprises 3.5% to 4% by weight of impurities based on the total weight of the graphene component. In some embodiments, the impurities comprise any substance other than graphene.

In some embodiments, the first layer 218 of the backsheet 102 comprises a polymeric material. In some embodiments, the first layer 218 of the backsheet 102 comprises one or more thermoplastic polymers. In some embodiments, the thermoplastic polymer comprises a polyolefin. In some embodiments, the thermoplastic polymer comprises a thermoplastic polyolefin (TPO). In some embodiments, the thermoplastic polyolefin comprises at least one of polyethylene, polypropylene, any copolymer thereof, any homopolymer thereof, any polymer blend thereof, or any combination thereof. In some embodiments, the thermoplastic polyolefin comprises at least one of a copolymer of propylene and ethylene, a blend of propylene and ethylene, a copolymer of ethylene alpha-olefin, a propylene homopolymer, an ethylene homopolymer, a propylene block copolymer, an ethylene block copolymer, a propylene elastomer, an ethylene elastomer, or any combination thereof. In some embodiments, the thermoplastic polymer comprises at least one of a copolymer comprising ethylene and octene, a copolymer comprising ethylene and hexane, a copolymer comprising ethylene and butene, polyethylene (including raw and/or recycled low density polyethylene (LDPE)), linear low density polyethylene (LLDPE), high density polyethylene (HDPE)), polypropylenes (e.g., isotactic polypropylene (IPP) and/or atactic polypropylene (APP/IPP)), amorphous polyalpha olefins (APAO), amorphous polyolefins (APO), or any combination thereof.

Such thermoplastic polymers can include, for example and without limitation, at least one of Vistamaxx® 6102, Vistamaxx® 8880, both of which are polypropylenes (e.g., isotactic polypropylene (IPP)) that are available from ExxonMobil, Irving, Tex.; Elvaloy®, which is a terpolymer that is available from Dow/DuPont, Wilmington, Del.; Fusabond®, which is a chemically modified ethylene acrylate copolymer and/or a modified polyethylene, that is available from Dow/DuPont, Wilmington, Del.; RT2304, which is an amorphous polyalpha olefin (APAO) that is available from Rextac APAO Polymers LLC, Odessa, Tex.; Eastoflex® P1023, which is an amorphous polyolefin (APO) that comprises a propylene homopolymer, and is available from Eastman Chemical Company, Kingsport, Tenn.; Eastoflex® E1060, which is an amorphous polyolefin (APO) that comprises a copolymer of propylene and ethylene, and is available from Eastman Chemical Company, Kingsport, Tenn.; Eastoflex® M1025, which is an amorphous polyolefin (APO) that comprises a blend of propylene homopolymer and copolymers of propylene and ethylene, and is available from Eastman Chemical Company, Kingsport, Tenn.; Engage® 7487, which is a polyolefin elastomer (POE) that is available from Dow Inc., Midland, Mich., or any combination thereof.

In some embodiments, the first layer 218 of the backsheet 102 comprises polyethylene terephthalate (PET). In some embodiments, the first layer 218 of the backsheet 102 comprises ethylene tetrafluoroethylene (ETFE). In some embodiments, the first layer 218 of the backsheet 102 comprises an acrylic such as polymethyl methacrylate (PMMA). In some embodiments, the first layer 218 of the backsheet 102 comprises thermoplastic polyolefin (TPO). In some embodiments, the first layer 218 of the backsheet 102 comprises a single ply TPO roofing membrane. In other embodiments, non-limiting examples of TPO membranes are disclosed in U.S. Pat. No. 9,359,014 to Yang et al., which is incorporated by reference herein in its entirety. In some embodiments, the first layer 218 of the backsheet 102 comprises polyvinyl chloride. In some embodiments, the first layer 218 of the backsheet 102 comprises ethylene propylene diene monomer (EPDM) rubber. In some embodiments, the first layer 218 of the backsheet 102 comprises a flame retardant. In some embodiments, the flame retardant comprises at least one of clays, nanoclays, silicas, carbon black, metal hydroxides such as aluminum hydroxide, metal foils, graphite, expandable graphite, or any combination thereof. In some embodiments, the first layer 218 of the backsheet 102 is white in color. In some embodiments, the first layer 218 of the backsheet 102 is white TPO.

In some embodiments, the first layer 218 comprises 50% to 99.5% by weight of the polymeric material based on the total weight of the first layer 218. In some embodiments, the first layer 218 comprises 50% to 95% by weight of the polymeric material based on the total weight of the first layer 218. In some embodiments, the first layer 218 comprises 50% to 90% by weight of the polymeric material based on the total weight of the first layer 218. In some embodiments, the first layer 218 comprises 50% to 85% by weight of the polymeric material based on the total weight of the first layer 218. In some embodiments, the first layer 218 comprises 50% to 80% by weight of the polymeric material based on the total weight of the first layer 218. In some embodiments, the first layer 218 comprises 50% to 75% by weight of the polymeric material based on the total weight of the first layer 218. In some embodiments, the first layer 218 comprises 50% to 70% by weight of the polymeric material based on the total weight of the first layer 218. In some embodiments, the first layer 218 comprises 50% to 65% by weight of the polymeric material based on the total weight of the first layer 218. In some embodiments, the first layer 218 comprises 50% to 60% by weight of the polymeric material based on the total weight of the first layer 218. In some embodiments, the first layer 218 comprises 50% to 55% by weight of the polymeric material based on the total weight of the first layer 218.

In some embodiments, the first layer 218 comprises 55% to 99.5% by weight of the polymeric material based on the total weight of the first layer 218. In some embodiments, the first layer 218 comprises 60% to 99.5% by weight of the polymeric material based on the total weight of the first layer 218. In some embodiments, the first layer 218 comprises 65% to 99.5% by weight of the polymeric material based on the total weight of the first layer 218. In some embodiments, the first layer 218 comprises 70% to 99.5% by weight of the polymeric material based on the total weight of the first layer 218. In some embodiments, the first layer 218 comprises 75% to 99.5% by weight of the polymeric material based on the total weight of the first layer 218. In some embodiments, the first layer 218 comprises 80% to 99.5% by weight of the polymeric material based on the total weight of the first layer 218. In some embodiments, the first layer 218 comprises 85% to 99.5% by weight of the polymeric material based on the total weight of the first layer 218. In some embodiments, the first layer 218 comprises 90% to 99.5% by weight of the polymeric material based on the total weight of the first layer 218. In some embodiments, the first layer 218 comprises 95% to 99.5% by weight of the polymeric material based on the total weight of the first layer 218.

In some embodiments, the first layer 218 has a thickness of 0.2 mm to 4 mm. In some embodiments, the first layer 218 has a thickness of 0.2 mm to 3.5 mm. In some embodiments, the first layer 218 has a thickness of 0.2 mm to 3 mm. In some embodiments, the first layer 218 has a thickness of 0.2 mm to 2.5 mm. In some embodiments, the first layer 218 has a thickness of 0.2 mm to 2 mm. In some embodiments, the first layer 218 has a thickness of 0.2 mm to 1.5 mm. In some embodiments, the first layer 218 has a thickness of 0.2 mm to 1 mm. In some embodiments, the first layer 218 has a thickness of 0.2 mm to 0.5 mm. In some embodiments, the first layer 218 has a thickness of 0.5 mm to 4 mm. In some embodiments, the first layer 218 has a thickness of 1 mm to 4 mm. In some embodiments, the first layer 218 has a thickness of 1.5 mm to 4 mm. In some embodiments, the first layer 218 has a thickness of 2 mm to 4 mm. In some embodiments, the first layer 218 has a thickness of 2.5 mm to 4 mm. In some embodiments, the first layer 218 has a thickness of 3 mm to 4 mm. In some embodiments, the first layer 218 has a thickness of 3.5 mm to 4 mm.

In some embodiments, the first layer 218 has a thickness of 0.2 mm to 0.5 mm. In another embodiment, the first layer 218 has a thickness of 0.2 mm to 0.4 mm. In another embodiment, the first layer 218 has a thickness of 0.2 mm to 0.3 mm. In some embodiments, the first layer 218 has a thickness of 0.3 mm to 0.5 mm. In another embodiment, the first layer 218 has a thickness of 0.3 mm to 0.4 mm. In some embodiments, the first layer 218 has a thickness of 0.4 mm to 0.5 mm. In some embodiments, the first layer 218 has a thickness of 0.2 mm. In some embodiments, the first layer 218 has a thickness of 0.3 mm. In some embodiments, the first layer 218 has a thickness of 0.4 mm. In some embodiments, the first layer 218 has a thickness of 0.5 mm.

In some embodiments, the first layer 218 has a thickness of 1 mm to 5 mm. In some embodiments, the first layer 218 has a thickness of 1 mm to 4 mm. In some embodiments, the first layer 218 has a thickness of 1 mm to 3.5 mm. In some embodiments, the first layer 218 has a thickness of 1 mm to 3 mm. In some embodiments, the first layer 218 has a thickness of 1 mm to 2.5 mm. In some embodiments, the first layer 218 has a thickness of 1 mm to 2 mm. In some embodiments, the first layer 218 has a thickness of 1 mm to 1.5 mm. In some embodiments, the first layer 218 has a thickness of 2 mm to 5 mm. In some embodiments, the first layer 218 has a thickness of 2 mm to 4 mm. In some embodiments, the first layer 218 has a thickness of 2 mm to 3.5 mm. In some embodiments, the first layer 218 has a thickness of 2 mm to 3 mm. In some embodiments, the first layer 218 has a thickness of 3 mm to 5 mm. In some embodiments, the first layer 218 has a thickness of 3 mm to 4 mm. In some embodiments, the first layer 218 has a thickness of 4 mm to 5 mm. In some embodiments, the first layer 218 has a thickness of 1 mm. In some embodiments, the first layer 218 has a thickness of 2 mm. In some embodiments, the first layer 218 has a thickness of 3 mm. In some embodiments, the first layer 218 has a thickness of 4 mm. In some embodiments, the first layer 218 has a thickness of 5 mm.

In some embodiments, the first layer 218 has a thickness of 1 mm to 10 mm. In some embodiments, the first layer 218 has a thickness of 1 mm to 9 mm. In some embodiments, the first layer 218 has a thickness of 1 mm to 8 mm. In some embodiments, the first layer 218 has a thickness of 1 mm to 7 mm. In some embodiments, the first layer 218 has a thickness of 1 mm to 6 mm. In some embodiments, the first layer 218 has a thickness of 4 mm to 10 mm. In some embodiments, the first layer 218 has a thickness of 5 mm to 10 mm. In some embodiments, the first layer 218 has a thickness of 6 mm to 10 mm. In some embodiments, the first layer 218 has a thickness of 7 mm to 10 mm. In some embodiments, the first layer 218 has a thickness of 8 mm to 10 mm. In some embodiments, the first layer 218 has a thickness of 9 mm to 10 mm.

In some embodiments, the first layer 218 has a thermal conductivity of 0.3 W m⁻¹ K⁻¹ to 3 W m⁻¹ K⁻¹. In some embodiments, the first layer 218 has a thermal conductivity of 0.3 W m⁻¹ K⁻¹ to 2.9 W m⁻¹ K⁻¹. In some embodiments, the first layer 218 has a thermal conductivity of 0.3 W m⁻¹ K⁻¹ to 2.8 W m⁻¹ K⁻¹. In some embodiments, the first layer 218 has a thermal conductivity of 0.3 W m⁻¹ K⁻¹ to 2.7 W m⁻¹ K⁻¹. In some embodiments, the first layer 218 has a thermal conductivity of 0.3 W m⁻¹ K⁻¹ to 2.6 W m⁻¹ K⁻¹. In some embodiments, the first layer 218 has a thermal conductivity of 0.3 W m⁻¹ K⁻¹ to 2.5 W m⁻¹ K⁻¹. In some embodiments, the first layer 218 has a thermal conductivity of 0.3 W m⁻¹ K⁻¹ to 2.4 W m⁻¹ K⁻¹. In some embodiments, the first layer 218 has a thermal conductivity of 0.3 W m⁻¹ K⁻¹ to 2.3 W m⁻¹ K⁻¹. In some embodiments, the first layer 218 has a thermal conductivity of 0.3 W m⁻¹ K⁻¹ to 2.2 W m⁻¹ K⁻¹. In some embodiments, the first layer 218 has a thermal conductivity of 0.3 W m⁻¹ K⁻¹ to 2.1 W m⁻¹ K⁻¹. In some embodiments, the first layer 218 has a thermal conductivity of 0.3 W m⁻¹ K⁻¹ to 2 W m⁻¹ K⁻¹. In some embodiments, the first layer 218 has a thermal conductivity of 0.3 W m⁻¹ K⁻¹ to 1.9 W m⁻¹ K⁻¹. In some embodiments, the first layer 218 has a thermal conductivity of 0.3 W m⁻¹ K⁻¹ to 1.8 W m⁻¹ K⁻¹. In some embodiments, the first layer 218 has a thermal conductivity of 0.3 W m⁻¹ K⁻¹ to 1.7 W m⁻¹ K⁻¹. In some embodiments, the first layer 218 has a thermal conductivity of 0.3 W m⁻¹ K⁻¹ to 1.6 W m⁻¹ K⁻¹. In some embodiments, the first layer 218 has a thermal conductivity of 0.3 W m⁻¹ K⁻¹ to 1.5 W m⁻¹ K⁻¹. In some embodiments, the first layer 218 has a thermal conductivity of 0.3 W m⁻¹ K⁻¹ to 1.4 W m⁻¹ K⁻¹. In some embodiments, the first layer 218 has a thermal conductivity of 0.3 W m⁻¹ K⁻¹ to 1.3 W m⁻¹ K⁻¹. In some embodiments, the first layer 218 has a thermal conductivity of 0.3 W m⁻¹ K⁻¹ to 1.2 W m⁻¹ K⁻¹. In some embodiments, the first layer 218 has a thermal conductivity of 0.3 W m⁻¹ K⁻¹ to 1.1 W m⁻¹ K⁻¹. In some embodiments, the first layer 218 has a thermal conductivity of 0.3 W m⁻¹ K⁻¹ to 1 W m⁻¹ K⁻¹. In some embodiments, the first layer 218 has a thermal conductivity of 0.3 W m⁻¹ K⁻¹ to 0.9 W m⁻¹ K⁻¹. In some embodiments, the first layer 218 has a thermal conductivity of 0.3 W m⁻¹ K⁻¹ to 0.8 W m⁻¹ K⁻¹. In some embodiments, the first layer 218 has a thermal conductivity of 0.3 W m⁻¹ K⁻¹ to 0.7 W m⁻¹ K⁻¹. In some embodiments, the first layer 218 has a thermal conductivity of 0.3 W m⁻¹ K⁻¹ to 0.6 W m⁻¹ K⁻¹. In some embodiments, the first layer 218 has a thermal conductivity of 0.3 W m⁻¹ K⁻¹ to 0.5 W m⁻¹ K⁻¹. In some embodiments, the first layer 218 has a thermal conductivity of 0.3 W m⁻¹ K⁻¹ to 0.4 W m⁻¹ K⁻¹.

In some embodiments, the first layer 218 has a thermal conductivity of 0.3 W m⁻¹ K⁻¹ to 3 W m⁻¹ K⁻¹. In some embodiments, the first layer 218 has a thermal conductivity of 0.4 W m⁻¹ K⁻¹ to 3 W m⁻¹ K⁻¹. In some embodiments, the first layer 218 has a thermal conductivity of 0.5 W m⁻¹ K⁻¹ to 3 W m⁻¹ K⁻¹. In some embodiments, the first layer 218 has a thermal conductivity of 0.6 W m⁻¹ K⁻¹ to 3 W m⁻¹ K⁻¹. In some embodiments, the first layer 218 has a thermal conductivity of 0.7 W m⁻¹ K⁻¹ to 3 W m⁻¹ K⁻¹. In some embodiments, the first layer 218 has a thermal conductivity of 0.8 W m⁻¹ K⁻¹ to 3 W m⁻¹ K⁻¹. In some embodiments, the first layer 218 has a thermal conductivity of 0.9 W m⁻¹ K⁻¹ to 3 W m⁻¹ K⁻¹. In some embodiments, the first layer 218 has a thermal conductivity of 1 W m⁻¹ K⁻¹ to 3 W m⁻¹ K⁻¹. In some embodiments, the first layer 218 has a thermal conductivity of 1.1 W m⁻¹ K⁻¹ to 3 W m⁻¹ K⁻¹. In some embodiments, the first layer 218 has a thermal conductivity of 1.2 W m⁻¹ K⁻¹ to 3 W m⁻¹ K⁻¹. In some embodiments, the first layer 218 has a thermal conductivity of 1.3 W m⁻¹ K⁻¹ to 3 W m⁻¹ K⁻¹. In some embodiments, the first layer 218 has a thermal conductivity of 1.4 W m⁻¹ K⁻¹ to 3 W m⁻¹ K⁻¹. In some embodiments, the first layer 218 has a thermal conductivity of 1.5 W m⁻¹ K⁻¹ to 3 W m⁻¹ K⁻¹. In some embodiments, the first layer 218 has a thermal conductivity of 1.6 W m⁻¹ K⁻¹ to 3 W m⁻¹ K⁻¹. In some embodiments, the first layer 218 has a thermal conductivity of 1.7 W m⁻¹ K⁻¹ to 3 W m⁻¹ K⁻¹. In some embodiments, the first layer 218 has a thermal conductivity of 1.8 W m⁻¹ K⁻¹ to 3 W m⁻¹ K⁻¹. In some embodiments, the first layer 218 has a thermal conductivity of 1.9 W m⁻¹ K⁻¹ to 3 W m⁻¹ K⁻¹. In some embodiments, the first layer 218 has a thermal conductivity of 2 W m⁻¹ K⁻¹ to 3 W m⁻¹ K⁻¹. In some embodiments, the first layer 218 has a thermal conductivity of 2.1 W m⁻¹ K⁻¹ to 3 W m⁻¹ K⁻¹. In some embodiments, the first layer 218 has a thermal conductivity of 2.2 W m⁻¹ K⁻¹ to 3 W m⁻¹ K⁻¹. In some embodiments, the first layer 218 has a thermal conductivity of 2.3 W m⁻¹ K⁻¹ to 3 W m⁻¹ K⁻¹. In some embodiments, the first layer 218 has a thermal conductivity of 2.4 W m⁻¹ K⁻¹ to 3 W m⁻¹ K⁻¹. In some embodiments, the first layer 218 has a thermal conductivity of 2.5 W m⁻¹ K⁻¹ to 3 W m⁻¹ K⁻¹. In some embodiments, the first layer 218 has a thermal conductivity of 2.6 W m⁻¹ K⁻¹ to 3 W m⁻¹ K⁻¹. In some embodiments, the first layer 218 has a thermal conductivity of 2.7 W m⁻¹ K⁻¹ to 3 W m⁻¹ K⁻¹. In some embodiments, the first layer 218 has a thermal conductivity of 2.8 W m⁻¹ K⁻¹ to 3 W m⁻¹ K⁻¹. In some embodiments, the first layer 218 has a thermal conductivity of 2.9 W m⁻¹ K⁻¹ to 3 W m⁻¹ K⁻¹.

In some embodiments, the second layer 222 of the backsheet 202 comprises a graphene component. In some embodiments, the graphene component comprises graphene. As used herein, the term “graphene” refers to a type of carbon nanomaterial. In some embodiments, the term “graphene” refers to a heat conducting (or thermally conductive) type of carbon nanomaterial. In some embodiments, the term “graphene” refers to a two-dimensional arrangement of carbon atoms. In some embodiments, the term “graphene” refers to a layer of atoms arranged in a two-dimensional honeycomb lattice. In some embodiments, the graphene includes graphene oxides. In some embodiments, the graphene includes reduced graphene oxides. In some embodiments, the term “graphene” does not refer to or does not include graphite. In some embodiments, the at least one layer of the backsheet 202 comprises carbon nanotubes.

In some embodiments, the graphene comprises graphene powder. In some embodiments, the graphene comprises a graphene particle. In some embodiments, the graphene comprises a plurality of graphene particles. In some embodiments, the plurality of graphene particles comprises a plurality of graphene nanoparticles. In some embodiments, the graphene comprises a graphene sheet. In some embodiments, the graphene comprises a plurality of graphene sheets. In some embodiments, the plurality of graphene sheets comprises a plurality of graphene nanosheets. In some embodiments, the graphene comprises graphene flakes. In some embodiments, the graphene flakes comprise graphene nanoflakes. In some embodiments, the graphene comprises graphene platelets. In some embodiments, the graphene platelets comprise graphene nanoplatelets. In some embodiments, the graphene comprises graphene rods. In some embodiments, the graphene comprises graphene fibers.

In some embodiments, the second layer 222 comprises 0.5% to 50% by weight of the graphene component based on a total weight of the second layer 222. In some embodiments, the second layer 222 comprises 0.5% to 45% by weight of the graphene component based on the total weight of the second layer 222. In some embodiments, the second layer 222 comprises 0.5% to 40% by weight of the graphene component based on the total weight of the second layer 222. In some embodiments, the second layer 222 comprises 0.5% to 35% by weight of the graphene component based on the total weight of the second layer 222. In some embodiments, the second layer 222 comprises 0.5% to 30% by weight of the graphene component based on the total weight of the second layer 222. In some embodiments, the second layer 222 comprises 0.5% to 25% by weight of the graphene component based on the total weight of the second layer 222. In some embodiments, the second layer 222 comprises 0.5% to 20% by weight of the graphene component based on the total weight of the second layer 222. In some embodiments, the second layer 222 comprises 0.5% to 15% by weight of the graphene component based on the total weight of the second layer 222. In some embodiments, the second layer 222 comprises 0.5% to 10% by weight of the graphene component based on the total weight of the second layer 222. In some embodiments, the second layer 222 comprises 0.5% to 5% by weight of the graphene component based on the total weight of the second layer 222. In some embodiments, the second layer 222 comprises 0.5% to 4% by weight of the graphene component based on the total weight of the second layer 222. In some embodiments, the second layer 222 comprises 0.5% to 2% by weight of the graphene component based on the total weight of the second layer 222. In some embodiments, the second layer 222 comprises 0.5% to 1% by weight of the graphene component based on the total weight of the second layer 222.

In some embodiments, the second layer 222 comprises 1% to 50% by weight of the graphene component based on the total weight of the second layer 222. In some embodiments, the second layer 222 comprises 5% to 50% by weight of the graphene component based on the total weight of the second layer 222. In some embodiments, the second layer 222 comprises 10% to 50% by weight of the graphene component based on the total weight of the second layer 222. In some embodiments, the second layer 222 comprises 15% to 50% by weight of the graphene component based on the total weight of the second layer 222. In some embodiments, the second layer 222 comprises 20% to 50% by weight of the graphene component based on the total weight of the second layer 222. In some embodiments, the second layer 222 comprises 25% to 50% by weight of the graphene component based on the total weight of the second layer 222. In some embodiments, the second layer 222 comprises 30% to 50% by weight of the graphene component based on the total weight of the second layer 222. In some embodiments, the second layer 222 comprises 35% to 50% by weight of the graphene component based on the total weight of the second layer 222. In some embodiments, the second layer 222 comprises 40% to 50% by weight of the graphene component based on the total weight of the second layer 222. In some embodiments, the second layer 222 comprises 45% to 50% by weight of the graphene component based on the total weight of the second layer 222.

In some embodiments, the second layer 222 comprises at least 35% by volume of the graphene based on the total volume of the second layer 222. In some embodiments, the second layer 222 comprises at least 40% by volume of the graphene based on the total volume of the second layer 222. In some embodiments, the second layer 222 comprises at least 45% by volume of the graphene based on the total volume of the second layer 222. In some embodiments, the second layer 222 comprises at least 50% by volume of the graphene based on the total volume of the second layer 222. In some embodiments, the second layer 222 comprises at least 55% by volume of the graphene based on the total volume of the second layer 222. In some embodiments, the second layer 222 comprises at least 60% by volume of the graphene based on the total volume of the second layer 222. In some embodiments, the second layer 222 comprises at least 65% by volume of the graphene based on the total volume of the second layer 222. In some embodiments, the second layer 222 comprises at least 70% by volume of the graphene based on the total volume of the second layer 222.

In some embodiments, the second layer 222 comprises 35% to 70% by volume of the graphene based on the total volume of the second layer 222. In some embodiments, the second layer 222 comprises 35% to 65% by volume of the graphene based on the total volume of the second layer 222. In some embodiments, the second layer 222 comprises 35% to 60% by volume of the graphene based on the total volume of the second layer 222. In some embodiments, the second layer 222 comprises 35% to 55% by volume of the graphene based on the total volume of the second layer 222. In some embodiments, the second layer 222 comprises 35% to 50% by volume of the graphene based on the total volume of the second layer 222. In some embodiments, the second layer 222 comprises 35% to 45% by volume of the graphene based on the total volume of the second layer 222. In some embodiments, the second layer 222 comprises 35% to 40% by volume of the graphene based on the total volume of the second layer 222.

In some embodiments, the second layer 222 comprises 40% to 70% by volume of the graphene based on the total volume of the second layer 222. In some embodiments, the second layer 222 comprises 45% to 70% by volume of the graphene based on the total volume of the second layer 222. In some embodiments, the second layer 222 comprises 50% to 70% by volume of the graphene based on the total volume of the second layer 222. In some embodiments, the second layer 222 comprises 55% to 70% by volume of the graphene based on the total volume of the second layer 222. In some embodiments, the second layer 222 comprises 60% to 70% by volume of the graphene based on the total volume of the second layer 222. In some embodiments, the second layer 222 comprises 65% to 70% by volume of the graphene based on the total volume of the second layer 222.

In some embodiments, the graphene is characterized by a lateral size. As used herein, the term “lateral size” of the graphene refers to a length or an average length of at least one dimension of the graphene component. In some embodiments, the term “lateral size” of the graphene refers to a length of the greatest dimension of the graphene component. In some embodiments, the term “lateral size” of the graphene refers to an average length of the greatest dimension of the graphene component. In some embodiments, for example, the lateral size of graphene may refer to a radius. In some embodiments, the lateral size of graphene may refer to a diameter. In some embodiments, the lateral size of graphene may refer to a width. In some embodiments, the lateral size of graphene may refer to a height. In some embodiments, the lateral size of graphene may refer to a length. In some embodiments, the lateral size of the graphene may refer to a thickness. In some embodiments, the lateral size of the graphene may refer to a median particle size.

In some embodiments, a lateral size of the graphene is 800 μm or less. In some embodiments, the lateral size of the graphene is 600 μm or less. In some embodiments, the lateral size of the graphene is 500 μm or less. In some embodiments, the lateral size of the graphene is 400 μm or less. In some embodiments, the lateral size of the graphene is 300 μm or less. In some embodiments, the lateral size of the graphene is 200 μm or less. In some embodiments, the lateral size of the graphene is 0.01 nm to 800 nm. In some embodiments, the lateral size of the graphene is 5 nm to 800 nm. In some embodiments, the lateral size of the graphene is 10 nm to 500 nm. In some embodiments, the lateral size of the graphene is 10 nm to 400 nm. In some embodiments, the lateral size of the graphene is 10 nm to 200 nm. In some embodiments, the lateral size of the graphene is 5 nm to 150 nm. In some embodiments, the lateral size of the graphene is 10 nm to 500 μm. In some embodiments, the lateral size of the graphene is 50 nm to 500 μm. In some embodiments, the lateral size of the graphene is 100 nm to 500 μm. In some embodiments, the lateral size of the graphene is 200 nm to 500 μm. In some embodiments, the lateral size of the graphene is 200 nm to 20 μm. In some embodiments, the lateral size of the graphene is 500 nm to 5 μm. In some embodiments, the lateral size of the graphene is 5 μm to 20 μm. In some embodiments, the lateral size of the graphene is 200 nm to 500 nm. In some embodiments, the lateral size of the graphene is 0.5 μm to 5 μm.

In some embodiments, the lateral size of the graphene is 1 nm to 100 μm. In some embodiments, the lateral size of the graphene is 1 nm to 90 μm. In some embodiments, the lateral size of the graphene is 1 nm to 80 μm. In some embodiments, the lateral size of the graphene is 1 nm to 70 μm. In some embodiments, the lateral size of the graphene is 1 nm to 60 μm. In some embodiments, the lateral size of the graphene is 1 nm to 50 μm. In some embodiments, the lateral size of the graphene is 1 nm to 40 μm. In some embodiments, the lateral size of the graphene is 1 nm to 30 μm. In some embodiments, the lateral size of the graphene is 1 nm to 20 μm. In some embodiments, the lateral size of the graphene is 1 nm to 10 μm. In some embodiments, the lateral size of the graphene is 10 nm to 100 μm. In some embodiments, the lateral size of the graphene is 20 nm to 100 μm. In some embodiments, the lateral size of the graphene is 30 nm to 100 μm. In some embodiments, the lateral size of the graphene is 40 nm to 100 μm. In some embodiments, the lateral size of the graphene is 50 nm to 100 μm. In some embodiments, the lateral size of the graphene is 60 nm to 100 μm. In some embodiments, the lateral size of the graphene is 70 nm to 100 μm. In some embodiments, the lateral size of the graphene is nm to 100 μm. In some embodiments, the lateral size of the graphene is 80 nm to 100 μm. In some embodiments, the lateral size of the graphene is 90 nm to 100 μm. In some embodiments, the lateral size of the graphene is 10 nm to 70 μm. In some embodiments, the lateral size of the graphene is 1 μm to 2 μm.

In some embodiments, the graphene component comprises impurities. In some embodiments, the graphene component comprises no more than 4% by weight of impurities based on a total weight of the graphene component. In some embodiments, the graphene component comprises no more than 3% by weight of impurities based on the total weight of the graphene component. In some embodiments, the graphene component comprises no more than 2% by weight of impurities based on the total weight of the graphene component. In some embodiments, the graphene component comprises no more than 1% by weight of impurities based on the total weight of the graphene component. In some embodiments, the graphene component comprises 0.01% to 4% by weight of impurities based on the total weight of the graphene component. In some embodiments, the graphene component comprises 0.01% to 3.5% by weight of impurities based on the total weight of the graphene component. In some embodiments, the graphene component comprises 0.01% to 3% by weight of impurities based on the total weight of the graphene component. In some embodiments, the graphene component comprises 0.01% to 2.5% by weight of impurities based on the total weight of the graphene component. In some embodiments, the graphene component comprises 0.01% to 2% by weight of impurities based on the total weight of the graphene component. In some embodiments, the graphene component comprises 0.01% to 1.5% by weight of impurities based on the total weight of the graphene component. In some embodiments, the graphene component comprises 0.01% to 1% by weight of impurities based on the total weight of the graphene component. In some embodiments, the graphene component comprises 0.01% to 0.5% by weight of impurities based on the total weight of the graphene component. In some embodiments, the graphene component comprises 0.5% to 4% by weight of impurities based on the total weight of the graphene component. In some embodiments, the graphene component comprises 1% to 4% by weight of impurities based on the total weight of the graphene component. In some embodiments, the graphene component comprises 1.5% to 4% by weight of impurities based on the total weight of the graphene component. In some embodiments, the graphene component comprises 2% to 4% by weight of impurities based on the total weight of the graphene component. In some embodiments, the graphene component comprises 2.5% to 4% by weight of impurities based on the total weight of the graphene component. In some embodiments, the graphene component comprises 3% to 4% by weight of impurities based on the total weight of the graphene component. In some embodiments, the graphene component comprises 3.5% to 4% by weight of impurities based on the total weight of the graphene component. In some embodiments, the impurities comprise any substance other than graphene.

In some embodiments, the second layer 222 of the backsheet 102 comprises a polymeric material. In some embodiments, the second layer 222 of the backsheet 102 comprises one or more thermoplastic polymers. In some embodiments, the thermoplastic polymer comprises a polyolefin. In some embodiments, the thermoplastic polymer comprises a thermoplastic polyolefin (TPO). In some embodiments, the thermoplastic polyolefin comprises at least one of polyethylene, polypropylene, any copolymer thereof, any homopolymer thereof, any polymer blend thereof, or any combination thereof. In some embodiments, the thermoplastic polyolefin comprises at least one of a copolymer of propylene and ethylene, a blend of propylene and ethylene, a copolymer of ethylene alpha-olefin, a propylene homopolymer, an ethylene homopolymer, a propylene block copolymer, an ethylene block copolymer, a propylene elastomer, an ethylene elastomer, or any combination thereof. In some embodiments, the thermoplastic polymer comprises at least one of a copolymer comprising ethylene and octene, a copolymer comprising ethylene and hexane, a copolymer comprising ethylene and butene, polyethylene (including raw and/or recycled low density polyethylene (LDPE)), linear low density polyethylene (LLDPE), high density polyethylene (HDPE)), polypropylenes (e.g., isotactic polypropylene (IPP) and/or atactic polypropylene (APP/IPP)), amorphous polyalpha olefins (APAO), amorphous polyolefins (APO), or any combination thereof.

Such thermoplastic polymers can include, for example and without limitation, at least one of Vistamaxx® 6102, Vistamaxx® 8880, both of which are polypropylenes (e.g., isotactic polypropylene (IPP)) that are available from ExxonMobil, Irving, Tex.; Elvaloy®, which is a terpolymer that is available from Dow/DuPont, Wilmington, Del.; Fusabond®, which is a chemically modified ethylene acrylate copolymer and/or a modified polyethylene, that is available from Dow/DuPont, Wilmington, Del.; RT2304, which is an amorphous polyalpha olefin (APAO) that is available from Rextac APAO Polymers LLC, Odessa, Tex.; Eastoflex® P1023, which is an amorphous polyolefin (APO) that comprises a propylene homopolymer, and is available from Eastman Chemical Company, Kingsport, Tenn.; Eastoflex® E1060, which is an amorphous polyolefin (APO) that comprises a copolymer of propylene and ethylene, and is available from Eastman Chemical Company, Kingsport, Tenn.; Eastoflex® M1025, which is an amorphous polyolefin (APO) that comprises a blend of propylene homopolymer and copolymers of propylene and ethylene, and is available from Eastman Chemical Company, Kingsport, Tenn.; Engage® 7487, which is a polyolefin elastomer (POE) that is available from Dow Inc., Midland, Mich., or any combination thereof.

In some embodiments, the second layer 222 of the backsheet 202 comprises polyethylene terephthalate (PET). In some embodiments, the second layer 222 of the backsheet 202 comprises ethylene tetrafluoroethylene (ETFE). In some embodiments, the second layer 222 of the backsheet 202 comprises an acrylic such as polymethyl methacrylate (PMMA). In some embodiments, the second layer 222 of the backsheet 202 comprises thermoplastic polyolefin (TPO). In some embodiments, the second layer 222 of the backsheet 202 comprises a single ply TPO roofing membrane. In other embodiments, non-limiting examples of TPO membranes are disclosed in U.S. Pat. No. 9,359,014 to Yang et al., which is incorporated by reference herein in its entirety. In some embodiments, the second layer 222 of the backsheet 202 comprises polyvinyl chloride. In some embodiments, the second layer 222 of the backsheet 202 comprises ethylene propylene diene monomer (EPDM) rubber. In some embodiments, the second layer 222 of the backsheet 202 comprises a flame retardant. In some embodiments, the flame retardant comprises at least one of clays, nanoclays, silicas, carbon black, metal hydroxides such as aluminum hydroxide, metal foils, graphite, expandable graphite, or any combination thereof. In some embodiments, the second layer 222 of the backsheet 202 is white in color. In some embodiments, the second layer 222 of the backsheet 202 is white TPO.

In some embodiments, the second layer 222 comprises 50% to 99.5% by weight of the polymeric material based on the total weight of the second layer 222. In some embodiments, the second layer 222 comprises 50% to 95% by weight of the polymeric material based on the total weight of the second layer 222. In some embodiments, the second layer 222 comprises 50% to 90% by weight of the polymeric material based on the total weight of the second layer 222. In some embodiments, the second layer 222 comprises 50% to 85% by weight of the polymeric material based on the total weight of the second layer 222. In some embodiments, the second layer 222 comprises 50% to 80% by weight of the polymeric material based on the total weight of the second layer 222. In some embodiments, the second layer 222 comprises 50% to 75% by weight of the polymeric material based on the total weight of the second layer 222. In some embodiments, the second layer 222 comprises 50% to 70% by weight of the polymeric material based on the total weight of the second layer 222. In some embodiments, the second layer 222 comprises 50% to 65% by weight of the polymeric material based on the total weight of the second layer 222. In some embodiments, the second layer 222 comprises 50% to 60% by weight of the polymeric material based on the total weight of the second layer 222. In some embodiments, the second layer 222 comprises 50% to 55% by weight of the polymeric material based on the total weight of the second layer 222.

In some embodiments, the second layer 222 comprises 55% to 99.5% by weight of the polymeric material based on the total weight of the second layer 222. In some embodiments, the second layer 222 comprises 60% to 99.5% by weight of the polymeric material based on the total weight of the second layer 222. In some embodiments, the second layer 222 comprises 65% to 99.5% by weight of the polymeric material based on the total weight of the second layer 222. In some embodiments, the second layer 222 comprises 70% to 99.5% by weight of the polymeric material based on the total weight of the second layer 222. In some embodiments, the second layer 222 comprises 75% to 99.5% by weight of the polymeric material based on the total weight of the second layer 222. In some embodiments, the second layer 222 comprises 80% to 99.5% by weight of the polymeric material based on the total weight of the second layer 222. In some embodiments, the second layer 222 comprises 85% to 99.5% by weight of the polymeric material based on the total weight of the second layer 222. In some embodiments, the second layer 222 comprises 90% to 99.5% by weight of the polymeric material based on the total weight of the second layer 222. In some embodiments, the second layer 222 comprises 95% to 99.5% by weight of the polymeric material based on the total weight of the second layer 222.

In some embodiments, the second layer 222 has a thickness of 0.2 mm to 4 mm. In some embodiments, the second layer 222 has a thickness of 0.2 mm to 3.5 mm. In some embodiments, the second layer 222 has a thickness of 0.2 mm to 3 mm. In some embodiments, the second layer 222 has a thickness of 0.2 mm to 2.5 mm. In some embodiments, the second layer 222 has a thickness of 0.2 mm to 2 mm. In some embodiments, the second layer 222 has a thickness of 0.2 mm to 1.5 mm. In some embodiments, the second layer 222 has a thickness of 0.2 mm to 1 mm. In some embodiments, the second layer 222 has a thickness of 0.2 mm to 0.5 mm. In some embodiments, the second layer 222 has a thickness of 0.5 mm to 4 mm. In some embodiments, the second layer 222 has a thickness of 1 mm to 4 mm. In some embodiments, the second layer 222 has a thickness of 1.5 mm to 4 mm. In some embodiments, the second layer 222 has a thickness of 2 mm to 4 mm. In some embodiments, the second layer 222 has a thickness of 2.5 mm to 4 mm. In some embodiments, the second layer 222 has a thickness of 3 mm to 4 mm. In some embodiments, the second layer 222 has a thickness of 3.5 mm to 4 mm.

In some embodiments, the second layer 222 has a thickness of 0.2 mm to 0.5 mm. In another embodiment, the second layer 222 has a thickness of 0.2 mm to 0.4 mm. In another embodiment, the second layer 222 has a thickness of 0.2 mm to 0.3 mm. In some embodiments, the second layer 222 has a thickness of 0.3 mm to 0.5 mm. In another embodiment, the second layer 222 has a thickness of 0.3 mm to 0.4 mm. In some embodiments, the second layer 222 has a thickness of 0.4 mm to 0.5 mm. In some embodiments, the second layer 222 has a thickness of 0.2 mm. In some embodiments, the second layer 222 has a thickness of 0.3 mm. In some embodiments, the second layer 222 has a thickness of 0.4 mm. In some embodiments, the second layer 222 has a thickness of 0.5 mm.

In some embodiments, the second layer 222 has a thickness of 1 mm to 5 mm. In some embodiments, the second layer 222 has a thickness of 1 mm to 4 mm. In some embodiments, the second layer 222 has a thickness of 1 mm to 3.5 mm. In some embodiments, the second layer 222 has a thickness of 1 mm to 3 mm. In some embodiments, the second layer 222 has a thickness of 1 mm to 2.5 mm. In some embodiments, the second layer 222 has a thickness of 1 mm to 2 mm. In some embodiments, the second layer 222 has a thickness of 1 mm to 1.5 mm. In some embodiments, the second layer 222 has a thickness of 2 mm to 5 mm. In some embodiments, the second layer 222 has a thickness of 2 mm to 4 mm. In some embodiments, the second layer 222 has a thickness of 2 mm to 3.5 mm. In some embodiments, the second layer 222 has a thickness of 2 mm to 3 mm. In some embodiments, the second layer 222 has a thickness of 3 mm to 5 mm. In some embodiments, the second layer 222 has a thickness of 3 mm to 4 mm. In some embodiments, the second layer 222 has a thickness of 4 mm to 5 mm. In some embodiments, the second layer 222 has a thickness of 1 mm. In some embodiments, the second layer 222 has a thickness of 2 mm. In some embodiments, the second layer 222 has a thickness of 3 mm. In some embodiments, the second layer 222 has a thickness of 4 mm. In some embodiments, the second layer 222 has a thickness of 5 mm.

In some embodiments, the second layer 222 has a thickness of 1 mm to 10 mm. In some embodiments, the second layer 222 has a thickness of 1 mm to 9 mm. In some embodiments, the second layer 222 has a thickness of 1 mm to 8 mm. In some embodiments, the second layer 222 has a thickness of 1 mm to 7 mm. In some embodiments, the second layer 222 has a thickness of 1 mm to 6 mm. In some embodiments, the second layer 222 has a thickness of 4 mm to 10 mm. In some embodiments, the second layer 222 has a thickness of 5 mm to 10 mm. In some embodiments, the second layer 222 has a thickness of 6 mm to 10 mm. In some embodiments, the second layer 222 has a thickness of 7 mm to 10 mm. In some embodiments, the second layer 222 has a thickness of 8 mm to 10 mm. In some embodiments, the second layer 222 has a thickness of 9 mm to 10 mm.

In some embodiments, the second layer 222 has a thermal conductivity of 0.3 W m⁻¹ K⁻¹ to 3 W m⁻¹ K⁻¹. In some embodiments, the second layer 222 has a thermal conductivity of 0.3 W m⁻¹ K⁻¹ to 2.9 W m⁻¹ K⁻¹. In some embodiments, the second layer 222 has a thermal conductivity of 0.3 W m⁻¹ K⁻¹ to 2.8 W m⁻¹ K⁻¹. In some embodiments, the second layer 222 has a thermal conductivity of 0.3 W m⁻¹ K⁻¹ to 2.7 W m⁻¹ K⁻¹. In some embodiments, the second layer 222 has a thermal conductivity of 0.3 W m⁻¹ K⁻¹ to 2.6 W m⁻¹ K⁻¹. In some embodiments, the second layer 222 has a thermal conductivity of 0.3 W m⁻¹ K⁻¹ to 2.5 W m⁻¹ K⁻¹. In some embodiments, the second layer 222 has a thermal conductivity of 0.3 W m⁻¹ K⁻¹ to 2.4 W m⁻¹ K⁻¹. In some embodiments, the second layer 222 has a thermal conductivity of 0.3 W m⁻¹ K⁻¹ to 2.3 W m⁻¹ K⁻¹. In some embodiments, the second layer 222 has a thermal conductivity of 0.3 W m⁻¹ K⁻¹ to 2.2 W m⁻¹ K⁻¹. In some embodiments, the second layer 222 has a thermal conductivity of 0.3 W m⁻¹ K⁻¹ to 2.1 W m⁻¹ K⁻¹. In some embodiments, the second layer 222 has a thermal conductivity of 0.3 W m⁻¹ K⁻¹ to 2 W m⁻¹ K⁻¹. In some embodiments, the second layer 222 has a thermal conductivity of 0.3 W m⁻¹ K⁻¹ to 1.9 W m⁻¹ K⁻¹. In some embodiments, the second layer 222 has a thermal conductivity of 0.3 W m⁻¹ K⁻¹ to 1.8 W m⁻¹ K⁻¹. In some embodiments, the second layer 222 has a thermal conductivity of 0.3 W m⁻¹ K⁻¹ to 1.7 W m⁻¹ K⁻¹. In some embodiments, the second layer 222 has a thermal conductivity of 0.3 W m⁻¹ K⁻¹ to 1.6 W m⁻¹ K⁻¹. In some embodiments, the second layer 222 has a thermal conductivity of 0.3 W m⁻¹ K⁻¹ to 1.5 W m⁻¹ K⁻¹. In some embodiments, the second layer 222 has a thermal conductivity of 0.3 W m⁻¹ K⁻¹ to 1.4 W m⁻¹ K⁻¹. In some embodiments, the second layer 222 has a thermal conductivity of 0.3 W m⁻¹ K⁻¹ to 1.3 W m⁻¹ K⁻¹. In some embodiments, the second layer 222 has a thermal conductivity of 0.3 W m⁻¹ K⁻¹ to 1.2 W m⁻¹ K⁻¹. In some embodiments, the second layer 222 has a thermal conductivity of 0.3 W m⁻¹ K⁻¹ to 1.1 W m⁻¹ K⁻¹. In some embodiments, the second layer 222 has a thermal conductivity of 0.3 W m⁻¹ K⁻¹ to 1 W m⁻¹ K⁻¹. In some embodiments, the second layer 222 has a thermal conductivity of 0.3 W m⁻¹ K⁻¹ to 0.9 W m⁻¹ K⁻¹. In some embodiments, the second layer 222 has a thermal conductivity of 0.3 W m⁻¹ K⁻¹ to 0.8 W m⁻¹ K⁻¹. In some embodiments, the second layer 222 has a thermal conductivity of 0.3 W m⁻¹ K⁻¹ to 0.7 W m⁻¹ K⁻¹. In some embodiments, the second layer 222 has a thermal conductivity of 0.3 W m⁻¹ K⁻¹ to 0.6 W m⁻¹ K⁻¹. In some embodiments, the second layer 222 has a thermal conductivity of 0.3 W m⁻¹ K⁻¹ to 0.5 W m⁻¹ K⁻¹. In some embodiments, the second layer 222 has a thermal conductivity of 0.3 W m⁻¹ K⁻¹ to 0.4 W m⁻¹ K⁻¹.

In some embodiments, the second layer 222 has a thermal conductivity of 0.3 W m⁻¹ K⁻¹ to 3 W m⁻¹ K⁻¹. In some embodiments, the second layer 222 has a thermal conductivity of 0.4 W m⁻¹ K⁻¹ to 3 W m⁻¹ K⁻¹. In some embodiments, the second layer 222 has a thermal conductivity of 0.5 W m⁻¹ K⁻¹ to 3 W m⁻¹ K⁻¹. In some embodiments, the second layer 222 has a thermal conductivity of 0.6 W m⁻¹ K⁻¹ to 3 W m⁻¹ K⁻¹. In some embodiments, the second layer 222 has a thermal conductivity of 0.7 W m⁻¹ K⁻¹ to 3 W m⁻¹ K⁻¹. In some embodiments, the second layer 222 has a thermal conductivity of 0.8 W m⁻¹ K⁻¹ to 3 W m⁻¹ K⁻¹. In some embodiments, the second layer 222 has a thermal conductivity of 0.9 W m⁻¹ K⁻¹ to 3 W m⁻¹ K⁻¹. In some embodiments, the second layer 222 has a thermal conductivity of 1 W m⁻¹ K⁻¹ to 3 W m⁻¹ K⁻¹. In some embodiments, the second layer 222 has a thermal conductivity of 1.1 W m⁻¹ K⁻¹ to 3 W m⁻¹ K⁻¹. In some embodiments, the second layer 222 has a thermal conductivity of 1.2 W m⁻¹ K⁻¹ to 3 W m⁻¹ K⁻¹. In some embodiments, the second layer 222 has a thermal conductivity of 1.3 W m⁻¹ K⁻¹ to 3 W m⁻¹ K⁻¹. In some embodiments, the second layer 222 has a thermal conductivity of 1.4 W m⁻¹ K⁻¹ to 3 W m⁻¹ K⁻¹. In some embodiments, the second layer 222 has a thermal conductivity of 1.5 W m⁻¹ K⁻¹ to 3 W m⁻¹ K⁻¹. In some embodiments, the second layer 222 has a thermal conductivity of 1.6 W m⁻¹ K⁻¹ to 3 W m⁻¹ K⁻¹. In some embodiments, the second layer 222 has a thermal conductivity of 1.7 W m⁻¹ K⁻¹ to 3 W m⁻¹ K⁻¹. In some embodiments, the second layer 222 has a thermal conductivity of 1.8 W m⁻¹ K⁻¹ to 3 W m⁻¹ K⁻¹. In some embodiments, the second layer 222 has a thermal conductivity of 1.9 W m⁻¹ K⁻¹ to 3 W m⁻¹ K⁻¹. In some embodiments, the second layer 222 has a thermal conductivity of 2 W m⁻¹ K⁻¹ to 3 W m⁻¹ K⁻¹. In some embodiments, the second layer 222 has a thermal conductivity of 2.1 W m⁻¹ K⁻¹ to 3 W m⁻¹ K⁻¹. In some embodiments, the second layer 222 has a thermal conductivity of 2.2 W m⁻¹ K⁻¹ to 3 W m⁻¹ K⁻¹. In some embodiments, the second layer 222 has a thermal conductivity of 2.3 W m⁻¹ K⁻¹ to 3 W m⁻¹ K⁻¹. In some embodiments, the second layer 222 has a thermal conductivity of 2.4 W m⁻¹ K⁻¹ to 3 W m⁻¹ K⁻¹. In some embodiments, the second layer 222 has a thermal conductivity of 2.5 W m⁻¹ K⁻¹ to 3 W m⁻¹ K⁻¹. In some embodiments, the second layer 222 has a thermal conductivity of 2.6 W m⁻¹ K⁻¹ to 3 W m⁻¹ K⁻¹. In some embodiments, the second layer 222 has a thermal conductivity of 2.7 W m⁻¹ K⁻¹ to 3 W m⁻¹ K⁻¹. In some embodiments, the second layer 222 has a thermal conductivity of 2.8 W m⁻¹ K⁻¹ to 3 W m⁻¹ K⁻¹. In some embodiments, the second layer 222 has a thermal conductivity of 2.9 W m⁻¹ K⁻¹ to 3 W m⁻¹ K⁻¹.

In some embodiments, the third layer 220 is an adhesive layer. In some embodiments, the adhesive layer comprises at least one of thermosetting polyolefin, thermosetting polyolefin encapsulant material, thermosetting ethylene-vinyl acetate (EVA), EVA encapsulants, thermoplastic olefin, thermoplastic polyolefin (TPO), any hybrids thereof, any combinations thereof. In some embodiments, the adhesive layer comprises at least one of polyvinyl butyrate, acrylic, silicone, polycarbonate, or any combination thereof. In some embodiments, the adhesive layer comprises pressure sensitive adhesives.

In some embodiments, the third layer 220 has a thickness of 0.2 mm to 2 mm. In some embodiments, the third layer 220 has a thickness of 0.2 mm to 1.5 mm. In some embodiments, the third layer 220 has a thickness of 0.2 mm to 1 mm. In some embodiments, the third layer 220 has a thickness of 0.2 mm to 0.5 mm. In some embodiments, the third layer 220 has a thickness of 0.5 mm to 2 mm. In some embodiments, the third layer 220 has a thickness of 0.5 mm to 1.5 mm. In some embodiments, the third layer 220 has a thickness of 0.5 mm to 1 mm. In some embodiments, the third layer 220 has a thickness of 1 mm to 2 mm. In some embodiments, the third layer 220 has a thickness of 1 mm to 1.5 mm. In some embodiments, the third layer 220 has a thickness of 1.5 mm to 2 mm.

In some embodiments, the third layer 220 has a thickness of 0.2 mm. In some embodiments, the third layer 220 has a thickness of 0.3 mm. In some embodiments, the third layer 220 has a thickness of 0.4 mm. In some embodiments, the third layer 220 has a thickness of 0.45 mm. In some embodiments, the third layer 220 has a thickness of 0.5 mm. In some embodiments, the third layer 220 has a thickness of 1 mm. In some embodiments, the third layer 220 has a thickness of 1.5 mm. In some embodiments, the third layer 220 has a thickness of 2 mm. In some embodiments, the third layer 220 has a thickness of 2.5 mm. In some embodiments, the third layer 220 has a thickness of 3 mm. In some embodiments, the third layer 220 has a thickness of 3.5 mm. In some embodiments, the third layer 220 has a thickness of 4 mm.

In another embodiment, the third layer 220 has a thickness of 1 μm to 900 μm. In some embodiments, the third layer 220 has a thickness of 1 μm to 900 μm. In some embodiments, the third layer 220 has a thickness of 1 μm to 850 μm. In some embodiments, the third layer 220 has a thickness of 1 μm to 800 μm. In some embodiments, the third layer 220 has a thickness of 1 μm to 750 μm. In some embodiments, the third layer 220 has a thickness of 1 μm to 700 μm. In some embodiments, the third layer 220 has a thickness of 1 μm to 650 μm. In some embodiments, the third layer 220 has a thickness of 1 μm to 600 μm. In some embodiments, the third layer 220 has a thickness of 1 μm to 550 μm. In some embodiments, the third layer 220 has a thickness of 1 μm to 500 μm. In some embodiments, the third layer 220 has a thickness of 1 μm to 450 μm. In some embodiments, the third layer 220 has a thickness of 1 μm to 400 μm. In some embodiments, the third layer 220 has a thickness of 1 μm to 350 μm. In some embodiments, the third layer 220 has a thickness of 1 μm to 300 μm. In some embodiments, the third layer 220 has a thickness of 1 μm to 250 μm. In some embodiments, the third layer 220 has a thickness of 1 μm to 200 μm. In some embodiments, the third layer 220 has a thickness of 1 μm to 150 μm. In some embodiments, the third layer 220 has a thickness of 1 μm to 100 μm. In some embodiments, the third layer 220 has a thickness of 1 μm to 50 μm.

In some embodiments, the third layer 220 has a thickness of 50 μm to 900 μm. In some embodiments, the third layer 220 has a thickness of 50 μm to 850 μm. In some embodiments, the third layer 220 has a thickness of 50 μm to 800 μm. In some embodiments, the third layer 220 has a thickness of 50 μm to 750 μm. In some embodiments, the third layer 220 has a thickness of 50 μm to 700 μm. In some embodiments, the third layer 220 has a thickness of 50 μm to 650 μm. In some embodiments, the third layer 220 has a thickness of 50 μm to 600 μm. In some embodiments, the third layer 220 has a thickness of 50 μm to 550 μm. In some embodiments, the third layer 220 has a thickness of 50 μm to 500 μm. In some embodiments, the third layer 220 has a thickness of 50 μm to 450 μm. In some embodiments, the third layer 220 has a thickness of 50 μm to 400 μm. In some embodiments, the third layer 220 has a thickness of 50 μm to 350 μm. In some embodiments, the third layer 220 has a thickness of 50 μm to 300 μm. In some embodiments, the third layer 220 has a thickness of 50 μm to 250 μm. In some embodiments, the third layer 220 has a thickness of 50 μm to 200 μm. In some embodiments, the third layer 220 has a thickness of 50 μm to 150 μm. In some embodiments, the third layer 220 has a thickness of 50 μm to 100 μm.

In some embodiments, the third layer 220 has a thickness of 100 μm to 900 μm. In some embodiments, the third layer 220 has a thickness of 100 μm to 850 μm. In some embodiments, the third layer 220 has a thickness of 100 μm to 800 μm. In some embodiments, the third layer 220 has a thickness of 100 μm to 750 μm. In some embodiments, the third layer 220 has a thickness of 100 μm to 700 μm. In some embodiments, the third layer 220 has a thickness of 100 μm to 650 μm. In some embodiments, the third layer 220 has a thickness of 100 μm to 600 μm. In some embodiments, the third layer 220 has a thickness of 100 μm to 550 μm. In some embodiments, the third layer 220 has a thickness of 100 μm to 500 μm. In some embodiments, the third layer 220 has a thickness of 100 μm to 450 μm. In some embodiments, the third layer 220 has a thickness of 100 μm to 400 μm. In some embodiments, the third layer 220 has a thickness of 100 μm to 350 μm. In some embodiments, the third layer 220 has a thickness of 100 μm to 300 μm. In some embodiments, the third layer 220 has a thickness of 100 μm to 250 μm. In some embodiments, the third layer 220 has a thickness of 100 μm to 200 μm. In some embodiments, the third layer 220 has a thickness of 100 μm to 150 μm.

In some embodiments, the third layer 220 has a thickness of 150 μm to 900 μm. In some embodiments, the third layer 220 has a thickness of 150 μm to 850 μm. In some embodiments, the third layer 220 has a thickness of 150 μm to 800 μm. In some embodiments, the third layer 220 has a thickness of 150 μm to 750 μm. In some embodiments, the third layer 220 has a thickness of 150 μm to 700 μm. In some embodiments, the third layer 220 has a thickness of 150 μm to 650 μm. In some embodiments, the third layer 220 has a thickness of 150 μm to 600 μm. In some embodiments, the third layer 220 has a thickness of 150 μm to 550 μm. In some embodiments, the third layer 220 has a thickness of 150 μm to 500 μm. In some embodiments, the third layer 220 has a thickness of 150 μm to 450 μm. In some embodiments, the third layer 220 has a thickness of 150 μm to 400 μm. In some embodiments, the third layer 220 has a thickness of 150 μm to 350 μm. In some embodiments, the third layer 220 has a thickness of 150 μm to 300 μm. In some embodiments, the third layer 220 has a thickness of 150 μm to 250 μm. In some embodiments, the third layer 220 has a thickness of 150 μm to 200 μm.

In some embodiments, the third layer 220 has a thickness of 200 μm to 900 μm. In some embodiments, the third layer 220 has a thickness of 200 μm to 850 μm. In some embodiments, the third layer 220 has a thickness of 200 μm to 800 μm. In some embodiments, the third layer 220 has a thickness of 200 μm to 750 μm. In some embodiments, the third layer 220 has a thickness of 200 μm to 700 μm. In some embodiments, the third layer 220 has a thickness of 200 μm to 650 μm. In some embodiments, the third layer 220 has a thickness of 200 μm to 600 μm. In some embodiments, the third layer 220 has a thickness of 200 μm to 550 μm. In some embodiments, the third layer 220 has a thickness of 200 μm to 500 μm. In some embodiments, the third layer 220 has a thickness of 200 μm to 450 μm. In some embodiments, the third layer 220 has a thickness of 200 μm to 400 μm. In some embodiments, the third layer 220 has a thickness of 200 μm to 350 μm. In some embodiments, the third layer 220 has a thickness of 200 μm to 300 μm. In some embodiments, the third layer 220 has a thickness of 200 μm to 250 μm.

In some embodiments, the third layer 220 has a thickness of 250 μm to 900 μm. In some embodiments, the third layer 220 has a thickness of 250 μm to 850 μm. In some embodiments, the third layer 220 has a thickness of 250 μm to 800 μm. In some embodiments, the third layer 220 has a thickness of 250 μm to 750 μm. In some embodiments, the third layer 220 has a thickness of 250 μm to 700 μm. In some embodiments, the third layer 220 has a thickness of 250 μm to 650 μm. In some embodiments, the third layer 220 has a thickness of 250 μm to 600 μm. In some embodiments, the third layer 220 has a thickness of 250 μm to 550 μm. In some embodiments, the third layer 220 has a thickness of 250 μm to 500 μm. In some embodiments, the third layer 220 has a thickness of 250 μm to 450 μm. In some embodiments, the third layer 220 has a thickness of 250 μm to 400 μm. In some embodiments, the third layer 220 has a thickness of 250 μm to 350 μm. In some embodiments, the third layer 220 has a thickness of 250 μm to 300 μm.

In some embodiments, the third layer 220 has a thickness of 300 μm to 900 μm. In some embodiments, the third layer 220 has a thickness of 300 μm to 850 μm. In some embodiments, the third layer 220 has a thickness of 300 μm to 800 μm. In some embodiments, the third layer 220 has a thickness of 300 μm to 750 μm. In some embodiments, the third layer 220 has a thickness of 300 μm to 700 μm. In some embodiments, the third layer 220 has a thickness of 300 μm to 650 μm. In some embodiments, the third layer 220 has a thickness of 300 μm to 600 μm. In some embodiments, the third layer 220 has a thickness of 300 μm to 550 μm. In some embodiments, the third layer 220 has a thickness of 300 μm to 500 μm. In some embodiments, the third layer 220 has a thickness of 300 μm to 450 μm. In some embodiments, the third layer 220 has a thickness of 300 μm to 400 μm. In some embodiments, the third layer 220 has a thickness of 300 μm to 350 μm.

In some embodiments, the third layer 220 has a thickness of 350 μm to 900 μm. In some embodiments, the third layer 220 has a thickness of 350 μm to 850 μm. In some embodiments, the third layer 220 has a thickness of 350 μm to 800 μm. In some embodiments, the third layer 220 has a thickness of 350 μm to 750 μm. In some embodiments, the third layer 220 has a thickness of 350 μm to 700 μm. In some embodiments, the third layer 220 has a thickness of 350 μm to 650 μm. In some embodiments, the third layer 220 has a thickness of 350 μm to 600 μm. In some embodiments, the third layer 220 has a thickness of 350 μm to 550 μm. In some embodiments, the third layer 220 has a thickness of 350 μm to 500 μm. In some embodiments, the third layer 220 has a thickness of 350 μm to 450 μm. In some embodiments, the third layer 220 has a thickness of 350 μm to 400 μm.

In some embodiments, the third layer 220 has a thickness of 400 μm to 900 μm. In some embodiments, the third layer 220 has a thickness of 400 μm to 850 μm. In some embodiments, the third layer 220 has a thickness of 400 μm to 800 μm. In some embodiments, the third layer 220 has a thickness of 400 μm to 750 μm. In some embodiments, the third layer 220 has a thickness of 400 μm to 700 μm. In some embodiments, the third layer 220 has a thickness of 400 μm to 650 μm. In some embodiments, the third layer 220 has a thickness of 400 μm to 600 μm. In some embodiments, the third layer 220 has a thickness of 400 μm to 550 μm. In some embodiments, the third layer 220 has a thickness of 400 μm to 500 μm. In some embodiments, the third layer 220 has a thickness of 400 μm to 450 μm.

In some embodiments, the third layer 220 has a thickness of 450 μm to 900 μm. In some embodiments, the third layer 220 has a thickness of 450 μm to 850 μm. In some embodiments, the third layer 220 has a thickness of 450 μm to 800 μm. In some embodiments, the third layer 220 has a thickness of 450 μm to 750 μm. In some embodiments, the third layer 220 has a thickness of 450 μm to 700 μm. In some embodiments, the third layer 220 has a thickness of 450 μm to 650 μm. In some embodiments, the third layer 220 has a thickness of 450 μm to 600 μm. In some embodiments, the third layer 220 has a thickness of 450 μm to 550 μm. In some embodiments, the third layer 220 has a thickness of 450 μm to 500 μm.

In some embodiments, the third layer 220 has a thickness of 500 μm to 900 μm. In some embodiments, the third layer 220 has a thickness of 500 μm to 850 μm. In some embodiments, the third layer 220 has a thickness of 500 μm to 800 μm. In some embodiments, the third layer 220 has a thickness of 500 μm to 750 μm. In some embodiments, the third layer 220 has a thickness of 500 μm to 700 μm. In some embodiments, the third layer 220 has a thickness of 500 μm to 650 μm. In some embodiments, the third layer 220 has a thickness of 500 μm to 600 μm. In some embodiments, the third layer 220 has a thickness of 500 μm to 550 μm.

In some embodiments, the third layer 220 has a thickness of 550 μm to 900 μm. In some embodiments, the third layer 220 has a thickness of 550 μm to 850 μm. In some embodiments, the third layer 220 has a thickness of 550 μm to 800 μm. In some embodiments, the third layer 220 has a thickness of 550 μm to 750 μm. In some embodiments, the third layer 220 has a thickness of 550 μm to 700 μm. In some embodiments, the third layer 220 has a thickness of 550 μm to 650 μm. In some embodiments, the third layer 220 has a thickness of 550 μm to 600 μm.

In some embodiments, the third layer 220 has a thickness of 600 μm to 900 μm. In some embodiments, the third layer 220 has a thickness of 600 μm to 850 μm. In some embodiments, the third layer 220 has a thickness of 600 μm to 800 μm. In some embodiments, the third layer 220 has a thickness of 600 μm to 750 μm. In some embodiments, the third layer 220 has a thickness of 600 μm to 700 μm. In some embodiments, the third layer 220 has a thickness of 600 μm to 650 μm.

In some embodiments, the third layer 220 has a thickness of 650 μm to 900 μm. In some embodiments, the third layer 220 has a thickness of 650 μm to 850 μm. In some embodiments, the third layer 220 has a thickness of 650 μm to 800 μm. In some embodiments, the third layer 220 has a thickness of 650 μm to 750 μm. In some embodiments, the third layer 220 has a thickness of 650 μm to 700 μm. In some embodiments, the third layer 220 has a thickness of 700 μm to 900 μm. In some embodiments, the third layer 220 has a thickness of 700 μm to 850 μm. In some embodiments, the third layer 220 has a thickness of 700 μm to 800 μm. In some embodiments, the third layer 220 has a thickness of 700 μm to 750 μm. In some embodiments, the third layer 220 has a thickness of 750 μm to 900 μm. In some embodiments, the third layer 220 has a thickness of 750 μm to 850 μm. In some embodiments, the third layer 220 has a thickness of 750 μm to 800 μm. In some embodiments, the third layer 220 has a thickness of 800 μm to 900 μm. In some embodiments, the third layer 220 has a thickness of 800 μm to 850 μm. In some embodiments, the third layer 220 has a thickness of 850 μm to 900 μm.

In some embodiments, the third layer 220 has a thickness of 1 μm. In some embodiments, the third layer 220 has a thickness of 50 μm. In some embodiments, the third layer 220 has a thickness of 100 μm. In some embodiments, the third layer 220 has a thickness of 1 μm. In some embodiments, the third layer 220 has a thickness of 150 μm. In some embodiments, the third layer 220 has a thickness of 200 μm. In some embodiments, the third layer 220 has a thickness of 250 μm. In some embodiments, the third layer 220 has a thickness of 300 μm. In some embodiments, the third layer 220 has a thickness of 350 μm. In some embodiments, the third layer 220 has a thickness of 400 μm. In some embodiments, the third layer 220 has a thickness of 450 μm. In some embodiments, the third layer 220 has a thickness of 500 μm. In some embodiments, the third layer 220 has a thickness of 550 μm. In some embodiments, the third layer 220 has a thickness of 600 μm. In some embodiments, the third layer 220 has a thickness of 650 μm. In some embodiments, the third layer 220 has a thickness of 700 μm. In some embodiments, the third layer 220 has a thickness of 750 μm. In some embodiments, the third layer 220 has a thickness of 800 μm. In some embodiments, the third layer 220 has a thickness of 850 μm. In some embodiments, the third layer 220 has a thickness of 900 μm.

In some embodiments, the backsheet 202 has a thickness of 1 mm to 10 mm. In some embodiments, the backsheet 202 has a thickness of 1 mm to 9 mm. In some embodiments, the backsheet 202 has a thickness of 1 mm to 8 mm. In some embodiments, the backsheet 202 has a thickness of 1 mm to 7 mm. In some embodiments, the backsheet 202 has a thickness of 1 mm to 6 mm. In some embodiments, the backsheet 202 has a thickness of 4 mm to 10 mm. In some embodiments, the backsheet 202 has a thickness of 5 mm to 10 mm. In some embodiments, the backsheet 202 has a thickness of 6 mm to 10 mm. In some embodiments, the backsheet 202 has a thickness of 7 mm to 10 mm. In some embodiments, the backsheet 202 has a thickness of 8 mm to 10 mm. In some embodiments, the backsheet 202 has a thickness of 9 mm to 10 mm. In some embodiments, the thickness of the backsheet 202 is different from a thickness of the encapsulant layer 210, the encapsulant layer 224, or both.

In some embodiments, the backsheet 202 has a thermal conductivity of 0.3 W m⁻¹ K⁻¹ to 3 W m⁻¹ K⁻¹. In some embodiments, the backsheet 202 has a thermal conductivity of 0.3 W m⁻¹ K⁻¹ to 2.9 W m⁻¹ K⁻¹. In some embodiments, the backsheet 202 has a thermal conductivity of 0.3 W m⁻¹ K⁻¹ to 2.8 W m⁻¹ K⁻¹. In some embodiments, the backsheet 202 has a thermal conductivity of 0.3 W m⁻¹ K⁻¹ to 2.7 W m⁻¹ K⁻¹. In some embodiments, the backsheet 202 has a thermal conductivity of 0.3 W m⁻¹ K⁻¹ to 2.6 W m⁻¹ K⁻¹. In some embodiments, the backsheet 202 has a thermal conductivity of 0.3 W m⁻¹ K⁻¹ to 2.5 W m⁻¹ K⁻¹. In some embodiments, the backsheet 202 has a thermal conductivity of 0.3 W m⁻¹ K⁻¹ to 2.4 W m⁻¹ K⁻¹. In some embodiments, the backsheet 202 has a thermal conductivity of 0.3 W m⁻¹ K⁻¹ to 2.3 W m⁻¹ K⁻¹. In some embodiments, the backsheet 202 has a thermal conductivity of 0.3 W m⁻¹ K⁻¹ to 2.2 W m⁻¹ K⁻¹. In some embodiments, the backsheet 202 has a thermal conductivity of 0.3 W m⁻¹ K⁻¹ to 2.1 W m⁻¹ K⁻¹. In some embodiments, the backsheet 202 has a thermal conductivity of 0.3 W m⁻¹ K⁻¹ to 2 W m⁻¹ K⁻¹. In some embodiments, the backsheet 202 has a thermal conductivity of 0.3 W m⁻¹ K⁻¹ to 1.9 W m⁻¹ K⁻¹. In some embodiments, the backsheet 202 has a thermal conductivity of 0.3 W m⁻¹ K⁻¹ to 1.8 W m⁻¹ K⁻¹. In some embodiments, the backsheet 202 has a thermal conductivity of 0.3 W m⁻¹ K⁻¹ to 1.7 W m⁻¹ K⁻¹. In some embodiments, the backsheet 202 has a thermal conductivity of 0.3 W m⁻¹ K⁻¹ to 1.6 W m⁻¹ K⁻¹. In some embodiments, the backsheet 202 has a thermal conductivity of 0.3 W m⁻¹ K⁻¹ to 1.5 W m⁻¹ K⁻¹. In some embodiments, the backsheet 202 has a thermal conductivity of 0.3 W m⁻¹ K⁻¹ to 1.4 W m⁻¹ K⁻¹. In some embodiments, the backsheet 202 has a thermal conductivity of 0.3 W m⁻¹ K⁻¹ to 1.3 W m⁻¹ K⁻¹. In some embodiments, the backsheet 202 has a thermal conductivity of 0.3 W m⁻¹ K⁻¹ to 1.2 W m⁻¹ K⁻¹. In some embodiments, the backsheet 202 has a thermal conductivity of 0.3 W m⁻¹ K⁻¹ to 1.1 W m⁻¹ K⁻¹. In some embodiments, the backsheet 202 has a thermal conductivity of 0.3 W m⁻¹ K⁻¹ to 1 W m⁻¹ K⁻¹. In some embodiments, the backsheet 202 has a thermal conductivity of 0.3 W m⁻¹ K⁻¹ to 0.9 W m⁻¹ K⁻¹. In some embodiments, the backsheet 202 has a thermal conductivity of 0.3 W m⁻¹ K⁻¹ to 0.8 W m⁻¹ K⁻¹. In some embodiments, the backsheet 202 has a thermal conductivity of 0.3 W m⁻¹ K⁻¹ to 0.7 W m⁻¹ K⁻¹. In some embodiments, the backsheet 202 has a thermal conductivity of 0.3 W m⁻¹ K⁻¹ to 0.6 W m⁻¹ K⁻¹. In some embodiments, the backsheet 202 has a thermal conductivity of 0.3 W m⁻¹ K⁻¹ to 0.5 W m⁻¹ K⁻¹. In some embodiments, the backsheet 202 has a thermal conductivity of 0.3 W m⁻¹ K⁻¹ to 0.4 W m⁻¹ K⁻¹.

In some embodiments, the backsheet 202 has a thermal conductivity of 0.3 W m⁻¹ K⁻¹ to 3 W m⁻¹ K⁻¹. In some embodiments, the backsheet 202 has a thermal conductivity of 0.4 W m⁻¹ K⁻¹ to 3 W m⁻¹ K⁻¹. In some embodiments, the backsheet 202 has a thermal conductivity of 0.5 W m⁻¹ K⁻¹ to 3 W m⁻¹ K⁻¹. In some embodiments, the backsheet 202 has a thermal conductivity of 0.6 W m⁻¹ K⁻¹ to 3 W m⁻¹ K⁻¹. In some embodiments, the backsheet 202 has a thermal conductivity of 0.7 W m⁻¹ K⁻¹ to 3 W m⁻¹ K⁻¹. In some embodiments, the backsheet 202 has a thermal conductivity of 0.8 W m⁻¹ K⁻¹ to 3 W m⁻¹ K⁻¹. In some embodiments, the backsheet 202 has a thermal conductivity of 0.9 W m⁻¹ K⁻¹ to 3 W m⁻¹ K⁻¹. In some embodiments, the backsheet 202 has a thermal conductivity of 1 W m⁻¹ K⁻¹ to 3 W m⁻¹ K⁻¹. In some embodiments, the backsheet 202 has a thermal conductivity of 1.1 W m⁻¹ K⁻¹ to 3 W m⁻¹ K⁻¹. In some embodiments, the backsheet 202 has a thermal conductivity of 1.2 W m⁻¹ K⁻¹ to 3 W m⁻¹ K⁻¹. In some embodiments, the backsheet 202 has a thermal conductivity of 1.3 W m⁻¹ K⁻¹ to 3 W m⁻¹ K⁻¹. In some embodiments, the backsheet 202 has a thermal conductivity of 1.4 W m⁻¹ K⁻¹ to 3 W m⁻¹ K⁻¹. In some embodiments, the backsheet 202 has a thermal conductivity of 1.5 W m⁻¹ K⁻¹ to 3 W m⁻¹ K⁻¹. In some embodiments, the backsheet 202 has a thermal conductivity of 1.6 W m⁻¹ K⁻¹ to 3 W m⁻¹ K⁻¹. In some embodiments, the backsheet 202 has a thermal conductivity of 1.7 W m⁻¹ K⁻¹ to 3 W m⁻¹ K⁻¹. In some embodiments, the backsheet 202 has a thermal conductivity of 1.8 W m⁻¹ K⁻¹ to 3 W m⁻¹ K⁻¹. In some embodiments, the backsheet 202 has a thermal conductivity of 1.9 W m⁻¹ K⁻¹ to 3 W m⁻¹ K⁻¹. In some embodiments, the backsheet 202 has a thermal conductivity of 2 W m⁻¹ K⁻¹ to 3 W m⁻¹ K⁻¹. In some embodiments, the backsheet 202 has a thermal conductivity of 2.1 W m⁻¹ K⁻¹ to 3 W m⁻¹ K⁻¹. In some embodiments, the backsheet 202 has a thermal conductivity of 2.2 W m⁻¹ K⁻¹ to 3 W m⁻¹ K⁻¹. In some embodiments, the backsheet 202 has a thermal conductivity of 2.3 W m⁻¹ K⁻¹ to 3 W m⁻¹ K⁻¹. In some embodiments, the backsheet 202 has a thermal conductivity of 2.4 W m⁻¹ K⁻¹ to 3 W m⁻¹ K⁻¹. In some embodiments, the backsheet 202 has a thermal conductivity of 2.5 W m⁻¹ K⁻¹ to 3 W m⁻¹ K⁻¹. In some embodiments, the backsheet 202 has a thermal conductivity of 2.6 W m⁻¹ K⁻¹ to 3 W m⁻¹ K⁻¹. In some embodiments, the backsheet 202 has a thermal conductivity of 2.7 W m⁻¹ K⁻¹ to 3 W m⁻¹ K⁻¹. In some embodiments, the backsheet 202 has a thermal conductivity of 2.8 W m⁻¹ K⁻¹ to 3 W m⁻¹ K⁻¹. In some embodiments, the backsheet 202 has a thermal conductivity of 2.9 W m⁻¹ K⁻¹ to 3 W m⁻¹ K⁻¹.

In some embodiments, the encapsulant layer 224 encapsulates 50% to 99.9% of an exterior surface area of the at least one solar cell 208. In another embodiment, the encapsulant layer 224 encapsulates 55% to 99.9% of an exterior surface area of the at least one solar cell 208. In another embodiment, the encapsulant layer 224 encapsulates 60% to 99.9% of an exterior surface area of the at least one solar cell 208. In another embodiment, the encapsulant layer 224 encapsulates 65% to 99.9% of an exterior surface area of the at least one solar cell 208. In another embodiment, the encapsulant layer 224 encapsulates 70% to 99.9% of an exterior surface area of the at least one solar cell 208. In another embodiment, the encapsulant layer 224 encapsulates 75% to 99.9% of an exterior surface area of the at least one solar cell 208. In another embodiment, the encapsulant layer 224 encapsulates 80% to 99.9% of an exterior surface area of the at least one solar cell 208. In another embodiment, the encapsulant layer 224 encapsulates 85% to 99.9% of an exterior surface area of the at least one solar cell 208. In another embodiment, the encapsulant layer 224 encapsulates 90% to 99.9% of an exterior surface area of the at least one solar cell 208. In another embodiment, the encapsulant layer 224 encapsulates 95% to 99.9% of an exterior surface area of the at least one solar cell 208.

In another embodiment, the encapsulant layer 224 encapsulates 50% to 95% of an exterior surface area of the at least one solar cell 208. In another embodiment, the encapsulant layer 224 encapsulates 55% to 95% of an exterior surface area of the at least one solar cell 208. In another embodiment, the encapsulant layer 224 encapsulates 60% to 95% of an exterior surface area of the at least one solar cell 208. In another embodiment, the encapsulant layer 224 encapsulates 65% to 95% of an exterior surface area of the at least one solar cell 208. In another embodiment, the encapsulant layer 224 encapsulates 70% to 95% of an exterior surface area of the at least one solar cell 208. In another embodiment, the encapsulant layer 224 encapsulates 75% to 95% of an exterior surface area of the at least one solar cell 208. In another embodiment, the encapsulant layer 224 encapsulates 80% to 95% of an exterior surface area of the at least one solar cell 208. In another embodiment, the encapsulant layer 224 encapsulates 85% to 95% of an exterior surface area of the at least one solar cell 208. In another embodiment, the encapsulant layer 224 encapsulates 90% to 95% of an exterior surface area of the at least one solar cell 208.

In another embodiment, the encapsulant layer 224 encapsulates 50% to 90% of an exterior surface area of the at least one solar cell 208. In another embodiment, the encapsulant layer 224 encapsulates 55% to 90% of an exterior surface area of the at least one solar cell 208. In another embodiment, the encapsulant layer 224 encapsulates 60% to 90% of an exterior surface area of the at least one solar cell 208. In another embodiment, the encapsulant layer 224 encapsulates 65% to 90% of an exterior surface area of the at least one solar cell 208. In another embodiment, the encapsulant layer 224 encapsulates 70% to 90% of an exterior surface area of the at least one solar cell 208. In another embodiment, the encapsulant layer 224 encapsulates 75% to 90% of an exterior surface area of the at least one solar cell 208. In another embodiment, the encapsulant layer 224 encapsulates 80% to 90% of an exterior surface area of the at least one solar cell 208. In another embodiment, the encapsulant layer 224 encapsulates 85% to 90% of an exterior surface area of the at least one solar cell 208.

In another embodiment, the encapsulant layer 224 encapsulates 50% to 85% of an exterior surface area of the at least one solar cell 208. In another embodiment, the encapsulant layer 224 encapsulates 55% to 85% of an exterior surface area of the at least one solar cell 208. In another embodiment, the encapsulant layer 224 encapsulates 60% to 85% of an exterior surface area of the at least one solar cell 208. In another embodiment, the encapsulant layer 224 encapsulates 65% to 85% of an exterior surface area of the at least one solar cell 208. In another embodiment, the encapsulant layer 224 encapsulates 70% to 85% of an exterior surface area of the at least one solar cell 208. In another embodiment, the encapsulant layer 224 encapsulates 75% to 85% of an exterior surface area of the at least one solar cell 208. In another embodiment, the encapsulant layer 224 encapsulates 80% to 85% of an exterior surface area of the at least one solar cell 208.

In another embodiment, the encapsulant layer 224 encapsulates 50% to 80% of an exterior surface area of the at least one solar cell 208. In another embodiment, the encapsulant layer 224 encapsulates 55% to 80% of an exterior surface area of the at least one solar cell 208. In another embodiment, the encapsulant layer 224 encapsulates 60% to 80% of an exterior surface area of the at least one solar cell 208. In another embodiment, the encapsulant layer 224 encapsulates 65% to 80% of an exterior surface area of the at least one solar cell 208. In another embodiment, the encapsulant layer 224 encapsulates 70% to 80% of an exterior surface area of the at least one solar cell 208. In another embodiment, the encapsulant layer 224 encapsulates 75% to 80% of an exterior surface area of the at least one solar cell 208.

In another embodiment, the encapsulant layer 224 encapsulates 50% to 75% of an exterior surface area of the at least one solar cell 208. In another embodiment, the encapsulant layer 224 encapsulates 55% to 75% of an exterior surface area of the at least one solar cell 208. In another embodiment, the encapsulant layer 224 encapsulates 60% to 75% of an exterior surface area of the at least one solar cell 208. In another embodiment, the encapsulant layer 224 encapsulates 65% to 75% of an exterior surface area of the at least one solar cell 208. In another embodiment, the encapsulant layer 224 encapsulates 70% to 75% of an exterior surface area of the at least one solar cell 208.

In another embodiment, the encapsulant layer 224 encapsulates 50% to 70% of an exterior surface area of the at least one solar cell 208. In another embodiment, the encapsulant layer 224 encapsulates 55% to 70% of an exterior surface area of the at least one solar cell 208. In another embodiment, the encapsulant layer 224 encapsulates 60% to 70% of an exterior surface area of the at least one solar cell 208. In another embodiment, the encapsulant layer 224 encapsulates 65% to 70% of an exterior surface area of the at least one solar cell 208.

In another embodiment, the encapsulant layer 224 encapsulates 50% to 65% of an exterior surface area of the at least one solar cell 208. In another embodiment, the encapsulant layer 224 encapsulates 55% to 65% of an exterior surface area of the at least one solar cell 208. In another embodiment, the encapsulant layer 224 encapsulates 60% to 65% of an exterior surface area of the at least one solar cell 208. In another embodiment, the encapsulant layer 224 encapsulates 50% to 60% of an exterior surface area of the at least one solar cell 208. In another embodiment, the encapsulant layer 224 encapsulates 55% to 60% of an exterior surface area of the at least one solar cell 208. In another embodiment, the encapsulant layer 224 encapsulates 55% to 60% of an exterior surface area of the at least one solar cell 208.

In some embodiments, the encapsulant layer 224 encapsulates 50% of an exterior surface area of the at least one solar cell 208. In another embodiment, the encapsulant layer 224 encapsulates 55% of the exterior surface area of the at least one solar cell 208. In another embodiment, the encapsulant layer 224 encapsulates 60% of the exterior surface area of the at least one solar cell 208. In another embodiment, the encapsulant layer 224 encapsulates 65% of the exterior surface area of the at least one solar cell 208. In another embodiment, the encapsulant layer 224 encapsulates 70% of the exterior surface area of the at least one solar cell 208. In another embodiment, the encapsulant layer 224 encapsulates 75% of the exterior surface area of the at least one solar cell 208. In another embodiment, the encapsulant layer 224 encapsulates 80% of the exterior surface area of the at least one solar cell 208. In another embodiment, the encapsulant layer 224 encapsulates 85% of the exterior surface area of the at least one solar cell 208. In another embodiment, the encapsulant layer 224 encapsulates 90% of the exterior surface area of the at least one solar cell 208. In another embodiment, the encapsulant layer 224 encapsulates 95% of the exterior surface area of the at least one solar cell 208. In another embodiment, the encapsulant layer 224 encapsulates 100% of the exterior surface area of the at least one solar cell 208.

In some embodiments, the encapsulant layer 224 has a thickness of 0.5 mm to 4 mm. In another embodiment, the encapsulant layer 224 has a thickness of 0.5 mm to 3.5 mm. In another embodiment, the encapsulant layer 224 has a thickness of 0.5 mm to 3 mm. In another embodiment, the encapsulant layer 224 has a thickness of 0.5 mm to 2.5 mm. In another embodiment, the encapsulant layer 224 has a thickness of 0.5 mm to 2 mm. In another embodiment, the encapsulant layer 224 has a thickness of 0.5 mm to 1.5 mm. In another embodiment, the encapsulant layer 224 has a thickness of 0.5 mm to 1 mm.

In some embodiments, the encapsulant layer 224 has a thickness of 1 mm to 4 mm. In another embodiment, the encapsulant layer 224 has a thickness of 1 mm to 3.5 mm. In another embodiment, the encapsulant layer 224 has a thickness of 1 mm to 3 mm. In another embodiment, the encapsulant layer 224 has a thickness of 1 mm to 2.5 mm. In another embodiment, the encapsulant layer 224 has a thickness of 1 mm to 2 mm. In another embodiment, the encapsulant layer 224 has a thickness of 1 mm to 1.5 mm. In some embodiments, the encapsulant layer 224 has a thickness of 1.5 mm to 4 mm. In another embodiment, the encapsulant layer 224 has a thickness of 1.5 mm to 3.5 mm. In another embodiment, the encapsulant layer 224 has a thickness of 1.5 mm to 3 mm. In another embodiment, the encapsulant layer 224 has a thickness of 1.5 mm to 2.5 mm. In another embodiment, the encapsulant layer 224 has a thickness of 1.5 mm to 2 mm.

In some embodiments, the encapsulant layer 224 has a thickness of 2 mm to 4 mm. In another embodiment, the encapsulant layer 224 has a thickness of 2 mm to 3.5 mm. In another embodiment, the encapsulant layer 224 has a thickness of 2 mm to 3 mm. In another embodiment, the encapsulant layer 224 has a thickness of 2 mm to 2.5 mm. In some embodiments, the encapsulant layer 224 has a thickness of 2.5 mm to 4 mm. In another embodiment, the encapsulant layer 224 has a thickness of 2.5 mm to 3.5 mm. In another embodiment, the encapsulant layer 224 has a thickness of 2.5 mm to 3 mm. In some embodiments, the encapsulant layer 224 has a thickness of 3 mm to 4 mm. In another embodiment, the encapsulant layer 224 has a thickness of 3 mm to 3.5 mm. In some embodiments, the encapsulant layer 224 has a thickness of 3.5 mm to 4 mm.

In some embodiments, the encapsulant layer 224 has a thickness of 0.5 mm. In some embodiments, the encapsulant layer 224 has a thickness of 0.6 mm. In some embodiments, the encapsulant layer 224 has a thickness of 0.7 mm. In some embodiments, the encapsulant layer 224 has a thickness of 0.8 mm. In some embodiments, the encapsulant layer 224 has a thickness of 0.9 mm. In some embodiments, the encapsulant layer 224 has a thickness of 1 mm. In some embodiments, the encapsulant layer 224 has a thickness of 1.5 mm. In some embodiments, the encapsulant layer 224 has a thickness of 2 mm. In some embodiments, the encapsulant layer 224 has a thickness of 2.5 mm. In some embodiments, the encapsulant layer 224 has a thickness of 3 mm. In some embodiments, the encapsulant layer 224 has a thickness of 3.5 mm. In some embodiments, the encapsulant layer 224 has a thickness of 4 mm.

In some embodiments, the encapsulant layer 224 has a thickness of 0.2 mm to 2 mm. In some embodiments, the encapsulant layer 224 has a thickness of 0.2 mm to 1.5 mm. In some embodiments, the encapsulant layer 224 has a thickness of 0.2 mm to 1 mm. In some embodiments, the encapsulant layer 224 has a thickness of 0.2 mm to 0.6 mm. In some embodiments, the encapsulant layer 224 has a thickness of 0.2 mm to 0.5 mm. In some embodiments, the encapsulant layer 224 has a thickness of 0.5 mm to 2 mm. In some embodiments, the encapsulant layer 224 has a thickness of 0.5 mm to 1.5 mm. In some embodiments, the encapsulant layer 224 has a thickness of 0.5 mm to 1 mm. In some embodiments, the encapsulant layer 224 has a thickness of 1 mm to 2 mm. In some embodiments, the encapsulant layer 224 has a thickness of 1 mm to 1.5 mm. In some embodiments, the encapsulant layer 224 has a thickness of 1.5 mm to 2 mm.

In some embodiments, the encapsulant layer 224 has a thickness of 0.2 mm. In some embodiments, the encapsulant layer 224 has a thickness of 0.3 mm. In some embodiments, the encapsulant layer 224 has a thickness of 0.4 mm. In some embodiments, the encapsulant layer 224 has a thickness of 0.45 mm. In some embodiments, the encapsulant layer 224 has a thickness of 0.5 mm. In some embodiments, the encapsulant layer 224 has a thickness of 0.6 mm. In some embodiments, the encapsulant layer 224 has a thickness of 1 mm. In some embodiments, the encapsulant layer 224 has a thickness of 1.5 mm. In some embodiments, the encapsulant layer 224 has a thickness of 2 mm. In some embodiments, the encapsulant layer 224 has a thickness of 2.5 mm. In some embodiments, the encapsulant layer 224 has a thickness of 3 mm. In some embodiments, the encapsulant layer 224 has a thickness of 3.5 mm. In some embodiments, the encapsulant layer 224 has a thickness of 4 mm.

In some embodiments, the photovoltaic module 200 comprises a film 226. In some embodiments, the film 226 is located between the backsheet 202 and, when the photovoltaic module 200 is installed, a roofing substrate. In some embodiments, the film 226 directly contacts the backsheet 202. In some embodiments, the film 226 directly contacts the roofing substrate. In some embodiments, an intervening layer is located between the backsheet 202 and the film 226. In some embodiments, for example, an adhesive layer is located between the backsheet 202 and the film 226.

In some embodiments, the film comprises a thermally conductive film. In some embodiments, the film comprises at least one of graphite, calcium carbonate, calcium silicate, talc, barite, barium sulfate, titanium oxide (e.g., rutile, anatase, etc.), magnetite, alumina, silicon dioxide, aluminum nitride, wollastonite, aluminum nitride, silicon carbide, graphene, carbon nanostructures (e.g., carbon nanotubes), fullerenes, or any combination thereof. In some embodiments, the graphite comprises a highly oriented pyrolytic graphite. In some embodiments, the highly oriented pyrolytic graphite refers to a pure and ordered form of synthetic graphite. In some embodiments, the highly oriented pyrolytic graphite comprises aligned graphite crystallites. In some embodiments, the adhesive layer between the backsheet 202 and the film 226 comprises any of the adhesives disclosed herein, such as, for example and without limitation, a hot melt adhesive, a pressure sensitive adhesive, or any combination thereof. For example, in some embodiments, the adhesive layer comprises at least one of a polyolefin elastomer, a polyurethane, an acrylic, a silicone, or any combination thereof.

In some embodiments, the film 226 has a thickness of 10 microns to 500 microns. In some embodiments, the film 226 has a thickness of 10 microns to 450 microns. In some embodiments, the film 226 has a thickness of 10 microns to 400 microns. In some embodiments, the film 226 has a thickness of 10 microns to 350 microns. In some embodiments, the film 226 has a thickness of 10 microns to 300 microns. In some embodiments, the film 226 has a thickness of 10 microns to 250 microns. In some embodiments, the film 226 has a thickness of 10 microns to 200 microns. In some embodiments, the film 226 has a thickness of 10 microns to 150 microns. In some embodiments, the film 226 has a thickness of 10 microns to 100 microns. In some embodiments, the film 226 has a thickness of 10 microns to 90 microns. In some embodiments, the film 226 has a thickness of 10 microns to 80 microns. In some embodiments, the film 226 has a thickness of 10 microns to 70 microns. In some embodiments, the film 226 has a thickness of 10 microns to 60 microns. In some embodiments, the film 226 has a thickness of 10 microns to 50 microns. In some embodiments, the film 226 has a thickness of 10 microns to 40 microns. In some embodiments, the film 226 has a thickness of 10 microns to 30 microns. In some embodiments, the film 226 has a thickness of 10 microns to 20 microns.

In some embodiments, the film 226 has a thickness of 50 microns to 500 microns. In some embodiments, the film 226 has a thickness of 100 microns to 500 microns. In some embodiments, the film 226 has a thickness of 150 microns to 500 microns. In some embodiments, the film 226 has a thickness of 200 microns to 500 microns. In some embodiments, the film 226 has a thickness of 250 microns to 500 microns. In some embodiments, the film 226 has a thickness of 300 microns to 500 microns. In some embodiments, the film 226 has a thickness of 350 microns to 500 microns. In some embodiments, the film 226 has a thickness of 400 microns to 500 microns. In some embodiments, the film 226 has a thickness of 450 microns to 500 microns.

In some embodiments, the film 226 has a thermal conductivity of 1 W m⁻¹ K⁻¹ to 2000 W m⁻¹ K⁻¹. In some embodiments, the film 226 has a thermal conductivity of 1 W m⁻¹ K⁻¹ to 1900 W m⁻¹ K⁻¹. In some embodiments, the film 226 has a thermal conductivity of 1 W m⁻¹ K⁻¹ to 1800 W m⁻¹ K⁻¹. In some embodiments, the film 226 has a thermal conductivity of 1 W m⁻¹ K⁻¹ to 1700 W m⁻¹ K⁻¹. In some embodiments, the film 226 has a thermal conductivity of 1 W m⁻¹ K⁻¹ to 1600 W m⁻¹ K⁻¹. In some embodiments, the film 226 has a thermal conductivity of 1 W m⁻¹ K⁻¹ to 1500 W m⁻¹ K⁻¹. In some embodiments, the film 226 has a thermal conductivity of 1 W m⁻¹ K⁻¹ to 1400 W m⁻¹ K⁻¹. In some embodiments, the film 226 has a thermal conductivity of 1 W m⁻¹ K⁻¹ to 1300 W m⁻¹ K⁻¹.

In some embodiments, the film 226 has a thermal conductivity of 1 W m⁻¹ K⁻¹ to 1200 W m⁻¹ K⁻¹. In some embodiments, the film 226 has a thermal conductivity of 1 W m⁻¹ K⁻¹ to 1100 W m⁻¹ K⁻¹. In some embodiments, the film 226 has a thermal conductivity of 1 W m⁻¹ K⁻¹ to 1000 W m⁻¹ K⁻¹. In some embodiments, the film 226 has a thermal conductivity of 1 W m⁻¹ K⁻¹ to 900 W m⁻¹ K⁻¹. In some embodiments, the film 226 has a thermal conductivity of 1 W m⁻¹ K⁻¹ to 800 W m⁻¹ K⁻¹. In some embodiments, the film 226 has a thermal conductivity of 1 W m⁻¹ K⁻¹ to 700 W m⁻¹ K⁻¹. In some embodiments, the film 226 has a thermal conductivity of 1 W m⁻¹ K⁻¹ to 600 W m⁻¹ K⁻¹. In some embodiments, the film 226 has a thermal conductivity of 1 W m⁻¹ K⁻¹ to 500 W m⁻¹ K⁻¹. In some embodiments, the film 226 has a thermal conductivity of 1 W m⁻¹ K⁻¹ to 400 W m⁻¹ K⁻¹. In some embodiments, the film 226 has a thermal conductivity of 1 W m⁻¹ K⁻¹ to 300 W m⁻¹ K⁻¹. In some embodiments, the film 226 has a thermal conductivity of 1 W m⁻¹ K⁻¹ to 200 W m⁻¹ K⁻¹. In some embodiments, the film 226 has a thermal conductivity of 1 W m⁻¹ K⁻¹ to 100 W m⁻¹ K⁻¹. In some embodiments, the film 226 has a thermal conductivity of 1 W m⁻¹ K⁻¹ to 90 W m⁻¹ K⁻¹. In some embodiments, the film 226 has a thermal conductivity of 1 W m⁻¹ K⁻¹ to 80 W m⁻¹ K⁻¹. In some embodiments, the film 226 has a thermal conductivity of 1 W m⁻¹ K⁻¹ to 70 W m⁻¹ K⁻¹. In some embodiments, the film 226 has a thermal conductivity of 1 W m⁻¹ K⁻¹ to 60 W m⁻¹ K⁻¹. In some embodiments, the film 226 has a thermal conductivity of 1 W m⁻¹ K⁻¹ to 50 W m⁻¹ K⁻¹. In some embodiments, the film 226 has a thermal conductivity of 1 W m⁻¹ K⁻¹ to 40 W m⁻¹ K⁻¹. In some embodiments, the film 226 has a thermal conductivity of 1 W m⁻¹ K⁻¹ to 30 W m⁻¹ K⁻¹. In some embodiments, the film 226 has a thermal conductivity of 1 W m⁻¹ K⁻¹ to 20 W m⁻¹ K⁻¹. In some embodiments, the film 226 has a thermal conductivity of 1 W m⁻¹ K⁻¹ to 10 W m⁻¹ K⁻¹. In some embodiments, the film 226 has a thermal conductivity of 1 W m⁻¹ K⁻¹ to 5 W m⁻¹ K⁻¹.

In some embodiments, the film 226 has a thermal conductivity of 100 W m⁻¹ K⁻¹ to 2000 W m⁻¹ K⁻¹. In some embodiments, the film 226 has a thermal conductivity of 200 W m⁻¹ K⁻¹ to 2000 W m⁻¹ K⁻¹. In some embodiments, the film 226 has a thermal conductivity of 300 W m⁻¹ K⁻¹ to 2000 W m⁻¹ K⁻¹. In some embodiments, the film 226 has a thermal conductivity of 400 W m⁻¹ K⁻¹ to 2000 W m⁻¹ K⁻¹. In some embodiments, the film 226 has a thermal conductivity of 500 W m⁻¹ K⁻¹ to 2000 W m⁻¹ K⁻¹. In some embodiments, the film 226 has a thermal conductivity of 600 W m⁻¹ K⁻¹ to 2000 W m⁻¹ K⁻¹. In some embodiments, the film 226 has a thermal conductivity of 700 W m⁻¹ K⁻¹ to 2000 W m⁻¹ K⁻¹. In some embodiments, the film 226 has a thermal conductivity of 800 W m⁻¹ K⁻¹ to 2000 W m⁻¹ K⁻¹. In some embodiments, the film 226 has a thermal conductivity of 900 W m⁻¹ K⁻¹ to 2000 W m⁻¹ K⁻¹. In some embodiments, the film 226 has a thermal conductivity of 1000 W m⁻¹ K⁻¹ to 2000 W m⁻¹ K⁻¹. In some embodiments, the film 226 has a thermal conductivity of 1100 W m⁻¹ K⁻¹ to 2000 W m⁻¹ K⁻¹. In some embodiments, the film 226 has a thermal conductivity of 1200 W m⁻¹ K⁻¹ to 2000 W m⁻¹ K⁻¹. In some embodiments, the film 226 has a thermal conductivity of 1300 W m⁻¹ K⁻¹ to 2000 W m⁻¹ K⁻¹. In some embodiments, the film 226 has a thermal conductivity of 1400 W m⁻¹ K⁻¹ to 2000 W m⁻¹ K⁻¹. In some embodiments, the film 226 has a thermal conductivity of 1500 W m⁻¹ K⁻¹ to 2000 W m⁻¹ K⁻¹. In some embodiments, the film 226 has a thermal conductivity of 1600 W m⁻¹ K⁻¹ to 2000 W m⁻¹ K⁻¹. In some embodiments, the film 226 has a thermal conductivity of 1700 W m⁻¹ K⁻¹ to 2000 W m⁻¹ K⁻¹. In some embodiments, the film 226 has a thermal conductivity of 1800 W m⁻¹ K⁻¹ to 2000 W m⁻¹ K⁻¹. In some embodiments, the film 226 has a thermal conductivity of 1900 W m⁻¹ K⁻¹ to 2000 W m⁻¹ K⁻¹.

In some embodiments, when the photovoltaic module 200 is installed on a roofing substrate such that the film 226 is located between the backsheet 202 and the roofing substrate, the photovoltaic module exhibits a 1% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 45% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 40% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 35% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 30% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 25% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 20% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 15% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 10% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 1% to 5% reduction in max temperature in comparison to a photovoltaic module without a film.

In some embodiments, when the photovoltaic module 200 is installed on a roofing substrate such that the film 226 is located between the backsheet 202 and the roofing substrate, the photovoltaic module exhibits a 5% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 10% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 15% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 20% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 25% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 30% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 35% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 40% to 50% reduction in max temperature in comparison to a photovoltaic module without a film. In some embodiments, when the photovoltaic module 200 is installed on a roofing substrate such that the film 226 is located between the backsheet 202 and the roofing substrate, the photovoltaic module exhibits a 45% to 50% reduction in max temperature in comparison to a photovoltaic module without a film. In some embodiments, the max temperature is an internal temperature of the photovoltaic module. In some embodiments, the max temperature is a temperature of the roofing substrate (e.g., a surface temperature).

In some embodiments, the roofing substrate may comprise, consist of, or consist essentially of at least one of a plywood substrate, a glass substrate, a cellulosic substrate, a roof shingle, a glass mat, a fiberglass mat, an underlayment, a roofing membrane, a roof deck, a photovoltaic (PV) panel, a modified bitumen (MODBIT) substrate, a roll good, a board (such as but not limited to at least one of a foam board (e.g., a polyisocyanurate (ISO) foam board), a cover board, or any combination thereof), a pipe, a base sheet, a chimney, a wax paper, or any combination thereof.

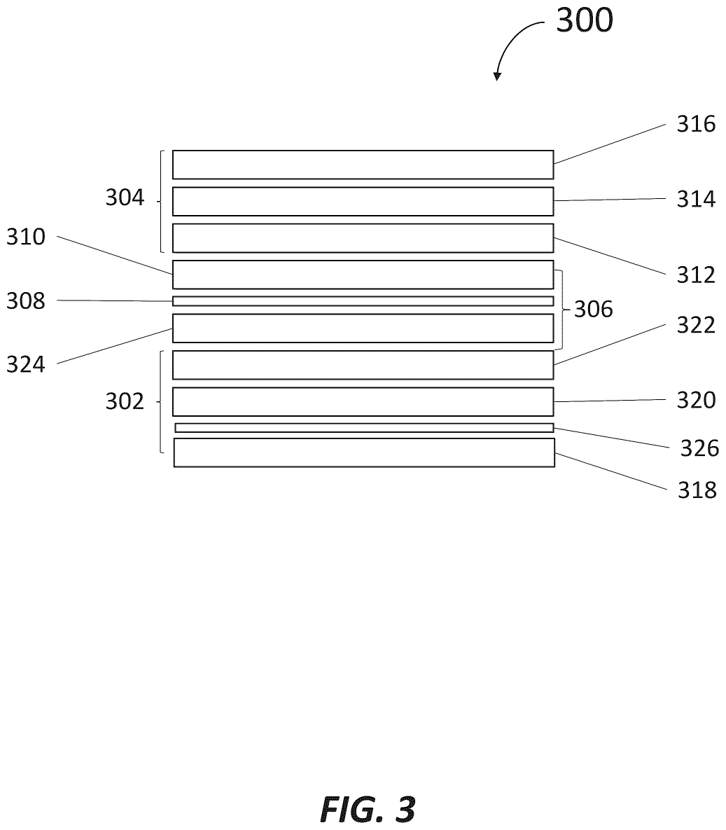

FIG. 3 is a schematic diagram of a cross-section of a photovoltaic module 300, according to some embodiments. The reference numbers for the photovoltaic module 300 are similar to the reference numbers used for the photovoltaic module 200. In some embodiments, the photovoltaic module 300 is similar to the photovoltaic module 200, except that the film 326 is located between the first layer 318 and the third layer 320. In some embodiments, the film 326 directly contacts the first layer 318. In some embodiments, the film 326 directly contacts the third layer 320. In some embodiments, an intervening layer is located between the film 326 and the first layer 318. In some embodiments, an intervening layer is located between the film 326 and the third layer 320. In some embodiments, for example, an adhesive layer is located between the film 326 and the first layer 318. In some embodiments, an adhesive layer is located between the film 326 and the third layer 320. In some embodiments, features not discussed with respect to the photovoltaic module 300 are same or similar to the features discussed with respect to the photovoltaic module 200. Some of the differences between the photovoltaic modules are discussed. It will be appreciated that other differences may exist without departing from the scope of this disclosure.

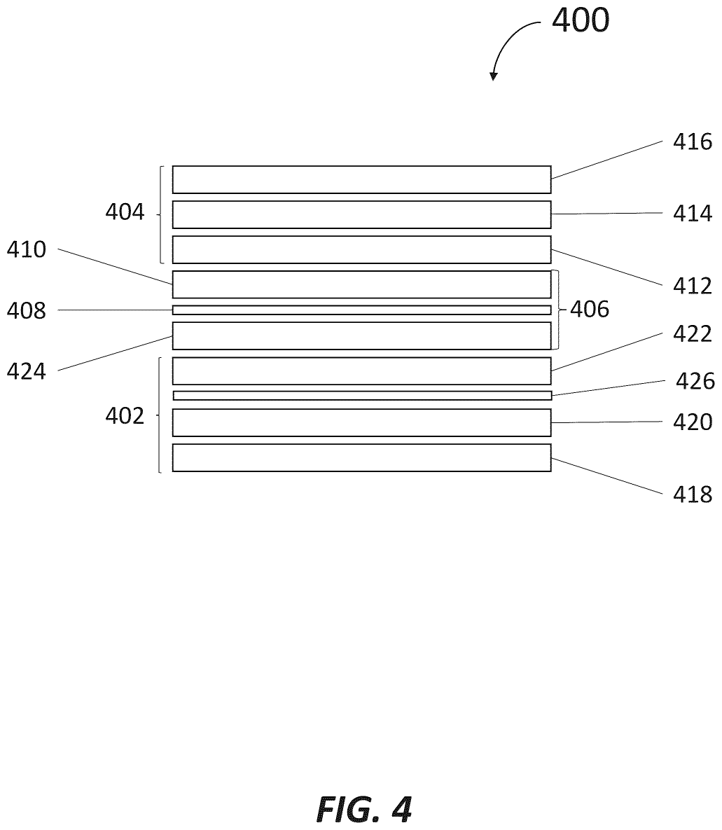

FIG. 4 is a schematic diagram of a cross-section of a photovoltaic module 400, according to some embodiments. The reference numbers for the photovoltaic module 400 are similar to the reference numbers used for the photovoltaic module 200. In some embodiments, the photovoltaic module 400 is similar to the photovoltaic module 200, except that the film 426 is located between the third layer 420 and the second layer 422. In some embodiments, the film 426 directly contacts the third layer 420. In some embodiments, the film 426 directly contacts the second layer 422. In some embodiments, an intervening layer is located between the film 426 and the third layer 420. In some embodiments, an intervening layer is located between the film 426 and the second layer 422. In some embodiments, for example, an adhesive layer is located between the film 426 and the third layer 420. In some embodiments, an adhesive layer is located between the film 426 and the second layer 422. In some embodiments, features not discussed with respect to the photovoltaic module 400 are same or similar to the features discussed with respect to the photovoltaic module 200. Some of the differences between the photovoltaic modules are discussed. It will be appreciated that other differences may exist without departing from the scope of this disclosure.

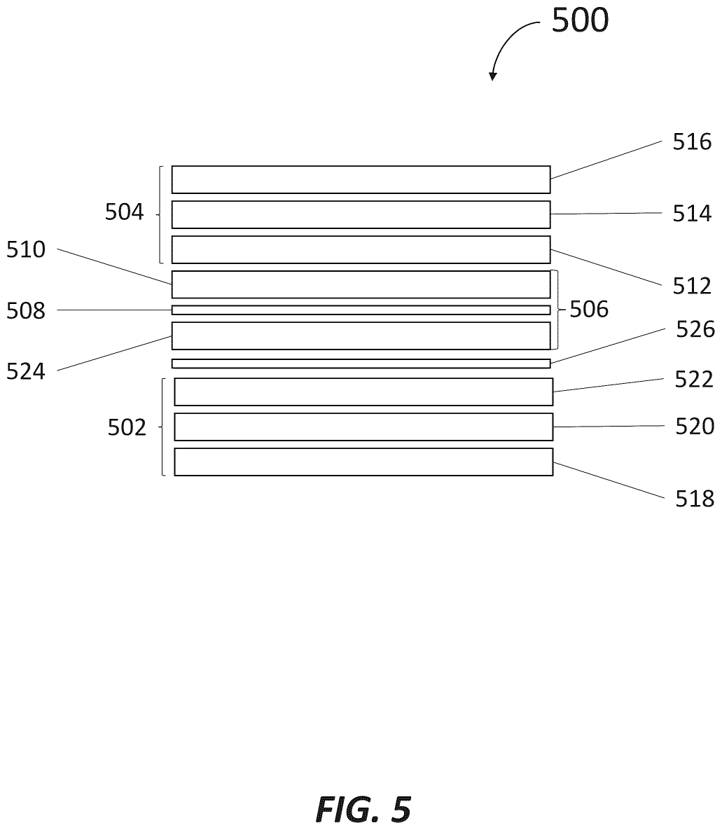

FIG. 5 is a schematic diagram of a cross-section of a photovoltaic module 500, according to some embodiments. The reference numbers for the photovoltaic module 500 are similar to the reference numbers used for the photovoltaic module 200. In some embodiments, the photovoltaic module 500 is similar to the photovoltaic module 200, except that the film 526 is located between the second layer 522 and the encapsulant layer 524. In some embodiments, the film 526 directly contacts the second layer 522. In some embodiments, the film 526 directly contacts the encapsulant layer 524. In some embodiments, an intervening layer is located between the film 526 and the second layer 522. In some embodiments, an intervening layer is located between the film 526 and the encapsulant layer 524. In some embodiments, for example, an adhesive layer is located between the film 526 and the encapsulant layer 524. In some embodiments, an adhesive layer is located between the film 526 and the second layer 522. In some embodiments, features not discussed with respect to the photovoltaic module 500 are same or similar to the features discussed with respect to the photovoltaic module 200. Some of the differences between the photovoltaic modules are discussed. It will be appreciated that other differences may exist without departing from the scope of this disclosure.

Some embodiments relate to roofing systems. In some embodiments, a roofing system comprises a roofing substrate. In some embodiments, the roofing system comprises a plurality of photovoltaic modules. In some embodiments, the plurality of photovoltaic modules are installed on the roofing substrate. In some embodiments, the plurality of photovoltaic modules comprises a first photovoltaic module and a second photovoltaic module. In some embodiments, the plurality of photovoltaic modules comprises at least one of a first photovoltaic module, a second photovoltaic module, a third photovoltaic module, a fourth photovoltaic module, a fifth photovoltaic module, a sixth photovoltaic module, a seventh photovoltaic module, an eighth photovoltaic module, a ninth photovoltaic module, a tenth photovoltaic module, up to one-thousand photovoltaic modules, or any combination thereof. In some embodiments, the roofing system comprises a single photovoltaic module.

Some embodiments relate to a roofing system. In some embodiments, the roofing system comprises a roofing substrate. In some embodiments, the roofing system a plurality of photovoltaic modules installed on the roofing substrate. In some embodiments, each of the plurality of photovoltaic modules comprises a frontsheet. In some embodiments, each of the plurality of photovoltaic modules comprises at least one solar cell. In some embodiments, each of the plurality of photovoltaic modules comprises an encapsulant, wherein the encapsulant encapsulates the at least one solar cell. In some embodiments, each of the plurality of photovoltaic modules comprises an encapsulated solar cell. In some embodiments, each of the plurality of photovoltaic modules comprises a backsheet. In some embodiments, the encapsulated solar cell is located between the frontsheet and the backsheet. In some embodiments, the backsheet is located between the encapsulated solar cell and the roofing substrate. In some embodiments, the backsheet comprises at least one layer. In some embodiments, the at least one layer comprises 50% to 99.5% by weight of a polymer based on a total weight of the at least one layer of the backsheet. In some embodiments, the at least one layer comprises 0.5% to 50% by weight of a graphene component based on the total weight of the at least one layer of the backsheet.

Some embodiments relate to a roofing system. In some embodiments, the roofing system comprises a roofing substrate. In some embodiments, the roofing system comprises a plurality of photovoltaic modules installed on the roofing substrate. In some embodiments, each of the plurality of photovoltaic modules comprises a frontsheet. In some embodiments, each of the plurality of photovoltaic modules comprises at least one solar cell. In some embodiments, each of the plurality of photovoltaic modules comprises an encapsulant, wherein the encapsulant encapsulates the at least one solar cell. In some embodiments, each of the plurality of photovoltaic modules comprises an encapsulated solar cell. In some embodiments, each of the plurality of photovoltaic modules comprises a backsheet. In some embodiments, each of the plurality of photovoltaic modules comprises a film. In some embodiments, the encapsulated solar cell is located between the frontsheet and the backsheet. In some embodiments, the backsheet is located between the encapsulated solar cell and the film. In some embodiments, the film is located between the backsheet and the roofing substrate. In some embodiments, the film comprises a graphite film.

Some embodiments relate to a roofing system. In some embodiments, the roofing system comprises a roofing substrate. In some embodiments, the roofing system comprises a plurality of photovoltaic modules installed on the roofing substrate. In some embodiments, each of the plurality of photovoltaic modules comprises a frontsheet. In some embodiments, each of the plurality of photovoltaic modules comprises at least one solar cell. In some embodiments, each of the plurality of photovoltaic modules comprises an encapsulant, wherein the encapsulant encapsulates the at least one solar cell. In some embodiments, each of the plurality of photovoltaic modules comprises an encapsulated solar cell. In some embodiments, each of the plurality of photovoltaic modules comprises a backsheet. In some embodiments, each of the plurality of photovoltaic modules comprises a film. In some embodiments, the encapsulated solar cell is located between the frontsheet and the backsheet. In some embodiments, the backsheet is located between the encapsulated solar cell and the film. In some embodiments, the film is located between the backsheet and the roofing substrate. In some embodiments, the backsheet comprises at least one layer. In some embodiments, the at least one layer comprises 50% to 99.5% by weight of a polymer based on a total weight of the at least one layer of the backsheet. In some embodiments, the at least one layer comprises 0.5% to 50% by weight of a graphene component based on the total weight of the at least one layer of the backsheet. In some embodiments, the film comprises a graphite film.

Some embodiments relate to a photovoltaic module. In some embodiments, the photovoltaic module comprises a frontsheet. In some embodiments, the photovoltaic module comprises an encapsulated solar cell. In some embodiments, the photovoltaic module comprises a backsheet. In some embodiments, the backsheet comprises at least one layer. In some embodiments, the at least one layer comprises 50% to 99.5% by weight of a polymer based on a total weight of the at least one layer of the backsheet. In some embodiments, the at least one layer comprises 0.5% to 50% by weight of a graphene component based on the total weight of the at least one layer of the backsheet. In some embodiments, the at least one layer is configured to be secured to a roofing substrate.

Some embodiments relate to a photovoltaic module. In some embodiments, the photovoltaic module comprises a frontsheet. In some embodiments, the photovoltaic module comprises an encapsulated solar cell. In some embodiments, the photovoltaic module comprises a backsheet. In some embodiments, the photovoltaic module comprises a film. In some embodiments, the encapsulated solar cell is located between the front sheet and the backsheet. In some embodiments, the backsheet is located between the encapsulated solar cell and the film. In some embodiments, when installed on a roofing substrate, the film is configured to be located between the backsheet and the roofing substrate. In some embodiments, the film comprises a graphite film.

Some embodiments relate to a photovoltaic module. In some embodiments, the photovoltaic module comprises a frontsheet. In some embodiments, the photovoltaic module comprises an encapsulated solar cell. In some embodiments, the photovoltaic module comprises a backsheet. In some embodiments, the photovoltaic module comprises a film. In some embodiments, the encapsulated solar cell is located between the front sheet and the backsheet. In some embodiments, the backsheet is located between the encapsulated solar cell and the film. In some embodiments, when installed on a roofing substrate, the film is configured to be located between the backsheet and the roofing substrate. In some embodiments, the backsheet comprises at least one layer. In some embodiments, the at least one layer comprises 50% to 99.5% by weight of a polymer based on a total weight of the at least one layer of the backsheet. In some embodiments, the at least one layer comprises 0.5% to 50% by weight of a graphene component based on the total weight of the at least one layer of the backsheet. In some embodiments, the film comprises a graphite film.

### Example 1

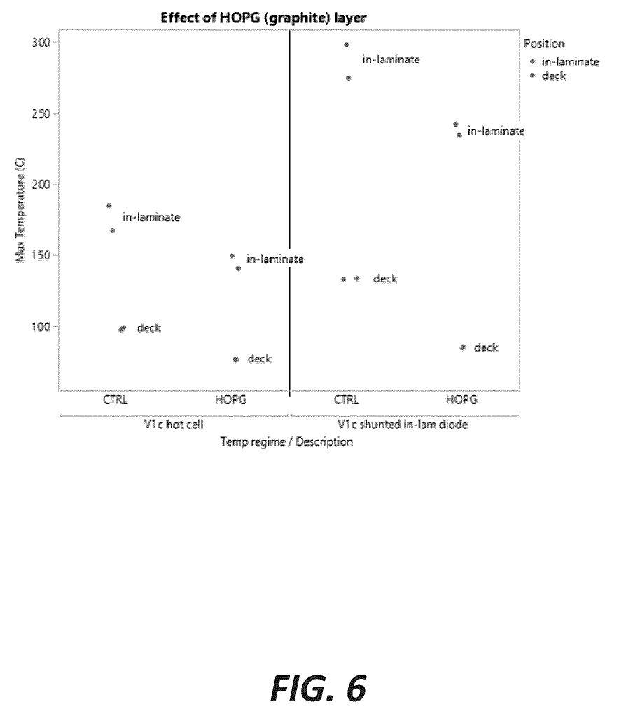

A thermal conductivity of a photovoltaic module was tested and compared to a control photovoltaic module. The photovoltaic module comprised a graphite film (e.g., a highly oriented pyrolytic graphite film). The graphite film was adhered to the backsheet of the photovoltaic module. The photovoltaic module was installed on a roof deck such that the graphite film was located between the backsheet and the roof deck. The control photovoltaic module was same as the photovoltaic module, except the control photovoltaic module did not comprise the graphite film. The photovoltaic modules, while installed, were heated. The temperature inside the photovoltaic module and on a surface of the roof deck were measured. FIG. 6 is a graphical view of the thermal conductivity test results, according to some embodiments. As shown in FIG. 6, the max temperature inside the photovoltaic module and on the surface of the roof deck was reduced by 15% to 40% relative to the control photovoltaic module.

What is claimed is:

1. A roofing system comprising:
a roofing substrate; and
a plurality of photovoltaic modules installed on the roofing substrate, each of the plurality of photovoltaic modules comprising:
a frontsheet;
at least one solar cell;
an encapsulant,
wherein the encapsulant encapsulates the at least one solar cell;
a backsheet;
wherein the backsheet is below the encapsulant;
wherein the backsheet comprises at least one layer, the at least one layer comprising:
50% to 99.5% by weight of a polymer based on a total weight of the at least one layer of the backsheet; and
0.5% to 50% by weight of a graphene component based on the total weight of the at least one layer of the backsheet.

2. The roofing system of claim 1, wherein the roofing substrate comprises at least one of a roof deck, an underlayment, or any combination thereof.

3. The roofing system of claim 1, wherein the graphene component comprises at least one of graphene particles, graphene sheets, graphene flakes, or any combination thereof.

4. The roofing system of claim 1, wherein the graphene component is provided in a form of graphite.

5. The roofing system of claim 1, wherein the graphene component having a median particle size of 1 μm to 300 μm.

6. The roofing system of claim 1, wherein the at least one layer having a thermal conductivity of 0.3 W m⁻¹ K⁻¹ to 3 W m⁻¹ K⁻¹.

7. The roofing system of claim 1, wherein the at least one layer of the backsheet having a thickness of 0.2 mm to 4 mm.

8. The roofing system of claim 1, wherein the at least one layer of the backsheet is in direct contact with the roofing substrate.

9. The roofing system of claim 1, wherein the at least one layer further comprises an encapsulant.

10. The roofing system of claim 6, wherein the encapsulant comprises at least one of polyolefins, ethyl vinyl acetates, ionomers, silicones, poly vinyl butyral, epoxies, polyurethanes, or any combination thereof.

11. A photovoltaic module comprising:
a frontsheet;
a backsheet; and
an encapsulated solar cell between the frontsheet and the backsheet;
wherein the backsheet comprises at least one layer, the at least one layer comprising:
50% to 99.5% by weight of a polymer based on a total weight of the at least one layer of the backsheet; and
0.5% to 50% by weight of a graphene component based on the total weight of the at least one layer of the backsheet;
wherein the at least one layer is configured to be secured to a roofing substrate.

12. The photovoltaic module of claim 11, wherein the roofing substrate comprises at least one of a roof deck, an underlayment, or any combination thereof.

13. The photovoltaic module of claim 11, wherein the graphene component comprises at least one of graphene particles, graphene sheets, graphene flakes, or any combination thereof.

14. The photovoltaic module of claim 11, wherein the graphene component is provided in a form of graphite.

15. The photovoltaic module of claim 11, wherein the graphene component having a median particle size of 1 μm to 300 μm.

16. The photovoltaic module of claim 11, wherein the at least one layer having a thermal conductivity of 0.3 W m⁻¹ K⁻¹ to 3 W m⁻¹ K⁻¹.

17. The photovoltaic module of claim 11, wherein the at least one layer of the backsheet having a thickness of 0.2 mm to 4 mm.

18. The photovoltaic module of claim 11, wherein the at least one layer of the backsheet, when installed on the roofing substrate, is in direct contact with the roofing substrate.

19. The photovoltaic module of claim 11, wherein the at least one layer further comprises an encapsulant.

20. The photovoltaic module of claim 19, wherein the encapsulant comprises at least one of polyolefins, ethyl vinyl acetates, ionomers, silicones, poly vinyl butyral, epoxies, polyurethanes, or any combination thereof.
